(19) United States
(12) Patent Application Publication
(10) Pub. No.: US 2024/0057244 A1
(43) Pub. Date: Feb. 15, 2024

(54) SYSTEM FOR TREATMENT OF SUBSTRATES

(71) Applicant: XEFCO PTY LTD, Eveleigh, NSW (AU)

(72) Inventors: Scott WHITBY, Chatswood, New South Wales (AU); Robert VOLPE, Highton, Victoria (AU); Thomas HUSSEY, Drummoyne, New South Wales (AU); Zhiqiang CHEN, Werribee, Victoria (AU); Weiwei LEI, Highton, Victoria (AU); John FRANCIA, Hamlyn Heights, Victoria (AU)

(21) Appl. No.: 18/258,204

(22) PCT Filed: Dec. 18, 2021
(86) PCT No.: PCT/AU2021/051519

§ 371 Date: Jun. 16, 2023

(30) Foreign Application Priority Data
Dec. 18, 2020 (AU) 2020904747

(51) Int. Cl. H05H 1/24; D06M 10/02

(52) U.S. Cl. CPC H05H 1/247; H05H 1/2406; D06M 10/025; H05H 2245/40

(57) ABSTRACT

A system for treating an article. The system comprises a segment adapted to contain a local atmosphere and an internal pressure which is within the range of 90 kPa to 110 kPa. The segment comprising a module. The module comprising a pair of electrodes and a manifold for delivering a fluid to the pair of electrodes, wherein the electrodes are adapted to energise the fluid delivered from the manifold before being deposited onto the article.

### TECHNICAL FIELD

The present invention relates to a system which is adapted to treat articles. More particularly, the present invention may relate to a plasma treatment system which can apply at least one treatment or functional coating to a substrate or article.

### BACKGROUND

Fabrics, materials or textiles are used in everyday life throughout the world for a wide range of applications. Typically fabrics will be manufactured for use in clothing, but may have a wide range of uses in other applications. Depending on the application of the textile, there may be a number of desired functions the textile is to perform. As such, applying functional coatings, polymer coatings, films or performing other treatment processes is typically desirable.

Other articles into which fabrics may be manufactured as well are commodities, such as backpacks, umbrellas, tents, blinds, screens, canopies, tapestry, household textiles, sleeping bags etc. Fabrics are also utilised as filtration media articles for use, for example, in heating, insulation, ventilation or air conditioning systems or for use in exhaust filters, diesel filters, liquid filters, filtration media for medical applications and so on. Typically, insulation materials are non-woven, knitted or otherwise formed into materials with a regular fibre structure or regular arrangement of the fibres. The methods and processes of this invention are applicable to all such fabrics or substrates which may be used for these applications.

The use of ionized gases, which may be plasma, for treating, modifying and etching of material surfaces is well established within the field of fabrics. Vacuum-based plasmas and near-atmospheric pressure plasmas have been used for surface modification of materials ranging from plastic wrap to non-woven materials and textiles, the plasma being used to provide an abundant source of active chemical species, which are formed inside the plasma, from the interaction between resident electrons in the plasma and neutral or other gas phase components of the plasma. Typically, the active species responsible for surface treatment processes have such short lifetimes that the substrate 1 must be placed inside the plasma, which may be referred to as “in-situ” plasma processing. In this process a substrate is present together inside a process chamber in contact with the plasma so that the short-lived active chemical species of the plasma are able to react with the substrate before decay mechanisms, such as recombination, neutralisation or radiative emission can de-activate or inhibit the intended surface treatment reactions.

In addition to vacuum-based plasmas, there are a variety of plasmas that operate at or near atmospheric pressure. Included are dielectric barrier discharges, which have a dielectric film or cover placed on one or both of the powered and ground electrodes; corona discharges, which typically involve a wire or sharply-pointed electrode; micro-hollow discharges, which consist of a series of closely-packed hollow tubes that form either the radiofrequency electrode or ground electrode to generate a plasma. A flow-through design may be used by these devices, which consists of parallel-placed screen electrode and in which a plasma is generated by the passage of gas through the two or more screen electrodes; plasma jets in which a high gas fraction of helium is used along with electrical power and a close electrode gap to form an arc-free, non-thermal plasma; and a plasma torch, which uses an of an arc intentionally formed between two interposed electrodes to generate extremely high temperatures for applications such as sintering, ceramic formation and incineration.

The use of atmospheric pressure gases for generating a plasma provides a greatly simplified means of treatment for large or high volume substrates, such as plastics, textiles, non-wovens, carpet, and other large flexible or inflexible objects, such as aircraft wings and fuselage, ships, flooring, commercial structures. Treatment of these substrates using vacuum-based plasmas is complicated, dangerous and typically prohibitively expensive. The present state of the art for plasmas operating at or near atmospheric pressure also limits the use of plasma for treatment of these commercially-important substrates. Further, plasmas operating at or near atmospheric pressure are still limited by the use of a processing chamber in which a plasma is generated, which again may lower the production rate of commercially-important substrates.

A known atmospheric pressure plasma chamber is disclosed in U.S. Pat. No. 7,288,204 B2 in which there is taught a method for generating an atmospheric pressure glow plasma. This method utilises a plasma treatment within a treatment chamber and gases are blown into the chamber. This method has a number of functional problems with regards to being used outside of a chamber.

Other chamber plasma processing methods are also known, and will generally restrict the volume of substrate which can be treated in a single processing run due to the size of the chamber and also due to the application methods.

Other known plasma treatment devices include plasma torches, however these devices are generally destructive for most materials as the torch can achieve temperatures of up to 5,000° C. up to 28,000° C. during use. These devices are typically used for welding, cutting or other industrial purposes and typically have limited applications in treatment of substrates, but may be used depending on the substrate being treated and the desired processing.

Any discussion of the prior art throughout the specification should in no way be considered as an admission that such prior art is widely known or forms part of common general knowledge in the field.

### SUMMARY

### Problems to be Solved

It may be advantageous to provide for a system which provides for an improved treatment process.

It may be advantageous to provide for a plasma treatment system with removable electrodes.

It may be advantageous to provide for a system which can deposit nanoparticle coatings.

It may be advantageous to provide for an improved deposition system utilising plasma polymerisation.

It may be advantageous to provide for a system which is modular.

It may be advantageous to provide for atmospheric plasma treatments.

It may be advantageous to provide for a system which can treat materials and substrates within atmosphere.

It may be advantageous to provide for a system which can be used in open atmosphere conditions and pressures.

It may be advantageous to provide for a plasma treatment system which can function at pressures relatively above local atmospheric pressures.

It may be advantageous to provide for a system with improved processing speeds.

It may be advantageous to provide for a modular system which can retain internal pressures and/or fluids.

It may be advantageous to provide for a treatment module which can apply at least one coating or treatment.

It may be advantageous to provide for an improved monomer plasma polymerisation system.

It may be advantageous to provide for a processing system to apply a treatment to an article.

It is an object of the present invention to overcome or ameliorate at least one of the disadvantages of the prior art, or to provide a useful alternative.

### Means for Solving the Problem

In a first aspect there may be provided a system for treating an article. The system may comprise a segment adapted to contain a local atmosphere and an internal pressure which may be within the range of 90 kPa to 110 kPa. The segment may comprise a module with a pair of electrodes. A manifold may be provided for delivering a fluid to the pair of electrodes; and wherein the electrodes are adapted to energise the fluid delivered from the manifold before being deposited onto the article.

Preferably, the segment further comprises a bias means which may attract the fluids energised by the electrodes. Preferably, the module may be connected to a common rail which may be in fluid communication with a fluid reservoir. Preferably, the common rail further comprises an electrical connection to power the module. Preferably, the common rail may be adapted to mate with and releasably fix the module in a desired position. Preferably, an exhaust system may be disposed relatively below the modules such that at least a portion of the energised fluids which are not deposited onto the substrate may be collected. Preferably, the system may further comprise a lacing system for guiding a substrate adjacent to the modules. Preferably, the manifold comprises a plurality of inlet manifold tubes which may comprise a plurality of apertures for delivery of the fluid. Preferably, a conduit may extend into the inlet manifold tube. Preferably, the system further may comprise at least one of an atomiser, a vaporiser and an aerosoliser. Preferably, the pair of electrodes may be coated with a dielectric material. Preferably, the system may comprise at least two segments, wherein each segment may be joined at a seal to an adjacent segment. Preferably, an entry seal may be mounted onto a segment and adapted to seal the segment from external atmosphere. Preferably, the internal pressure of the system may be increased relative to ambient atmosphere by the introduction of fluids from the modules. Preferably, plasma may be formed between the electrodes when the fluid may be energised.

In the context of the present invention, the words “comprise”, “comprising” and the like are to be construed in their inclusive, as opposed to their exclusive, sense, that is in the sense of “including, but not limited to”.

The invention is to be interpreted with reference to the at least one of the technical problems described or affiliated with the background art. The present aims to solve or ameliorate at least one of the technical problems and this may result in one or more advantageous effects as defined by this specification and described in detail with reference to the preferred embodiments of the present invention.

### BRIEF DESCRIPTION OF THE FIGURES

FIG. 1 illustrates an isometric view of an embodiment of a system for treatment of substrates;

FIG. 2 illustrates a side view of a portion of an embodiment of a plasma system for applying coatings;

FIG. 3 illustrates a top view of an embodiment of a system for treatment of articles;

FIG. 4 illustrates an isometric view of a segment of an embodiment of the system;

FIG. 5 illustrates a top front view of an embodiment of a segment of a system;

FIG. 6 illustrates a front view of an embodiment of a segment comprising a module array;

FIG. 6A illustrates another embodiment of a system for treatment of substrates;

FIG. 6B illustrates an embodiment of a lifting system connected to a bias plate array;

FIG. 7 illustrates an isometric view of an embodiment of a module array which can be mounted in a segment;

FIG. 8 illustrates an isometric view of an embodiment of a plurality of modules in an array connected to a fluid rail;

FIG. 9 illustrates a top down view of an embodiment of a module array in communication with a common rail;

FIG. 10 illustrates an isometric view of an embodiment of a plurality of modules in an array above an exhaust plate;

FIG. 11 illustrates an isometric view of an embodiment of a plurality of modules in an array connected to a fluid rail;

FIG. 12 illustrates an isometric view of an embodiment of a plurality of modules in an array;

FIG. 13 illustrates a side view of an embodiment of an array of modules for treatment of an article;

FIG. 14 illustrates a section view of an embodiment of a segment without a housing which shows of exhaust plate and a module;

FIG. 15 illustrates an isometric view of a module which may be mounted within a system;

FIG. 16 illustrates an isometric view of a section of a module array with a portion of the manifold with connection spigots;

FIG. 17 illustrates an isometric view of a section of a module with a portion of the manifold removed;

FIG. 18 illustrates a sectional view of an embodiment of an array of electrodes which can be mounted in a segment used to form a plasma;

FIG. 19 illustrates a portion of an embodiment of a module wherein the electrodes and the inlet manifold can be seen as being mounted in a manifold block;

FIG. 20 illustrates a similar embodiment as that shown in FIG. 19, wherein the electrodes are removed;

FIG. 21 illustrates a perspective view of an embodiment of a manifold block and the seals for electrodes and inlet manifolds:

FIG. 22 illustrates a front sectional view of the system wherein a lacing system is shown;

FIG. 22A illustrates a perspective view of an embodiment of a lacing system which may be used to move a substrate though the system;

FIG. 22B illustrates another view of the embodiment of FIG. 22A;

FIG. 23 illustrates a perspective view of an embodiment of a system with an entry seal and an internal adjustment means for a substrate;

FIG. 24 illustrates a similar view as that shown in FIG. 23, however the housing of the segments has been removed;

FIG. 25 shows a side view of an embodiment of a seal and an adjustment means in a closed configuration;

FIG. 26 illustrates a similar embodiment of the seal and adjustment means as that shown in FIG. 25 but in an open configuration;

FIG. 27 illustrates a perspective view of an embodiment of a pair of rollers which can be used to seal a segment;

FIG. 28 illustrates a perspective view of an embodiment of a pair of rollers which are mounted to a segment;

FIG. 29 illustrates an embodiment of a cleaning tool which can be used to clean electrodes of a module;

FIG. 30 illustrates an embodiment of a cleaning tool engaged with a plurality of electrodes of a module;

FIG. 31 illustrates an embodiment of a cleaning tool engaged with a plurality of electrodes and has moved and cleaned a portion of the electrodes;

FIG. 32 shows an embodiment of a manifold block formed from a first portion and a second portion;

FIG. 33 illustrates another perspective of the embodiment of FIG. 32 without electrodes and manifolds connected;

FIG. 34 illustrates an embodiment of a first portion of a two portion manifold block; and

FIG. 35 illustrates a sectional side view of the embodiment of FIG. 32.

### DESCRIPTION OF THE INVENTION

Preferred embodiments of the invention will now be described with reference to the accompanying drawings and non-limiting examples.

### LIST OF FEATURES

1 Substrate
10 System
11A System entry
11B System exit
12 Winder/unwinder
15 Segment
18 Module array
20 Module
25 Frame
35 Electrode cooling system
37 Fluid delivery system
40 Fluid collection system/Recirculation system
50 High pressure region
55 Low pressure region
60 Injection assembly
70 Common rail
71 Interface
72 First fluid channel
74 Second fluid channel
76 Connection channel
77 Cavity
78 Ports
80 First region
82 Second region
84 Third region
90 Local region
95 Reaction gap
101 Electrodes
102 Core
103 Sheath
104 Electrode channel
105 Electrode manifold seal
106 Plasma region
107 Manifold
108 Manifold block
109 Inlet manifold
110 Inner manifold
111 Inlet manifold seal
112 Manifold outlets
114 Alignment means
118 Manifold fluid connectors
119 Fluid sealing means
120 Manifold electrical connector
121 Electrode electrical connector/busbar
122 Manifold mount
123 Manifold end caps
138 Module rack
140 Electrode rack
142 Electrode recess
144 Projection
146 Manifold rack
148 Manifold recess
150 Electrode portion
152 End portion
154 Seal
156 Conductive element
158 Securing means
160 Module housing
162 Side
164 Bottom
166 Weir
168 Alignment port
170 Lip
174 Electrode aperture
176 Manifold aperture
180 Adjustment means
181 Drive means
182 Lead roller
184 Second roller
186 Adjustment roller
188 Guidance roller
189 Adjustment means mount
190 Cleaning tool
192 Body
194 Protrusions
196 Scraping edge
200 Housing
203 Front wall
205 Top portion
207 Side portion
209 Sectioned portion
210 Bottom portion
215 Access
220 Housing support
225 Brace
250 Bias plate
255 Bias support
257 Flange
260 Bias support end
300 Sealing chamber
305 Seal
310 Sealing means
315 Lip
320 Corresponding surface
325 Hinge
330 Internal entry seal
331 Outer portion
332 Diaphragm
334 Pressure element
336 Bias chamber
338 Wall
339 Inner portion
340 Roller
345 Cover
347 Housing
350 Exhaust plate
355 Exhaust array
360 Exhaust system
370 Exhaust array connection
380 Combined exhaust
400 Lacing system
401 Body
405 Clamp
410 Elongate connection element
415 Support bar
418 Fulcrum
420 Actuators
422 Body actuators
425 Stopper
500 Lifting system
505 Lifting device
510 Lifting device member

System

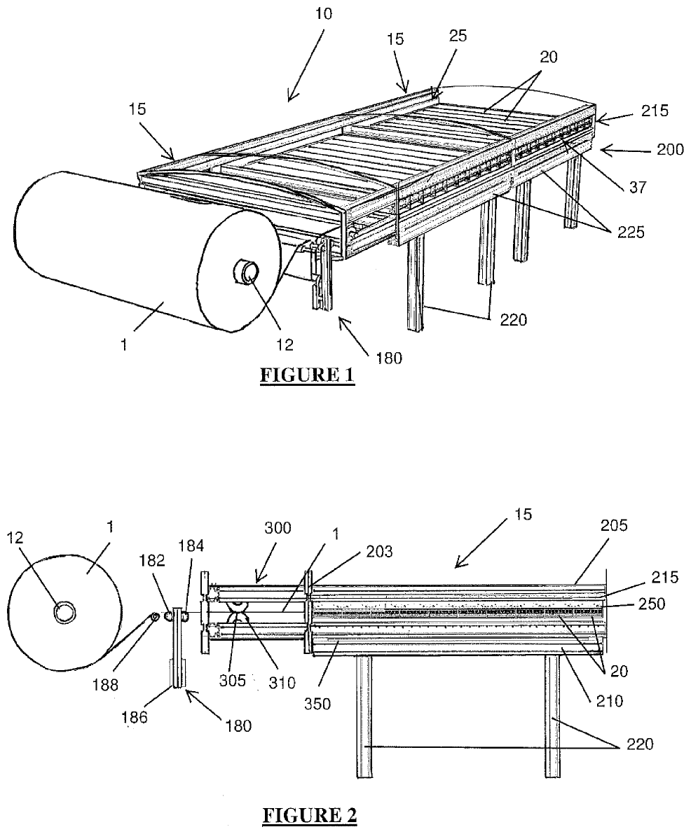

There is described herein a plasma system which may be used to provide coatings or treatments to materials. More specifically, the system 10 may have particular utility in processing substrates 1 or sheets of materials as is shown in FIG. 1. Other articles may also be treated by the system 10 which are not substrates 1. As such, it is not a limitation of the system to only be used in the treatment of substrates 1.

The terms ‘fabric’, ‘textile’ or ‘substrate’ may include any materials that are non-woven as well as woven or knitted textiles, which may be manufactured into articles, such as articles of apparel for; application in daily use, industrial environments, personal protective equipment (PPE), sport and leisure environments and any other common use for fabrics or textiles. For simplicity, the terms ‘fabric’ and ‘textile’ may be referred to herein as “substrate”. Substrates may include any planar material which may be processed. Optionally, in further embodiments the substrate 1 may be replaced with particulate materials or objects to be processed on a conveyor belt or similar transport apparatus, which may be of particular use in food processing or manufacture of medical devices.

Referring to FIG. 1, there is illustrated an embodiment of a system 10 adapted to treat a substrate 1. The system illustrated comprises a number of treatment modules 20 which are used to treat a substrate 1. While a roll of substrate 1 to be treated is shown being mounted to one side of the system 10, the system may be an in-line system which allows for continual processing and not only batch processing. The system 10 is formed from one or more segments 15 which are fixed together to form a treatment chamber. Each segment 15 may house one or more modules 20, common rails 70, an exhaust system 350 and a frame 25 which can be used to support the common rails 70. Treatment of the substrate 1 is affected by the modules 20, and each treatment segment 15 of the system may house one or more modules 20. The module 20 has a treatment face which may be used to treat substrates and articles, typically with the use of atmospheric plasma. If module 20 is used to form a plasma, the module 20 comprises a plurality of electrodes 101 and a fluid delivery system 37. The fluid delivery system 37 may be in the form of a manifold 107 which connects to a common rail within the segment 15. The fluid delivery system 37 may comprise a plasma gas delivery system and a fluid cooling system for the electrodes 101, for example. The common rail may extend within the segment 15 and be coupled to one or more fluid supply and the power supply. The modules 20 may be at least one of; shower head modules, spray modules, deposition modules, heating modules, or any other treatment module. Each module 20 may be removably mounted in the system 10 and be used to pre-treat, treat, coat, cover, heat, shrink, dye, radiate, deposit, activate or perform any desired treatment process to a substrate 1. Functional coatings may be applied by the modules, such as UV reactive property, a reflective property, luminescent coating property, a water-resistant property, a waterproof property, or another functional or visual property which may be known in the field of textiles.

Substrate 1 treatments may involve physical alterations, chemical alterations, coatings, application of films, surface activations, sterilisation, polymerisation or other desired treatment process. The system 10 may comprise any number of modules to perform said treatments.

A module 20 preferably comprises a module housing 160, a manifold 107, and at least one electrode 101. More preferably, the modules 20 comprise a plurality of electrodes 101 which are a combination of radiofrequency (RF) and ground electrodes, or positive and negative electrodes 101.

Fluids can be provided to the manifold 107 via a common rail 70. The fluids may comprise at least one fluid selected from the following group; a precursor gas, a monomer, a sol-gel, a nanoparticle solution, a fluid with a nanoparticle, a delivery gas, a treatment chemical, a treatment compound, a hydrophobic fluid, a hydrophilic fluid, a pigment, a dye, as sterilant, or any other predetermined fluid for supply to a substrate 1.

A power supply may be directly coupled with the module 20, or may be connected to the common rail 70 to power the module 20. Each module 20 can be activated, deactivated, altered or otherwise manipulated by a user of the system 10 for a desired treatment process as desired. The power supply may be used to supply a desired power, frequency and voltage to the electrodes. Optionally, more than one power source can be used, with a first power source which can be used to strike a plasma and a second power source adapted to maintain a plasma which has been struck. In this way the first power source may be adapted to deliver a higher voltage relative to the second power source, or vice versa.

Electrodes 101 may be formed from with a core 102, a sheath 103 and a channel 104. The core 102 being a conductive material, such as copper or stainless steel for example, and the sheath 103 being a dielectric material. The core 102 may be any conductive material which can withstand heating to temperatures which are greater than or equal to that of the plasma formed in the plasma region 106. The sheath 103 selected is to be formed from a dielectric material which can encompass or encapsulate the core material to reduce arcing and assist with stabilisation of plasma formed in the plasma region. A substrate 1 is shown as passing relatively between the modules 20 and the bias plate 250 which can treat a substrate 1. It will be appreciated that the plasma may not be in direct contact with a substrate 1 to treat the substrate, and ionised gases, fractionated monomer, polymers, and monomers can be urged towards or flow towards the substrate 1 to be deposited thereon or may interact with the substrate 1. Without charge to ionise a delivery gas, an ionised gas may return to an uncharged state within a relatively short period of time, generally in the matter of seconds to minutes. In yet another embodiment, the distance between the module 20 and the substrate is between 20 mm to 0.1 mm, but more preferably between 10 mm to 1 mm, such that as the substrate 1 moves relative to the module 20. The module housing 160 of the module may be used to support or suspend the substrate 1 above the electrodes, rather than the substrate being suspended above all components of the module 20.

The desired temperatures within the system 10 may be in the range of 0° C. to 70° C., but are more preferably in the range of 0° C. to 40° C. The temperature within the segment 15 of the system is preferred to be less than 40° C. Reducing the temperature within the segment 15 may allow for an improved coating to be imparted relative to a higher temperature coating. An improved coating may relate to an end functionality of the coating, and/or the thickness of the coating. For example, it may be preferred that the temperature of the substrate be generally around 0° C. to 35° C. when having a coating applied thereto as this may increase the deposition rate of the coating via the plasma process, and/or improve the end functionality of the coating being applied.

In yet a further embodiment, the functionality may be improved when the substrate temperature is greater than 60° C., however the coating thickness may be diminished relative to a coating applied with a substrate temperature less than 35° C.

Substrate temperatures are preferably controlled with cooling of the electrodes 101 and/or the bias plate 350 and/or the atmosphere of the system segment 15. It is preferred that the surface temperature of the substrate is less than 100° C. for an ideal coating thickness and functionality. In another embodiment, the substrate temperature may exceed 100° C. for a predetermined precursor or a desired functionality.

Optionally, an air gap or fluid gap may be provided around the core which can assist with cooling and dielectric properties of the electrode 101. For example, air or inert gas may be used as a cooling fluid which may be passed between the electrode core 102 and the sheath 103. In another embodiment, the electrode 101 is provided with one or more fluid cooling channels or a cooling channel which is used to cool the electrode 101. The dielectric may comprise a material such as PET, PEN, PTFE or a ceramic such as silica or alumina. In at least one embodiment the electrodes are formed with an alumina sheath 103.

While electrode sheaths 103 may be a rectangular shape or circular shape, the core 102 may be any predetermined shape which may or may not correspond with the shape of the electrode sheath. For example, an electrode 101 may be a blade type electrode 101 which has a rectangular sheath cross section, however the core may be circular or any other predetermined shape. Fluid conduits may have any predetermined cross section which is sufficient to cool the electrodes 101 effectively, and may include shapes such as a regular shape, a sinusoidal shape or a waveform shape cross section. The general shape of the sheath may define the type of electrode 101 regardless of the cross section of the core 102.

It is preferred that the electrodes 101 have a uniform spacing such that corona discharges are less likely to occur during use which can damage electrodes 101. Spacings may have a maximum distance such that a desired plasma density can be formed. Further, it is preferred that the electrodes 101 comprise a uniform diameter or cross-sectional area.

The space between the electrodes 101 may be referred to as a reaction gap 95, wherein a reaction of a monomer and plasma between electrodes may be observed, or where polymerisation occurs. The plasma region(s) 106 is formed within the reaction gap 95, and may fill the entire reaction gap 95, or a portion thereof.

The manifold outlets 112 may be fitted with a sealing means to stop or restrict flow of a fluid via outlet 112. This may be advantageous in the event of an emergency stop of the system 10 as the sealing means can prevent further delivery of fluids and contain potentially flammable fluids or hazardous chemicals. Sealing means may be actuated by a controller connected with the module 20 or may move into a sealing position in the absence of a current if there is an emergency stop of the system 10. The sealing means can be actuated to open or restrict flow of a fluid to allow for greater fluid delivery control to a substrate. Optionally, manifold outlets 112 can be fitted with nozzles, grills, meshes, or fixed flow restrictor means to control the flow of fluids. The flow of fluids may also be increased or decreased by internal pressures within the chamber 116 or the pressure from the fluid inlet 107. A pressure valve may also be provided to the module 20 to increase or decrease internal pressures which may assist with controlling the flow rate of the fluids for treatment. Alternatively, the fluid inlet 107 is coupled with a manifold 107 which can distribute fluids via fluid conduits 110 within the module housing 160. Fluid conduits may be in fluid communication with one or more chambers 116 which may allow for more effective distribution of fluids. The manifold 107 may be adapted to provide more than one fluid to a chamber 116 or directly to the manifold outlets 112.

Optionally, a fluid reservoir (not shown) can be mounted to a module 20 which is filled with a desired fluid, such as a treatment fluid or dye. The desired fluid can then be allowed to flow from the fluid reservoir through the module 20 and be provided to a substrate 1 via the manifold 107. The fluid reservoir may be a mountable tank of fluids which can be used for treatment processing and can be easily swapped or replaced between processing or during processing. The fluid reservoir may be similar to the fluid supply in that it can provide a fluid to a module 20, and that the reservoir can be filled while in use such that processing need not stop. It will be appreciated that some modules 20 may be fitted with multiple mounting means to allow for more than one fluid reservoir to be mounted to the module 20. This may be of particular advantage in relation to fluids which are required to be mixed immediately prior to application to a substrate 1.

The mounting location for a fluid reservoir may be a keyed fit such that only predetermined reservoir connectors can be mated with the module 20 which may prevent users from mounting fluids which are not to be used with predetermined modules 20. For example, a dyeing module 20 may not allow functional coating chemical fluid reservoirs to be mounted with the module 20. Optionally, a key can be used to lock the fluid reservoir to the module 20 which may also provide for a further safety means which may prevent mounting of a reservoir which is not to be used with a module 20. Further a key can be used to lock and/or connect the fluid supply with other components of the fluid delivery system 37. Optionally, the reservoirs can be fitted with an RFID or similar authentication means which can be recorded with the system to verify that the reservoirs are authorised to be mated. Fluid logs may also be used to record the volume of fluids which enter into the system 10 from a specific fluid reservoir. In this way the volume of fluids used can be monitored and reminders or other notifications to users can be triggered to ensure that fluid reservoirs are replaced before being emptied or if remaining stocks are low. Preferably, the number of fluid reservoirs in stock may also be logged or recorded with the system and automatic reorders or notifications to reorder more fluids may be triggered based on historical consumption of fluids. For example, if the system 10 in the previous 30 days has used an average of 5 litres of fluids per day, the system may issue a notification when lead times for reordering fluids is within a predetermined threshold. If for example, the current lead time for ordering more fluid reservoirs is 5 business days, the system may be adapted to issue alerts or warnings based on this known information. Alternatively, the system 10 may trigger alerts which are several days or weeks ahead of supply runouts to ensure that the systems can remain operational.

In another embodiment, the system may be adapted to record, log or determine the length of treated substrate 1, or the number of articles which are treated by the system. This can assist with auditing goods treated by the system 10. Optionally, the system may be adapted to identify predetermined materials within the system and only activate the treatment modules when the predetermined material to be treated is identified as being within the system. This can reduce the potential for incorrect treatments to be applied to substrates or articles.

In at least one embodiment, the manifold outlets 112 may impart a desired effect to the fluids when exiting said outlets 112. Each of the manifold outlets 112 may comprise a nozzle which is adapted to dispense fluids in a desired manner, or may be configured to function similar to that of a fluid injector. For example, the fluid released from manifold outlets 112 may be a mist, a stream, vaporisation, aerosolization, a pulsed fluid release, a bead, a droplet or any other ejection or release of fluids. It is most preferred that the manifold outlets 112 are adapted to dispense, eject, distribute or otherwise provide a fluid evenly to a substrate 1 surface. If there are applications in which the substrate surface 1 is to be unevenly coated, the module 20 may be adapted to provide said uneven coating.

The housing 160 of at least one module 20 is preferably shaped to allow for further modules 20 to be mounted adjacently. Each module housing 160 may be fitted with a mounting means to allow for adjacent mounting of modules and mounting to a frame (not shown) of the system 10. Alternatively, a mounting means can be used to mount the modules in a desired manner in the system 10.

Module housings may be secured to racks internal the module 20. Portions of the housing 160 may be accessible without dismounting the modules from the system. This may allow for replacement of internal components, such as heating elements, electrodes or blocks. Further, portions of the housing may be removable if multiple modules are mounted adjacently in a module series. This may allow for electrode 101 mounting or heating element mounting at, or near to, the area in which the housing was removed.

A desired fluid flow may be imparted by the fluid delivery system 37 for providing fluids to the electrodes and subsequently to the substrate. Optionally, the fluid delivery system may be tuned to impart a waveform or wave flow to the fluids being delivered to the module 20 which may assist with a desired flow of fluids to the plasma region 106. A sonic wave may be used in the fluid flow to impart such a wave. Preferably, fluid outlet 112 or fluid conduit 110 may be used to impart said desired fluid flow. It is preferred that if fluids are expelled from a module that the fluids have a laminar flow. As discussed above, if the fluid delivery system 37 comprises chamber, the chamber may be shaped to impart a desired fluid flow to fluids being ejected via the outlet 112 module 20. A desired flow may be a turbulent flow, or a laminar flow for example. It is preferred that if fluids are expelled from a module that a laminar flow may be preferred to more effectively treat a substrate. It is preferred that multiple manifold outlets 112 are provided for each module 20 adapted to release fluids, however a single outlet 112 may be desirable depending on the function of the module 20. Reference will be made herein to modules 20 comprising a plurality of manifold outlets 112.

In another embodiment, the manifold may comprise a dispersion plate rather than a series of manifold inlets. The plate (not shown) can be used to distribute delivery gases or any other desired fluids to the electrodes 101 such that the delivery gases and/or fluids can be used to treat a substrate 1. Preferably, any arrays of electrodes or apertures may be used which are aligned to allow for fluid to be effectively distributed to a plasma region 106.

The dispersion plate may be in the form of at least one of; a grill, mesh or sheet comprising a plurality of apertures or channels through which fluids can be urges or expelled from the manifold 107. The plate may be mounted relatively parallel to the plane of the electrodes 101 if the plate is a linear dispersion plate. The array of apertures may correspond to a desired deposition pattern to be imparted to the substrate 1. The plates may comprise uniform apertures, or a predetermined array of apertures for uniformly distributing fluids form the manifold block 108. Each region 106 formed by the electrodes 101 may be selectively turned on or off during use to allow for different rates of polymerisation or different polymerisation effects. The fluids provided via the manifold may also be selectively turned off, or apertures 112 of the manifolds may be opened, closed, dilated or otherwise restricted to allow only a predetermined volume of fluids to be provided to the plasma region 106 or electrodes 101.

The substrate 1 to be treated may be, for example, a textile, a fabric, a woven material, a non-woven material, a foil, a polymer, a sheet, or any other desired material which can be provided to the system in sheets. As the substrate 1 is passed through the system 10, the substrate can be processed and/or treated by at least one module 20 of the system 10.

Conventional plasma treatment apparatuses generally require a vacuum chamber or a chamber in which an object is to be treated. Further, there are a number of problems associated with the use of plasma in non-vacuum chambers or in areas which are not within vacuum chambers. One such problem is even distribution or uniform distribution of delivery gases and monomers contained therein without the presence of a vacuum. Another problem is the introduction of fluids into the plasma region 106 or reaction region 106 which may cause polymerisation of dangerous/undesired molecules or ionisation of molecules which may damage a substrate 1 being processed or impact the quality of the treatment. In contrast, the system 10 is preferably adapted to generate a plasma in atmospheric conditions and/or positive pressure conditions which are above atmospheric pressure. For example, the atmospheric pressure within the system may be between 1 atmosphere (approximately 100 kPa) to 1.1 atmosphere pressure (approximately 115 kPa). Other pressures may be used internally, but are preferred to be at or near to atmospheric pressure. In yet another embodiment, the internal pressures within the system are in the range of 98% atmosphere to 105% atmospheric pressure. In a further embodiment, the pressure internal the system chambers may be increased by between 0.5% to 2.5% relative to external atmospheric pressure of the system.

It will also be appreciated that the internal pressures of the system 10 may be in the range of between 95% atmospheric pressure to 105% atmospheric pressure (around 95 kPa to 105 kPa), or more preferably in the range of 98% to 102% atmospheric pressure (around 98 kPa to 102 kPa). Other pressures above 1 atmosphere may also be used to allow for a higher internal pressure relative to the outside of the system. The internal pressures of the system may be desired to be relatively higher than those of the ambient atmosphere, such that fluids are likely to flow from high pressure regions, internal the system, to lower pressure regions, outside the system. In this way the fluids distributed inside the system 10 may be more pure with a reduced potential for outside, or non-controlled, fluids from entering into the system. While the higher pressures are desired, it may also be possible to supply fluids to the local region 90 without sealing the system segment from the ambient atmosphere and maintaining a desired fluid purity or quality.

Modules

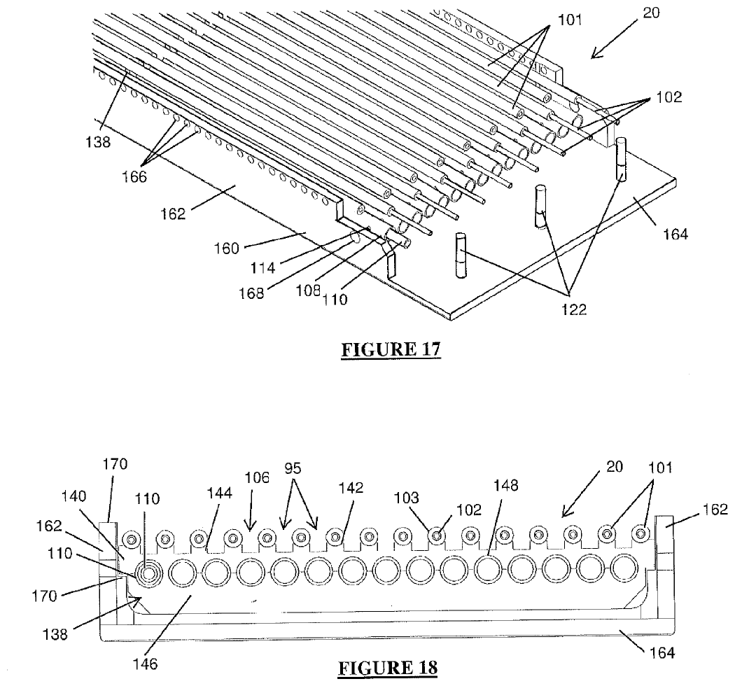

The module 20 comprises a module housing 160 which houses the electrodes 101. The module housing 160 is preferably U-shaped, similar to that shown in FIG. 17 or 18, or is formed with at least one open side such that fluids from a manifold 107 can be supplied to a substrate 1. The module housing may comprise side walls 162, a bottom 164, a plurality of weirs formed in the side walls and/or the bottom. An alignment port 168 may also be provided within at least one of the side walls which can be used to ensure alignment of the inlet manifold 109 alignment means 114 with the alignment port 168. The alignment means 114 and alignment port may be adapted to receive an elongate element which may be used to urge the inlet manifolds 109 into an aligning relationship with the alignment port 168. Similarly, the electrodes may also be formed with an alignment port (not shown) and can be used to align electrodes if they are not a circle or similar regular geometric shape. The module housing 160 is preferably formed from a non-conductive material or is earthed to reduce potential arcing.

The manifold 107 comprises at least one manifold block 108 and a plurality inlet manifolds 109. The inlet manifolds may be longitudinal tubes with one or more apertures 112 in each tube to allow for the distribution of fluids. The one or more apertures 112 may be at least one of; evenly spaced, evenly sized, non-uniformly sized, sized according to a predetermined pattern or array, unevenly spaced, or unevenly sized. The apertures 112 may be selected to ensure the even flow of fluids from the manifold to the electrodes 101. The apertures 112 may be of a regular spacing, an irregular spacing, a uniform aperture diameter or with a differential aperture diameters or cross-sectional areas. Apertures 112 may be of any predetermined or desired shape to impart a desired fluid flow. Apertures may also be bevelled or chamfered on at least one side to impart a fluid flow from the inlet manifold 109.

Each of the inlet manifold 109 tubes may be evenly sized, or may be unevenly sized to assist with a desired gas flow or fluid movement within the module. The channel of the inlet manifold 109 may be adapted to receive an inner manifold 110 which is perforated or comprises a plurality of apertures which can be used to fill the inlet manifold 109 with fluids such that the distribution of fluids are relatively more evenly distributed. The apertures 112 of the inner manifold 110 may preferably be disposed to face the inner wall(s) of the inlet manifold 109. Inlet manifolds may extend from a first manifold block 108 to a second manifold block 108. Each of the manifold blocks may be adapted to supply fluids to the inlet manifolds 109 and may allow for fluids to be recirculated or passed to a recycling system, particularly the cooling system for the electrodes 101.

Optionally, the manifolds 108 are sized such that a respective manifold tube can be installed relatively below the plasma regions such that the fluids can be directed into the plasma regions. Polymerisation, activation, curing or reaction of fluids can occur within the plasma regions between the electrodes 101.

The cross-sectional area of the inlet manifold 109 and the electrodes 101 may be independent, but preferably can be spaced to allow for manifold apertures to direct fluids to the region between the electrodes 101.

Optionally, the electrodes 101 are disposed within the same plane. Optionally, the manifold tubes can be disposed within the same plane, or may be staggered to allow for sufficient injection of fluids to the electrodes 101.

The manifold block 108 fluid connectors allow for fluids to be delivered from the common rail to the module 20. If a module 20 is removed from the common rail, the common rail 70 is adapted to seal the common rail 70 fluid ports 78. The common rail 70 also has connection means or ports to allow for electrical connection via the manifold electrical connector 120.

Manifold fluid connectors 118 or spigots of the manifold 107 may be fitted with a fluid sealing means 119 which can be used to prevent the leaking of fluids between the common rail 70 and the manifold block 107. Electrical connectors 120 may also be fitted with an insulating means to reduce the potential for arcing to occur.

In another embodiment, the system 10 is provided with a pre-treatment module 20 which may clean or activate a surface of an article or substrate before treatment with a polymer, nanoparticle or other coating.

The plasma region 106 is a region in which a plasma can be formed, such as the area between two electrodes 101. It will be appreciated that the plasma region may selectively have plasma present. The surface of a substrate 1 may be activated by a plasma region 106 which can allow for an improved adhesion of a subsequent coating, such as a chemical or physical coating. Activation of a surface of a substrate 1 may also change the surface properties of said substrate 1. For example, functional coatings may be modified or the surface of a substrate may be modified by passing a substrate 1 under, near to or through an electromagnetic field, a radiation source, a plasma field or by passing a substrate 1 under or over a treatment module 20. A module 20 is preferably used by the system 10 and generates a plasma region. The plasma region 106 may optionally be a plasma field in which electromagnetic fields influence the plasma of the plasma region in a desired manner.

In at least one embodiment it is preferred that the plasma generated in the plasma region is an atmospheric-pressure plasma glow (APG). APG may be encouraged by introducing a monomer into a plasma region 106, or may be encouraged by introducing a Penning mixture into the plasma region. The monomer may be used as a low ionisation fluid which can form part of the Penning mixture with a plasma gas. In some embodiments, the plasma gas is an argon gas and the monomer selected for polymerisation has a lesser ionisation threshold.

Optionally, the inlet manifold 109 may be replaced with fluid injectors and may be configured to disperse known volumes of fluids at a desired interval. A delivery gas and a precursor, which may be a monomer or another plasma reactive species, can be mixed near to the electrodes 101 with the use of gas injectors and ensure that the monomer is predominantly in a vapour or aerosolised state when injected into the plasma region 106 which may assist with reducing monomer build up in the system 10. In addition, the use of fluid injectors may allow for the selective treatment or coating of an area on a substrate 1 rather than providing a coating to the entire surface of the substrate 1. Further, fluid injectors may allow for more accurate coating or treatment of a substrate in some treatment processes.

As the module 20 can be used in atmosphere, the delivery gas for generating a plasma in the plasma region 106 may be pumped into the local region 90 (region between the substrate and the module) for a predetermined amount of time such that local atmosphere is evacuated from the local region 90 before igniting the delivery gas such that local atmosphere molecules are not ionised or activated. Purging local atmosphere of the system 10 may also allow for a high assurance of known substances within the system 10, and may also be desirable to allow for more predictable interactions of ionised matter and improve functional treatment properties.

Polymerisation and/or re-polymerisation of a coating may also be achieved by passing a substrate 1 under a plasma. Other pre-treatments may include treatments with an electromagnetic field, or the supply of a sterilant gas to a substrate, such as ozone, ethylene oxide, or hydrogen peroxide. Other sterilant gases may also be used by the system with appropriate safety provisions. It is preferred that any undeposited or unconsumed fluids from a module 20 may be captured and recycled. Recycling monomer, polymer and fluids from the treatment module 20 may allow for feeding of these fluids back into the treatment module 20 such that they can be recycled by a fluid collection system 40 until they are consumed or taken out of the system 10. The fluid collection system may comprise the exhaust systems and conduits therefor, such as exhaust plate 350, exhaust system 360, pumps and recycling and/or filtration means, collection reservoirs, and any other means which assists with collection of fluids from the system segments 15.

The electrodes 101 of the module 20 can be charged such that when a delivery gas is provided between or near to the electrodes 101 and a plasma region 106 can be created. The frequency and amplitude of the electrodes 101 will depend on the delivery gas provided to the electrodes 101 and/or depend on the substrate 1 to be treated by the plasma region 106.

At least one further fluid may be provided to the plasma region 106 which is carried by the delivery gas, or injected directly into the plasma region 106. The combination of the delivery gas and the further fluid may form an aerosol if the further fluid comprises droplets or the further fluid may be a vapour. The further fluid may be used to treat a substrate 1 or apply a coating to a substrate 1. The further fluid may additionally include particles and/or nanoparticles which can form at least one of; discrete clusters of nanoparticles, an even dispersion of nanoparticles on a substrate or may be used to form a film. Particles can be dispersed within a precursor, and may be evenly distributed to allow for an even or more uniform treatment. Particle sizes may be in the range of mm to 300 micron, and may have a mean particle size in the range of 10 nm to 250 nm. Other particle sizes may also be dispersed within a precursor, and may be used to impart a functional property to a substrate, such as biocidal properties, conductive properties, hydrophobic properties, hydrophilic properties, self-cleaning properties and any other desired properties for substrates or articles.

In one embodiment, the further fluid may be a monomer which can be polymerised within the plasma region 106. If a delivery gas and at least one further fluid are provided to the module 20 the fluids are preferably mixed together in a desired ratio such that a known amount of further fluids can be delivered to a target article or substrate 1.

The distance between the electrodes, may be referred to as the discharge space and defines the plasma region. The discharge space may be in the range of 0.1 mm to 10 mm. The volumetric gas flow rate may be within the range of 1 L/min and 50 L/min, but more preferably is within the range of 5 L/min to 15 L/min. Optionally, the electrodes 101 may be coated with a thin dielectric layer rather than having a sheath 103 made entirely from a dielectric material. The thickness of dielectric layer on the electrodes may be in a range of 1 μm to 1000 μm, but in one embodiment may be between 250 μm to 500 μm. It will be appreciated that the sheath 103 may have thickness of between 0.1 mm to 5 mm, from the outer surface to the core 102 of the electrode 101, and be formed entirely from a dielectric material, or laminations or layers of dielectric material. The stability of the plasma generated may be affected by the surface of the dielectric and the thickness of the dielectric. For example, organic dielectrics, such as PEN or PET, may be used to provide for better plasma stability in comparison to other dielectrics used.

A substrate 1 or textile to be processed can be initially disposed outside of the plasma region 106 generated by the module 20, and passed into plasma regions 106 formed by the electrodes 101. The substrate 1 is preferably maintained at a predetermined distance from the electrodes 101, or may be exposed to contact to the electrodes for some treatment methods. It will be appreciated that the electrodes 101 may be moved relative to the substrate 1 such that a desired effect can be imparted to the substrate 1. In this way portions of the substrate may be activated, sterilised or treated with a predetermined pattern or array. Flowing fluids, preferably gas, aerosol, vapour and/or a spray/mist of liquid, can be provided via the manifold 107 to the plasma region 106 between the electrodes 101 to generate plasma. Fluids entering into the plasma can be fractionated and/or excited by the plasma and may then flow onto the substrate 1.

In an embodiment, the densest plasma can be formed between the shortest distance between the electrodes 101. It is preferred that the fluid flow from the outlets 112 flows through at least one dense plasma region before deposition on the substrate 1. As the fluid passes through the plasma region 106, the fluids can be excited, and potentially fractionated to form reactive species which can polymerise to form a functional coating.

The substrate 1 may be moved through the system using an appropriate moving apparatus, such as winder 12, which can physically move the substrate 1 through the system 10. Any conventional substrate 1 movement equipment may be used with the system 10. Optionally, the substrate 1 may be fixed, mounted, clamped, held or pinned to a movement apparatus to be moved through the system 10. The system 10 may be fitted with a lacing system 400 which can receive the substrate 1 to be treated and pass the substrate 1 through the system 10 to be in a position which is in a pre-treatment position. Alternatively, the lacing system may be used to take a substrate through the length of the system 10 and to the exit seal 305. The lacing system 400 may have a clamp 405 or other fixing means to temporarily retain or hold the substrate 1 in a position in which it can be taken through to a desired location in the system or to a seal 305. It will be appreciated that the adjustment means 180 or tension means within the system 10 can be actuated such that the path of the lacing system is generally unobstructed, as is shown in FIG. 26, for example.

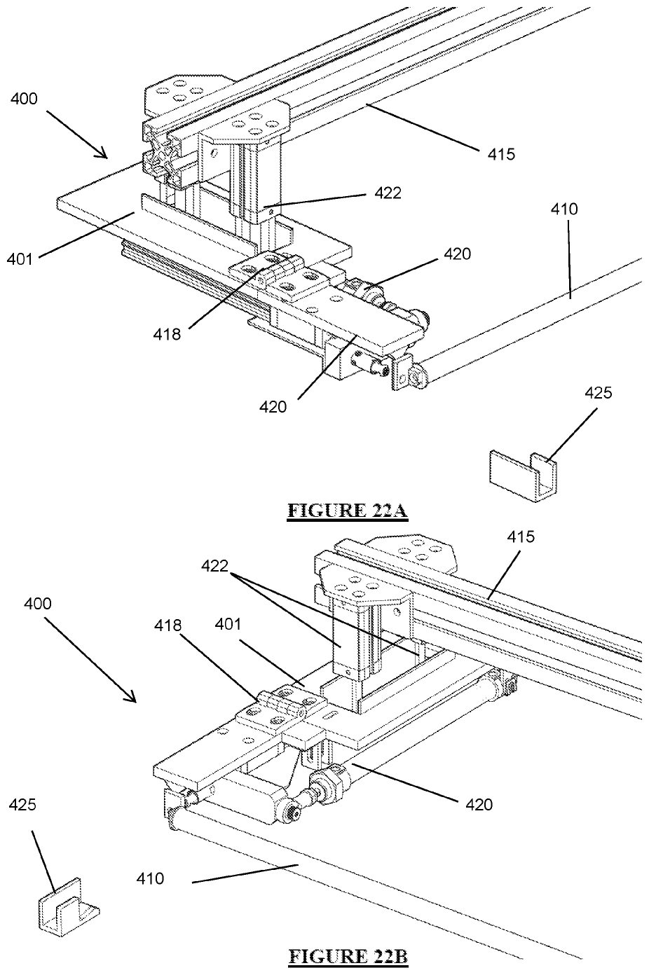

An embodiment of another lacing system 400 is shown in FIG. 22A and FIG. 22B. the lacing system 400 comprises an elongate connection element 410 which is adapted to mate or be attached with a substrate 1 such that the lacing system can move the substrate 1 through the system 10.

The lacing system 400 may have one or more actuators 420 which can be used to extend the relative position of element 410 such that the element can be extended past an airlock or other sealing mechanism to allow for a substrate to be mounted without compromising the internal atmosphere of the system 10. The actuators may be fixed to a lacing system body 401 which is adapted to move along a rail (not shown) from a first position in the chamber to a second position in the chamber. Preferably the first position is near to the entry rollers or entry of the system, and the second position is near to the exit rollers or the exit of the system. The lacing system 400 preferably has a first body 401 and a second body 401 which are on opposing side of the chamber, and are mounted to respective rails or tracks. A support bar 415 may extend between the rails or tracks for the lacing system to provide a rigid support for the first and second body. The body 401 may be moveable up and down relative to the support bar 415 by body actuators 422. Support bar 415 may span between the rails for the lacing system 400. The body actuators 422 may be mounted to the support bar to move the body 401.

Actuator 420 may be used to rotate or move the element 410 relatively upwardly via a fulcrum 418 such that it may be mounted in a guide, or pass over a stopper 425. Optionally, more than one actuator 420 may be used to achieve the desired extended position of the element 410. Optionally, element 410 can be replaced with a clamp 405 or may be used in combination with a clamp or other gripping means.

A door or opening may be provided in the entry and/or exit of the system adjacent the rollers. The door or opening may be provided in the roller system, or the housing to allow for passing the element 410 or clamp 405 through to allow for operators to mount the substrate 1 while allowing for closure of the seals or rollers 340 of the system 10 to prevent or reduce loss of internal atmosphere.

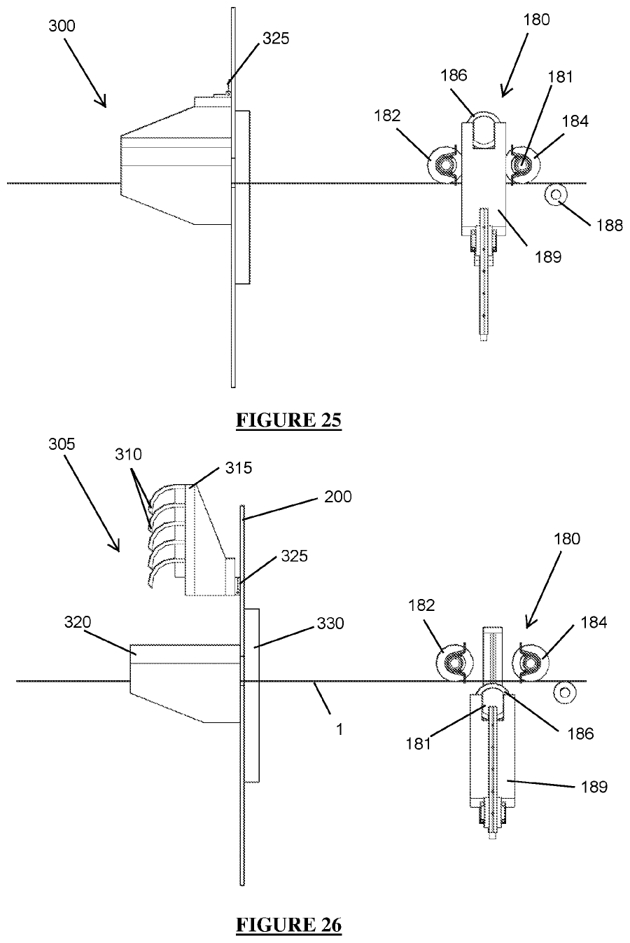

The adjustment means 180 may be positioned at any desired location within the path of the substrate 1, and may be within the segments 15 or may be outside of the segments 15. The adjustment means may be adapted to apply a tension to the substrate 1 and may also be used to pull the substrate 1 through the system, or assist with doing so. The adjustment means 180 may be fitted with at least one roller which may be used to apply a tension to the substrate 1, which may be in the range of 1N to 50N. Other tensions may be applied if desired, depending on the substrate to be treated. Adjustment means 180 such as the one illustrated in FIGS. 25 and 26 are preferably used for flexible substrates 1. A lead roller 182 and a second roller 184 may be positioned either side of an adjustment roller 186. The adjustment roller 186 may be adapted to maintain a desired tension to the substrate 1 and may be used to increase or reduce the tension to one portion of the substrate 1 relate to another portion of a substrate 1, which may be of advantage when a roll-to-roll system is treating a substrate with an uneven winding tension. An adjustment means mount 189 may be used to mount the adjustment roller 186. A motor (not shown) may be mounted to the adjustment means mount 189 for driving the adjustment roller 186. A guidance roller 188 may be positioned either side of the adjustment means 180 to guide the roller to a desired level of the system.

The adjustment roller 186 may be adapted to be displaced relative to the plane defined by the axis of the lead roller 182 and the second roller 184. In this way the adjustment roller can be positioned relatively lower than the rollers 182, 184 such that the lacing system (FIG. 22) may be passed between the adjustment means rollers in a generally linear manner. Further the guidance roller may also be adapted to be displaced relative to the rollers 182, 184 and may move in any desired direction. The guidance roller movement may align the substrate 1 with the local region 90 between the bias plate 250 and the modules 20. When the lacing system 400 can pass between the rollers to lace a substrate, this is considered to be an open position, as is shown in FIG. 26. When the adjustment roller 186 is displaced to a position which could apply a tension to a substrate laced the system is in the closed configuration, as is seen in FIG. 25. A rail may be used to guide the adjustment roller 186 between the open and closed positions. The rollers may be similar to any rollers known in the art and may be provided with any predetermined coating or material. The guidance roller 188 may optionally be a bent or “banana” type roller which can also apply a tension to the substrate 1.

The fluid delivery system 37 is used to supply a common rail 70 with fluids, which are subsequently supplied to the manifold 107 of the modules 20. The fluid delivery system 37 may comprise a fluid inlet connected to a manifold 107, and the manifold being in fluid communication with at least one fluid conduit. One or more fluid supplied may be connected to the fluid delivery system 37 such that fluids can be mixed by the fluid delivery system 37 before being provided to a plasma region 106. Optionally, multiple fluid manifold outlets 112 may be provided, with each fluid outlet 112 being used to provide a discrete fluid to the plasma region 106. For example, a first fluid outlet may provide a delivery gas, and a second fluid outlet may provide a monomer to the plasma region 106. The above configurations may be of particular advantage when supplying a monomer to the plasma region 106. Fluids may be received by the module 20 via the common rail 70 through the manifold block 108 and out of the manifold outlets 112 inlet manifold 110. The fluid delivery system may be used to impart a desired pressure to the fluid which may be used to regulate flow from the module. It will be appreciated that the system 1 may be adapted to dynamically adjust pressures flow rates during processing. The desired pressure may be within a predetermined range and may be a constant pressure or continuous pressure. The outlet 112 may be a fluid channel or may be a plurality of apertures spaced apart along the length thereof, such that fluid (delivery gas) emerges from the outlet 112 through an electrode pair 102, 104 discharge region which can ionise the gas and travel to substrate 1 through the local region 5. The plasma formed between electrodes 101 may be used to polymerise a monomer which has been provided to the plasma. The monomer may be polymerised at the surface of the substrate such that the polymerisation forms a bond with the surface of the substrate at the time of polymerisation. It will be appreciated that some monomers may be polymerised in the plasma region 106, in the local region and on the surface of the substrate 1, such that the polymerised monomers bond with the surface of the substrate 1.

In yet another embodiment, the system 10 has at least one pair of electrodes 101 having at least one elongated planar surface with the respective elongated planar surfaces being disposed adjacent and parallel to each other.

The system 10 includes a power supply which can power at least one first electrode 101 and a second electrode 101. The first and second electrode 101 may form a pair of electrodes. A cooling system can supply a source of coolant having a chosen temperature for cooling the first electrode and a second electrode. A fluid delivery system 37 adapted to supply a source of delivery gas to the first electrode and/or the second electrode via a gas manifold and/or fluid conduit 110. A plasma region 106 is generated between the first electrode and the second electrode when the delivery gas is ignited. The plasma region 106 defined by the space between the first electrode and the second electrode. The ionised or activated gases may exit the plasma region generally perpendicular to the surface of a substrate 1 to be treated. An atmospheric-pressure plasma (±2%) can be formed the plasma region 106. The distance between the bias plate 250 and the electrodes 101 of the module 20 may be referred to as the local region 90, or if there is no bias plate, the distance between the substrate 1 and the electrodes 101 may be referred to as the local region 90. As the module 20 for generating plasma regions can be used in atmosphere, the delivery gas for generating a plasma in the plasma region 106 may be pumped into the local region 90 for a predetermined amount of time such that local atmosphere is evacuated from the local region 90 before igniting the delivery gas such that local atmosphere fluids are not ionised or activated. Modules 20 may be fitted with at least one sensor to detect whether the manifold is supplying sufficient fluids and/or the concentration of the fluids A sensor may be provided in the local region to detect whether a delivery gas in the plasma region can be ignited.

The cooling system may utilise a fluid coolant such as an inert gas or a liquid coolant which can be used to reduce the temperature of the electrodes 101. The cooling system may be adapted to regulate temperatures of the module 20, or components thereof. Suitable fluids may include at least one of; antifreeze, water, deionized water, oxygen, air, argon, inert gas, nitrogen (gas or liquid), hydrogen, sulfur hexafluoride, air, polyalkylene glycol, oil, mineral oil, liquid salts, carbon dioxide, nanofluids, or any other desired coolant.

Preferably, conduits of the cooling system can be run through the hollow cores of the electrodes 101. Further, the cooling system may transport fluids near to portions of a module 20 which require cooling. The cooling system may form a portion of the common rail 70 or be in communication with a channel within the common rail 70. Coolants used for the system 10 may be any desired coolant, but are preferably fluids which can be recycled, such as water or a carrier fluid. Each predetermined module 20 may be in communication with a respective cooling system, or a central cooling system may be used to cool all predetermined modules 20 of the system. It will be appreciated that a pump may be used to pump or push fluids through the system 10 or components thereof. The coolant fluids may be in a fixed circuit which are recycled continuously by the cooling system whereby the coolant cools components of the segments and is subsequently cooled by any desired cooling method.

In yet another embodiment, the electrodes 101 may comprise a dielectric coating rather than the sheaths 103 of the electrodes being formed from a dielectric material. Coatings may be adapted to reduce build-up of by-products or debris the electrodes 101. Optionally, other portions of the module 20 may be coated with a dielectric to reduce the potential for arcing to occur within the module 20.

It will be appreciated that atmospheric pressures may be in the range of about 500 Torr and about 1000 Torr. Further, any gases delivered to the plasma regions 106 generated by the electrodes may be initially in the temperature range of −10° C. to 40° C. before entering the plasma regions. The temperature of electrodes or fluids within the plasma region 106 may reach or exceed temperatures of around 300° C., and therefore electrode cooling systems 35 can be used to regular the temperature of the electrodes 101 to reduce the potential for damage to occur.

The active chemical species or active physical species of the plasma exit the plasma region 106 and are deposited onto a substrate 1, thereby permitting substrate 1 surface processing. It is preferred that the substrate is positioned near to the plasma region to allow for sufficient treatments to be imparted, while also reducing plasma or heat damage to the substrate. Preferably, the distance of the substrate 1 from the electrodes 101 is in the range of 1 mm to 50 mm which may reduce the potential for activated species exiting the plasma region 106 to become inactive before reaching the substrate 1.

The system 10 may be used for coating, polymerisation, surface cleaning and modification, etching, adhesion promotion, and sterilization, or any other desired treatment process. Polymerisation may be free radical-induced or through dehydrogenation-based polymerisation for example, however other polymerisation processes may be achieved by use of the system.

It is preferred that active species in the plasma generated by the system 10 have as long as possible activation to more successfully be deposited onto or interact with a substrate. Extending the active species life may be achieved by the addition of small amounts of N₂ or O₂, or other gases, or mixtures thereof to a noble gas, such as helium, or a mixture of noble gases may be used in a delivery gas. Optionally, monomer(s) can be deposited on a substrate 1 and the modules 20 are used to polymerise the monomer rather than apply and polymerise a monomer.

In yet a further embodiment, the electrodes 101 may be alternating RF powered and grounded parallel opposing planar electrodes. The electrodes 101 can be supplied with a delivery gas or other gas from the manifold 107, and the gas is directed into the inner manifold 110 and out via the inlet manifold 109. The fluids flowing from the plasma regions 106 may be considered to be are generally perpendicular to the substrate 1. The substrate 1 is preferably in the range of 0 mm to 10 mm away from the electrodes of the module 20 during processing such activated monomers or excited gases can be deposited on a substrate 1 or interact with a substrate 1 more quickly and therefore production times may also be improved. The flow rate may also have a direct influence on the deposition rate, and may also allow for films or coatings to build relatively faster.

Electrode lengths, widths, gap spacings, relative distance to the substrate from electrodes, substrate thickness, distance between manifold and electrodes, flow rate, and the number of electrodes can be chosen depending on the substrate 1 to be treated. An example of a system 10 adapted for industrial-scale textile fabric treatment may comprise electrodes 101 with a spacing of between 0.1 mm to 10 mm, and at least two plasma regions 106. Preferably the spacing of the electrodes is in the range of 2 mm to 8 mm, or in some embodiments may be around 6 mm±2 mm. Electrodes 101 may be fabricated with a hollow structure, round, ovoid, square or rectangular stainless steel, aluminium, copper, or brass tubing, or other metallic conductors. The hollow structure of the electrodes 101 may allow for a fluid to be passed therethrough to allow for cooling of the electrodes 101, by pumping a coolant through the hollow structure of the electrodes 101. Preferably, the electrodes 101 are shaped to minimise the potential for arcing or other edge effects when in use, and therefore any edges of electrodes 101 may be curved 128 or otherwise chamfered 128.

In one embodiment, the electrodes 101 may be formed with a width of between 0.5 cm to 3 cm and a height between 10 mm to 30 mm, or a diameter between 0.5 mm to 45 mm. The cross-section of the electrodes 101 are preferably uniform along the length of the electrode 101, which may encourage a relatively more uniform plasma field to be generated. It will be appreciated that in some embodiments, portions of the electrodes 101 may be formed with a different diameter, cross-sectional area or cross-section such that differing effects or strengths may be imparted to a plasma region 106.

The power required to form and maintain a plasma may be dependent on the diameter of the electrodes 101, the thickness of the sheath 103, the thickness of the core 102 or the materials forming the core 102 and/or sheath 103. By reducing the wall thickness of the sheath the overall power which may be required may also be reduced. This in turn may also reduce the overall temperature of the electrodes 101 when in use. Having electrodes with a smaller cross-sectional area may also allow formation of a smaller plasma region or a less dense plasma region 106. These may be advantageous as modules 20 may be fabricated as more compact systems and the distance between the top and the bottom of the modules may be minimised, and therefore the local environment fluids can also be reduced. This is of particular advantage in relation to plasma fluid consumption and potential losses.

Fewer electrodes 101 may be used in a module 20 to generate fewer plasma regions 106 or weaker plasma densities while also maintaining a constant total delivery gas flow. Further, reducing the distance between the plasma discharge and the substrate 1 may also reduce the overall energy requirements. Reducing the distance between the substrate 1 and the plasma discharge may allow for a more compact system to process a substrate, or may allow for more modules 20 to be installed in the system without a reduction of size of the system. Including more modules 20 in the system 10 may increase the overall processing length of the system 10 which may allow for additional treatment times while maintaining a desired processing speed.

The plasma region 106 generated by a module 20 may be an atmospheric pressure plasma. Electrodes 101 for generation of the plasma region 106 may be coated with a dielectric film to prevent formation of an arc that would otherwise form between the electrodes 101, and may be referred to as a Dielectric Barrier Discharge (DBD). Capacitive discharges and corona discharges may also be generated by the system 10 to allow for different treatment, such as surface modifications.

Modules 20 may also be used to prime a substrate 1 which can be then further processed by another technique or treatment. Plasma treatment of a substrate 1 may alter the surface to allow for improved bonding, a cleaning of the surface which may enhance the surface wetting of adhesives or over-moulded elastomers, improve adhesion to other substrates, functionalise groups (such as carbonyl and hydroxyl groups) which may improve surface energy, and may establish hydrophobic and hydrophilic properties.

Other System Modules

Other modules 20 which may be used with the system 10 are described below. It will be appreciated that any combination of modules may be used with a system 10, and the system may allow for modules 20 to be swapped or changed to allow for a desired substrate 1 processing. Other modules 20 may also utilise fluid inlets, power supplies, controllers, electronics, or other means which may be used with modules 20.

A coating module 20 may be a module with a fluid applicator which can partially cover, cover or coat a substrate 1 region. Fluids may be a chemical coating, a wetting coating, or another fluid coating, and is preferably a liquid coating. The fluids applied may provide for a physical property or may provide for a functional coating. Functional coatings can provide a number of properties such as abrasion resistance, antimicrobial, antistatic, hydrophobic, hydrophilic, washable, flame-resistant coatings, reflective coatings, absorbing coatings, colourisation coatings, reactive coatings or any other desired functional coating. Heating modules 20 may be used to heat treat coatings applied to a substrate 1. It will be appreciated that heating elements may also be provided in the coating module and act as both a fluid applicator and heat treatment module.

The coating module 20 comprises a module housing 160 which houses a fluid delivery means and an outlet 112. The fluid delivery means may be supplied with a fluid from a fluid inlet which is in fluid communication with a fluid supply. A power supply may be used to activate the spraying devices of the coating module. Spraying devices may use a propellant or pressurised gas to allow distribution of fluids from the coating module 20 to the substrate 1.

In another embodiment, the coating provided may be a ceramic coating. Conductive, abrasion, thermal and insulative properties may be imparted to a substrate 1 by the use of ceramic coatings.

As discussed above, another module 20 may be a heat treatment module 20 which can be used to bake, heat treat or seal a substrate 1. Heat treatment modules 20 may be used to melt films or set coatings or films on a substrate 1. Heat treatment modules 20 may use heat lamps, UV lights, e-beam, UV-beam, fire, heating devices, heated gases or any other desired heating element to achieve a desired temperature. Other heating element arrangements may also be used to allow for a desired heat treatment process.

A shield or other heat blocking device may be used to focus heat to a desired location and prevent heat from radiating to adjacent modules or equipment. The shielding may be formed as part of the housing and extend in the proximal direction towards the substrate 1.

A film applicator module 20 may also be part of the system 10 and used to apply a coating or film to a substrate 1. The film may be a functional film, such as a hydrophilic film or hydrophobic film, or the film may be an aesthetic coating such as a decal or other predetermined film. Similar to other coatings which may be applied by the system 10, the films may have any predetermined functional property. Films applied to a substrate 1 may be fixed with an adhesive or subsequent treatment process from another module. Films may be pressed or applied to the substrate 1 via physical means or by pressurised gases urging the film to a substrate 1. Films may also be cured by a module 20 of the system 10, which may involve a plasma treatment, a heat treatment, or a chemical treatment. Films may or may not be applied to one or two surfaces of a substrate 1, and may be fixed only on a portion of the surface. Films may also be heat treated, radiation treated, dyed, or otherwise processed by another module to impart a desired property to the film. For example, films may be heat shrinkable, textured, conductive or mouldable. Bonds between films and substrates 1 may also be improved by modules 20 which clean or activate the surface of the substrate 1 prior to application of a film. Modules 20 may also be used to “break-down” or alter a functional treatment which has previously been applied to a substrate 1. Altering or breaking down a functional coating in this way may allow for improved bonding of films or further coatings onto a substrate 1. Conductive films also have utility when being used for conducting electricity or for thermal conduction. Thermal films can be used as heat sinks or to transfer heat on the substrate.

The film applicator module 20 may have at least one roller and a film mount (not shown). The film mount may be used to support a roll of film or other sheet which may be applied to a substrate 1. The roller may be used to guide the film from the roll through the module 20. It is preferred that a film is applied to a substrate 1 and the substrate moving through the system 10 will pull the film at the same rate of speed. As such, the film module 20 may be free of motors or actuators to effect deposition of the film. Alternatively, the film applicator module 20 may have actuators to realign the film being deposited, or may have a motor to lead the first portion of film from the roll to the substrate 1. A paddle or other abutment means may be provided at the proximal end of the module which may be used to straighten and/or press the film to the substrate 1. One end of the paddle may be attached to the module 20, and a free end may project towards the substrate 1 upper surface (surface to be treated 2). In one embodiment, the free end of the paddle may be positioned at generally the same height as the substrate surface to be treated such that the film may be adequately pressed to the substrate 1.

The film module 20 may also be used to screen print, or laser print on a substrate 1 and may also function as a printing module (see below). Any predetermined printing method may also be used by the system 10 to impart a desired image, shape or deposition to a substrate. Multiple layers of film and/or printing may be applied to a substrate 1 by a film module 20, or multiple film modules 20.

Optionally, a ceramic coating or enamel film can be applied by the film module 20 to a substrate 1. Any such film may be applied such that air bubbles are removed during application and contact between the film and the substrate 1 is optimised. Films applied may be sacrificial films which are removed during processing or when the substrate 1 is to be in use. For example, a sacrificial coating may be a coating for a medial substrate.

Preferably, the system 10 is adapted to record the volume of fluids used by a module 20 and can determine remaining fluids within a fluid supply or fluid reservoir. Sensors may also be provided at inlets and outlets to verify the volume of fluids being consumed. Optionally, fluid reservoirs may also have a sensor at the outlet which connects to the fluid inlet of the module 20. Another treatment module 20 may utilise radiation treatments such as UV radiation, microwaves, electromagnetic radiation, gamma radiation or X-ray which may be used to activate a surface, clean a surface or impart a desired property. It will be appreciated that any predetermined radiation type can be used with the system 10. Radiation modules may have at least one radiation source installed therein, such as a lamp or radiation pellet. Other conventional radiation treatment sources may also be employed by a radiation module 20. Radiation shielding may also be used to reduce potential radiation exposure to nearby persons or prevent or reduce the potential for radiation to contaminate adjacent components of the system 10.

Radiation modules 20 may be utilised for ionisation which may be of particular use for processing paper substrates or substrates which are required to be sterile or for medial use. Radiation may also be used to activate or excite particular substrates 1 such that a desired effect is established, such as excitation of a particle to cause luminescence. The radiation module 20 may also use electromagnetic wavelengths which may interact with the substrate 1. For example, phosphorescent substrates may be excited by heat or light interactions for a short period of time which may have utility for further processing steps or short term uses.

While all modules 20 are preferably provided with a module housing 160, which in some embodiments may be a housing or shield, the module housing 160 may be optionally removed and the internal components of the module 20 may still be adapted to function and/or remain in a predetermined configuration.

Modification processes may also be conducted by the system in which a substrate 1 can be etched, cut, punctured, deformed or otherwise physically altered by a treatment head. The physical alteration may be desired before or after treatment or processing of a substrate. Functional properties may also be imparted to the substrate, such as a tactile property which may improve a tactile sensation or gripability. Physical alterations of a substrate 1 may be achieved by kinetic processes, heat treatments, or chemical treatments. Chemical treatments may be used to form a desired microstructure surface, or a desired surface property. A visual property may also be imparted to a substrate 1 by physical alterations. Other treatment processes such as laser etching, sintering, laser cutting, laser surface treatments may be achieved by specialised modules 20. Lasers may be used to achieve at least one of the aforementioned processes.

A fluid may be delivered to a substrate 1 via a module 20 of the system 10. The manifold 107 and the common rail 70 may be used to spray, release or supply a fluid to a segment 15 or a substrate 1 therein. Each module 20 may be adapted to deliver a controlled discrete fluid to a substrate 1. Any number of fluids may be provided by a module 20 or array of modules to a substrate 1. Fluids may include chemicals, gases or plasma, for example. Other fluids may also include dyes which may be hardened, polymerised, or set using heat or plasma fields.

The system 10 may comprise any number of modules 20 which may be used to treat or process a substrate 1. Each module 20 may have a specific function, a unique function, or all modules may have the same function. Some modules may be adapted to alternate functions or perform selected functions at desired intervals. It will be appreciated that any mix or combination of modules 20 may be used with the system 10. Each module 20 may be selectively activated or deactivated for processing a substrate 1. Processing a substrate 1 may include any desired treatment or processing methods. Modules 20 may be selectively activated or deactivated after predetermined lengths of substrate 1 have been treated. This may allow substrates 1 to be cut at the end of processing and multiple different substrates may be continuously treated by the system 10 in this way. Optionally, the substrate 1 may be a homogenous substrate 1 and treatments may be altered at desired intervals or lengths of the substrate 1 such that multiple processed substrates may be manufactured by the system 10. Substrates may be separated or cut at a finishing region at the end of the system 10. The end of the system 10 may be any stage of the system 10 where processing is finished or the substrate 1 proceeds to a finishing location.

The substrate 1 may be provided into the system by conventional conveying means which can transport the substrate 1 from the entry to the exit of the system 10. It is preferred that by the time the substrate 1 has reached the exit of the system that the substrate has been processed or has been provided with one treatment or surface modification.

A user terminal may be used to activate, deactivate or otherwise interact with the system 10. The user terminal may be installed with predetermined system functions which may be executed to activate and operate the system 10. A user interface may be provided on the user terminal which may allow input of substrate and the desired treatment processes therefor, such as substrate grade, substrate thickness, substrate desired treatments, or any other predetermined inputs. It is preferred that the system is adapted to only allow for processing of known substrates or articles to ensure correct processing. Minimal inputs may be allowable, and a sensor or camera may be used to verify the substrate to be treated before treatments are allowed. The system 10 may be adapted to provide error messages to a user if the system 10 is attempting to treat a substrate with processing treatments which may cause damage to at least one of the; system 10, substrate 1 or modules 20. For example, if a substrate 1 has a low melting point heat treatments of the system 10 may not be suitable and therefore an error message may be provided which may indicate the issue with selections. Based on the inputs to the user terminal, a controller associated with the user terminal may actuate portions of the system 10 and prepare suitable modules for treatment processing. For example, if a substrate is to be heat treated, heating modules 20 (also referred to as “heat treatment modules”) may be warmed up to a predetermined temperature before processing can begin, and the relative locations of the modules may be altered to allow for processing of a substrate 1. The user terminal may also have access to a data storage device which can record usage, store processing data, store processing functions, store executable programs or any other predetermined function.

Each usage of the system 10 may be logged and each module 20 may have an internal counter or other measurement means to determine the volume or length of substrates which have been treated. In this way it can be verified whether systems are being used outside of prearranged treatment schedules or whether additional treatment processes are being undertaken without knowledge of the owner of the system. Any data stored with the system may be hashed or otherwise encrypted such that tampering with data records by users of the system 10 cannot be easily achieved. Time stamps and or processing stamps may be imprinted or market on substrates treated at the tail end of the substrate 1. The tail end of the substrate 1 may be the last portion of the substrate 1 which is to be treated. Time stamps may comprise information including, but not limited to, a time, a date, a location, a machine identification number, a region of manufacture, local temperatures or any other desired data set. Processing stamps may include codes or identifiers which denote the treatment processes which have been applied to a substrate. Optionally, if there are any errors in treatments, such as a fluid has spattered or been applied in a manner which is not desired, the region of the substrate with inferior treatments may also be denoted, which may assist with visual inspection of treated substrates. It will be appreciated that the substrate 1 length may be predetermined, but also may be calculated by the system 10 during processing to allow for a matching of lengths.

Data from the system 10 may be uploaded to a server, a storage device or network. Data can also be communicated to a further device or remote server. The further device may be a monitoring system which may monitor a plurality of systems 10 and may notify users of potential machinery errors or other system 10 errors. This may be beneficial as systems 10 can be monitored remotely and repairs or maintenance of systems 10 can be more effectively delegated. The system may be connected to the Internet continuously, or at intervals to allow for third party monitoring, or third party actuation of the system 10. If the system 10 does not connect to the Internet and receive a confirmation signature from a third party device in a predetermined time period, the system 10 may be adapted to cease processing of a substrate 1 until such a signature is received. In this way the signature may allow for a predetermined usage period of the system 10 before being shut down. Optionally, a signature is a hash which is confirmed by the system 10 and a predetermined processing time can be used for the system. Optionally, signatures may be required for specific treatments, such as radiation treatments which may require regulation of radioactive components of the system 10.

The usage data and efficiency data for each module 20 of the system 10 may be recorded and accessed in real time. These data sets may be transmitted to a server associated with the system and accessed remotely. If a module efficiency or usage is outside of predetermined thresholds, the system may require maintenance or manual inspection for the system to continue processing treatments. In at least one embodiment, the system 10 can be remotely shut down by a third party.

### ILLUSTRATED EMBODIMENTS

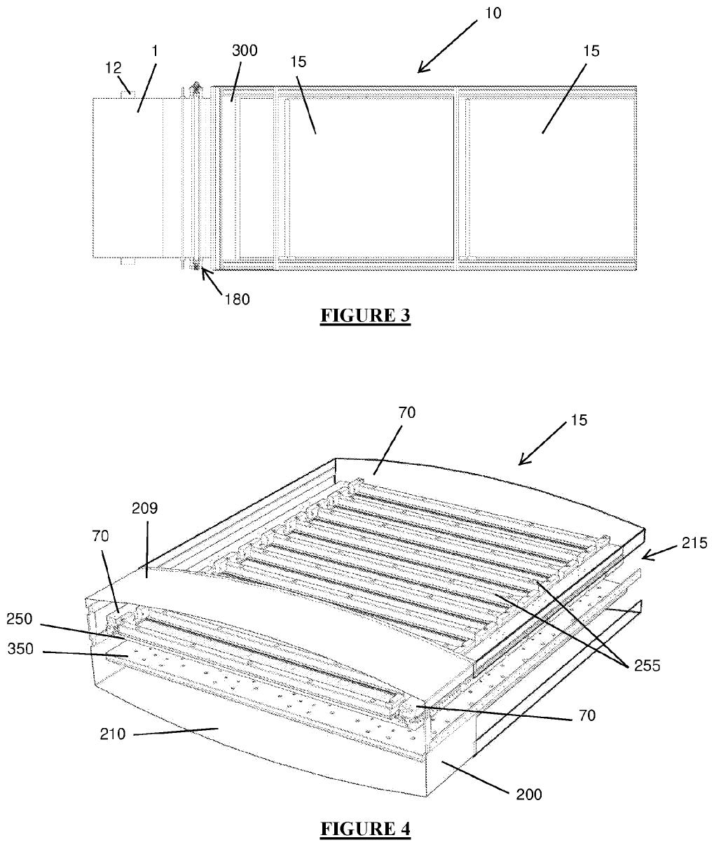

Referring FIGS. 1 to 3 there is shown an embodiment of a portion of a system 10. The system 10 shown is a roll-to-roll treatment system 10. The system 10 shown comprises an array of modules 18 which are mounted within a segment 15. An adjustment means 180 is provided on the exterior of the entry segment which may be used for guiding, aligning and moving a substrate 1 into the entry segment. The adjustment means is also illustrated within FIGS. 25 and 26, however the adjustment means is located within the entry segment, or a segment after the seal 305. Any number of segments 15 may be used to form the system, and may include segments which are adapted to perform any predetermined function. For example, segments may be fitted with drying means which can be used to lower the moisture content of substrates prior to processing, or may be fitted with plasma treatment systems, spray systems or any other desired treatment modules as described within this specification. Protective chambers may be used to house the winder and the unwinder of the system, and the substrate thereon. Protective chambers may also be used to wrap or apply a protective storage cover to a roll of substrate 1. Protective covers or wraps may be polymer bags for example or another barrier which can keep external the bag or barrier moisture from interacting with the substrate 1. The processing portion of the system 10 is preferably in open atmosphere rather than a protective chamber, which can also allow for in-line processing of a substrate.

In an unillustrated embodiment, the system 10 allows for processing of a substrate 1 which can be supplied from web handling systems, or a fabric tank, which are common in the art of fabric production. Each system may be fitted with a guiding means, which may be similar to that of the adjustment means 180, which can direct the substrate 1 into the system 10 to be treated. The guidance means may be adapted to transport a lead portion of a substrate through the system and allow for processing treatments. Other guiding means or transport means may be used with the system which can position a substrate between the bias plate and the modules of the system 10.

An array of modules 18 comprising one or more modules 20 are arranged within a segment 15. The modules 20 may be fixed to a common rail 70 which spans the length of the segment 15, and may be generally parallel with the substrate 1. The modules may be snap-fitted, press-fitted, releasably fixed, or connected to the common rail 70. It is preferred that the manifold block 108 is provided with fluid connectors 118 and electrical connectors 120. In the configuration shown, the modules 20 are mounted to the underside of the common rail 70. The modules may have one or more connections which can be mated with the common rail at predetermined intervals. Common rail 70 may be connected to the manifold block 108 which can allow for fluids to be supplied to the module 20. A frame 25 may be used to support the modules 20 and/or the common rails 70. Optionally, the frame 25 has a housing or shield which can be used to cover at least one of the modules 20, substrate 1 being processed and the winder 12 such that persons working near to the system 10 cannot injure themselves. Further, an exhaust plate 350 or fluid bed, or fluid collection system 40 (see FIGS. 4 to 8 for example) may be disposed below the substrate to collect excess fluids from the module 20. Fluid collection system 40 may be a recirculation system which recycles desired fluids which enter into the system 10. It will also be appreciated that the recirculation system 40 may be mounted at any desired location within the system 10 which allows for collection and movement of fluids to processing systems, filters, or an external processing location.

The size of the unwinder 12, or winder 12, may depend on the size of the modules 20 of the system 10. It will be appreciated that each of the winder and the unwinder may be the same apparatus, and can function to both wind and unwind a substrate 1, and may be in the form of a roller, but be driven by a motor. The winder 12 may also act as tensioners to maintain a desired tautness or tension of the substrate 1. Each module 20 of the system 10 may be of a uniform size such that modules 20 can be disposed at any location in the system 10. This may be of particular benefit for continuous processing systems 10 as there may be required to be waiting times between treatment processes or application of fluids to a substrate. A substrate 1 may be guided from a roll by rollers, or other suitable movement means, to the winder 12 and to the processing area. The processing area may be any portion of the system 10 which can treat a substrate 1 or apply a fluid to a substrate 1.

In the most basic arrangement, a module 20 comprises electrodes 101, which can be alternating positive and negative charged electrodes 101, or radiofrequency (RF) electrodes and ground electrodes arranged in a parallel relationship. The electrodes are configured to be in an arrangement which allows for a plasma fluid to be excited to form a plasma between a corresponding pair of electrodes 101. The array of modules 18 are preferably disposed within the same plane, however some modules may be offset depending on the treatment to be provided to the substrate 1, or if the modules 20 are configured to provide different treatments to a substrate 1. In some embodiments, the modules may be in a stacked configuration or angled to provide a treatment effect or to allow for more control over the direction of fluids from the module 20. In another embodiment, the system may comprise stacked segments 15 which can reduce the overall footprint of the system 10. Modules may be angled in the range of ±90 degrees from parallel with the substrate 1. The modules 20 are shown as being relatively below the substrate to be treated, but may instead be disposed relatively above the substrate or an article to be treated instead, which may be of particular use when coating articles on a conveyor.

Spaces between the modules 20 and the bias plate is preferably sufficient to pass a substrate 1 to be treated therebetween. The distance between the module 20 and the bias plate 250 may be in the range of 1 mm to 20 mm, and may be Treatments may be any predetermined or desired treatments as described herein, or undergo treatments which are known in the art.

Some segments 15 of the system 10 may have modules 20 disposed on both sides of the substrate 1 such that each side of the substrate 1 can be treated simultaneously. If this configuration is selected, the electrodes 101 of the lower module and the electrodes of the upper module may be opposite polarities, or charged oppositely. In another embodiment the lower module electrodes 101 may be in an order of positive-negative-positive, and the electrodes relatively above in the upper module 20 may have a negative-positive-negative configuration. Treatment of both sides of the substrate may allow for a desired effect to be imparted to the substrate, for example a first surface may be hydrophobic and the second surface may be hydrophilic to encourage moisture transfer.

In some embodiments, the system may utilise electrode arrangements 101 which are mirrored, such that positive electrodes are adjacently disposed (positive-positive) or negative electrodes 104 are adjacently disposed (negative-negative). In this way plasma regions may not be generated between like electrodes 101.

Modules may be fitted with one or more electrode layers which may form more than one electrode plane. An electrode plane may be defined by two or more electrodes which are in a generally linear configuration, but more preferably an electrode plane may be three or more electrodes in a linear configuration. By increasing the number of electrode layers in a module 20, it may be possible to increase the speed within which the substrate 1 passes through the system 10 without compromising quality of treatment processes. The electrode layers may allow for a full polymerisation of a monomer without increasing the density of the plasma between two electrodes of an electrode layer. In another embodiment, increasing the number of modules 20 of a system 10 may also increase the speed in which the substrate 1 can move through the system to complete a desired treatment or treatments. It will be appreciated that the speed of the substrate 1 through the system 10 may also be increased by increasing the volume of monomer or treatment fluid from a module, which may be increasing the flow rate. Monomers may be more effectively directed towards a substrate 1 in atmospheric conditions relative to low pressure or vacuum conditions. As such the system 10 may increase the speed in which a fluid or monomer may be delivered to a substrate. As such, the system 10 may provide for faster production of polymerised substrates using a plasma field. Further, monomers polymerised in a plasma field can be disposed in thinner layers with improved adhesion to a substrate 1 which is further advantageous over other deposition or treatment methods. In addition, the behaviour of fluids may more easily be predicted within atmospheric conditions.

The strength (or density) of the plasma generated between these electrodes 101 may be varied by modifying the relative spacing between adjacent electrodes. It will be appreciated that if spacing between all electrodes is uniform the extended plasma region 106 generated will generally be uniform in density. Further, it will be appreciated that the spacing of the electrodes 101 may dictate whether polymerisation can be affected.

The system 10 modules 20 may be adapted to provide a high volume of delivery gas, such as argon, to evacuate or otherwise purge the local region 90 between the substrate 1 and the electrodes 101 which may remove ambient atmosphere and therefore eliminate the potential for undesired particles from being activated, polymerised or otherwise ionised in a plasma formed in the plasma region 106. It may be preferred that breathable or inert gases are used to evacuate or purge a local region 90 of local atmospheric gases. Gases which may be suitable for such a purpose may include argon, oxygen, nitrogen, helium, neon, krypton, xenon, radon or any other predetermined gas. It is preferred that the gas used for local region 90 evacuation is also a delivery gas, which may also be used to form a plasma when the electrodes are charged.

The spacing between the adjacent modules may be any predetermined distance, but is preferably within the range of 2 mm to 50 mm. Other spacing may be used depending on processing treatments desired. It will be appreciated that each module 20 may have a predetermined spacing from the surface of a substrate 1. For example, a coating module 20 may require a distance of 50 mm from a surface of a substrate 1 to reduce spattering while a module 20 may be desirably 3 mm from the surface of the substrate 1 to effectively treat the surface, for example. The system 10 may be adapted to automatically detect module 20 functions and/or the substrate 1 thickness and displace the substrate or the modules 20 relative to each other.

One or more rollers may be disposed within the system 10 which can be used to transport the substrate 1 through the system and apply a desired tension. Preferably, the tensions are limited to less than around 300 Newtons per meter width such that substrates treated are not damaged in the case of treating textiles. It will be appreciated that the system 10 can be adapted to limit or otherwise control the tension applied to the substrate being processed based on a preset process within the system. An adjustment means 180 may be provided for the system to adjust and align the substrate before being treated by the modules 20.

In another embodiment, the system 10 may be adapted to treat one or more sides (both surfaces) of a substrate 1. This can be achieved by rotating the substrate to allow for processing of the second side, or the substrate can be passed back through the system for a second treatment. Alternatively, two sets of modules can be disposed within the chamber (not shown) which can be used to treat both sides of the substrate simultaneously, or in an alternating configuration to allow for a bias plate to be positioned on the other side of the substrate 1. Preferably, the substrate 1 is disposed between a module and a bias plate, or is disposed between two modules 20. Atmosphere can be locally evacuated between a module 20 and the substrate 1 using a delivery gas, the pressure between the module 20 and the substrate 1 may be generally atmospheric or at a higher pressure than atmospheric. A delivery gas may be any fluid that can be used to carry a further fluid and/or be used as to form a plasma. It will also be appreciated that any reference to the term “delivery gas” may encompass “delivery fluid” which may include liquids, vapours, gases and plasmas. In at least one embodiment, the delivery gas is an inert fluid, such as argon or another noble gas.

The module 20 may be moved relatively to the substrate 1 such that the distance and/or angle of deposition or treatment can be modified. It is preferred that the distance between module and the substrate 1 to be coated or treated is minimised such that the ionised fluids from the module are relatively closer to the substrate 1. In this way ambient atmosphere can be more effectively removed from between the module manifold outlets 112 and the textile which may remove potential impurities when the processing line is not within a sealed environment or is not in a vacuum or partial vacuum.

The system may be flushed by pressurised gases or pressurised liquids, or a combination thereof before processing begins. Alternatively, chemical flushing may also be used which can chemically remove build-up of monomers or other residual processing materials in the segments, on modules or within fluid delivery channels. Cleaning may be performed during predetermined periods, or at predetermined intervals, such as when substrates are not being processed, or when modules are deactivated. For example, cleaning may occur when the system has finished processing a substrate, or between processing steps.

Modules 20 may be removed from the system 10 for cleaning at a cleaning station or may be swapped for clean modules 20 to reduce downtime of the system 10. Hot-swapping of modules 20 may also be achieved in some configurations whereby an active module 20 is removed during processing and a replacement module is installed and activated while the removed module is cleaned.

Substrates 1 which may be used with the system 10 may include ceramics, polymers, elastomers and metal assemblies are all good candidates for plasma treatments or other desired treatments. Plasma treatments may improve adherence properties therefore and reduce the volume of defective processed products (processed substrates) as plasma treatments may reduce the potential for insufficient bonding of paints (or pigments), inks, mouldings and other coatings.

The system 10 may be used to treat substrates 1 and/or coat substrates 1. These treatments may include pre-treatment processing steps, such as surface activations or sterilisations. However, modules are preferably adapted to deliver a coating, such as a polymer coating or functional coating to a substrate 1.

In one embodiment, the pre-treatment of a substrate 1 can be achieved by passing the substrate through, or adjacent to, an active plasma region. Preferably, purging or partial purging of atmospheric gases within the local region 90 is conducted in advance of treatments. Evacuating the local region 90 may reduce the potential for polymerisation or undesirable surface modification of the substrate 1 from undesired reactants in the plasma field. Evacuation of gases and other potential contaminants in the local region 90 may be required as the system is outside of a vacuum chamber.

It will be appreciated that monomer at the surface or near to the surface of a substrate at the time of being introduced to a plasma may polymerise the monomer. Monomers may be applied to a substrate in advance of entering into the system 10, which may be of particular advantage with respect to thicker coatings which cannot be efficiently deposited by the flow rate of a module 20, or may be desirable if a monomer is applied in a predetermined array or pattern and can then be polymerised in the predetermined array or pattern. An array or pattern applied to the substrate 1 may be achieved by sputtering, spattering, transfer, film transfer, printing, knife coating, gravure coating and/or any other desired method of deposition or application. While an array or pattern of a material doped with a monomer or entirely comprising monomers may be applied prior to the substrate 1 entering a plasma treatment area in the local region 90, the monomers may be adhered to the substrate 1 prior to plasma treatment and a superior bonding may be achieved by polymerisation of the monomer(s) by the plasma treatment. Optionally, the material in the array or pattern may comprise at least two monomer species which react in the plasma field and bond or react in a desired manner in said plasma field. In this way a desired functional property such as a hardened surface, a flexible surface, a protective layer, a tactile property, a hydrophilic property, a hydrophobic property, or a desired aesthetic.

In another embodiment, the relative distance between the electrodes and the substrate 1 may be increased or decreased if desired. The relative distance may be changed by moving a module 20 relative to the substrate 1 or moving the substrate 1 relative to the module 20. If a bias plate is used with the system 10, at least one of the bias plate and the module 20 may be moved relative to the other, such that the distance between the substrate and the module may be varied. The system 10 may be adapted to modify the distance between a surface of the substrate 1 and the module automatically based on inputs received before processing. Inputs received may be pre-set by the system 10 based on at least one of; substrate 1 type, treatment processes, and substrate 1 thickness. Actuators may be used to adjust the relative location of at least one of the modules 20 and/or the bias plate which may allow for modification of heights during processing such that processing does not need to stop.

In yet another embodiment, the thicknesses of coatings or treatments may also be measured during processing and module heights may be adjusted dynamically based on a desired treatment thickness deposition or overall thickness of the substrate. There are a number of different methods which may be used by the system 10 to test the thickness or density of a coating or layer on the substrate. It is preferred that non-destructive means of measuring thicknesses and densities may be used by the system. For example, ultrasonic testing methods may be used, laser testing, x-ray fluorescent testing (XRF), magnetic testing, micro-resistance testing, duplex measurement testing, eddy current method testing, phase-sensitive testing, coulometry testing, beta-backscatter measuring, STEP testing methods, or any other desired non-destructive testing methods which can be used while the substrate 1 is being processed. The thicknesses of coatings may also be calculated by known volumes and concentrations of fluids provided to the module via the manifold. Optionally, each module may be fitted with a sensor which can determine at least one of the flow rate and the concentration of fluids.

Thickness testing may be taken at predetermined time intervals or predetermined length intervals. Incremental testing may also allow for identification and/or tagging of potentially defective regions of substrate 1 which can be removed after processing if necessary. Optionally, thickness testing modules may be provided before and after a treatment module which can be used to record the thickness of a substrate 1 and compare before and after treatment thicknesses.

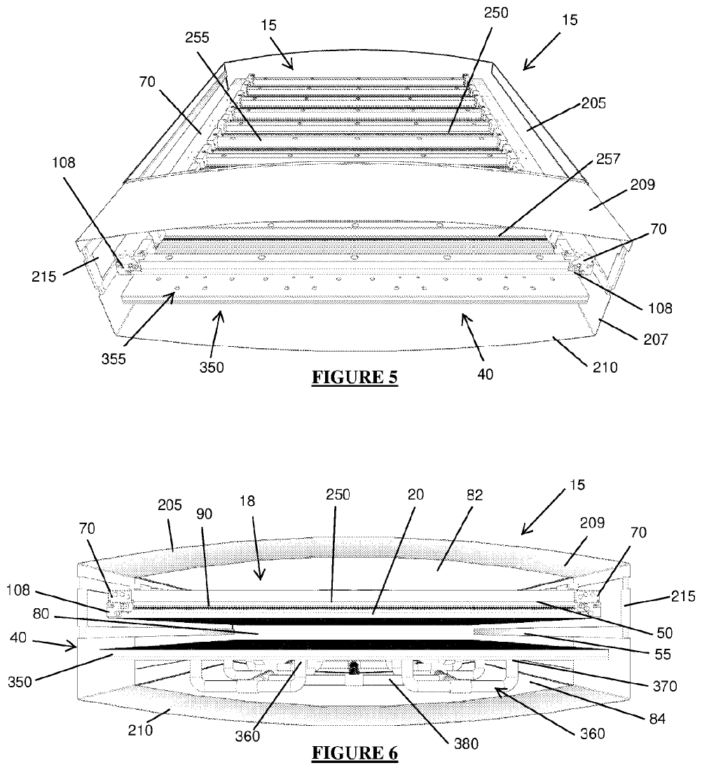

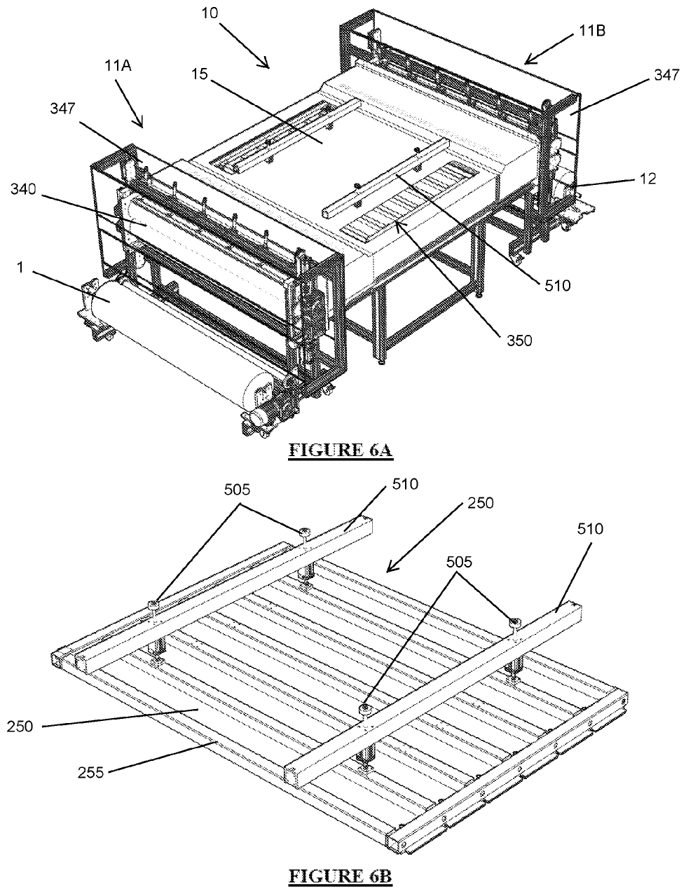

Referring to FIGS. 5 and 6, there are illustrated embodiments of a segment with a fluid collection system which may be used to recover fluids which are not consumed during processing. The fluids not consumed may include monomer, polymer, nanoparticles and delivery fluids. Fluid collection systems may utilise vacuum systems to draw in fluids, or may be trough systems which are angled or shaped to direct flow of a fluid to a collection drain to be either recycled, collected or disposed of.

The segments 15 may be separated into several regions which can be of various pressures. Preferably, the region bound between the bias plate and the exhaust plate is a first region 80. This region can be sealed relative to other regions of a segment 15. The first region 80 can be pressurised to be relatively higher pressure than the local atmosphere external the system 10. The first region 80 is preferably sealed from a second 82 and third 84 region of the system, in which the second region 82 is relatively above the bias plates, and the third region 84 is relatively below the exhaust plate. Each of the second and third regions may also be pressurised relative to the external local atmosphere of the system 10. Preferably, the first, second and third regions 80, 82, 84 are all of an equal pressure, or substantially equal pressure. It is preferred that the first region 80 is provided with carrier fluids and precursor fluids to treat a substrate 1 or article 1. Optionally, the first region 80 may have a pressure which is 0.01% to 0.5% higher than the second 82 and/or third regions 84 which may encourage any fluid movement to be from the first region 80 to the other regions. It will be appreciated that all segments 15 may have any number of desired regions. Further, as each segment 15 is mounted and connected, the segments may extend the regions length, and allow for the atmosphere of each region to remain bound between respective features of the system 10. Each segment may be fitted with segment seals to reduce fluid movement between regions. The entry and exit segments of the system may be part of first region 80, and the first region 80 in these sections is bound by the housing of the entry and/or exit segment rather than between the bias plate and the exhaust plate 350. Optionally, these entry and exit segments may be fitted with an exhaust plate 350. As can be seen in FIG. 2, the first region defined by the entry segment 300 may be of a different dimension than the first region 80 of the treatment segment 15. In addition, the exhaust system 360 will also be adapted to operate at pressures which are above ambient atmospheric pressure, such that ingress of fluids from outside are reduced. This is particularly useful if the exhaust system 360, or part thereof, is positioned outside the housing, or is exposed to ambient atmosphere

Second and third regions 82, 84 may have a slow introduction of fluids from the first region 80 if the seals or barriers between the first region 80 and the respective second 82 or third region 84 are not fluid tight. This may be of particular advantage as the system can be adapted to slowly transfer fluids to all regions of the system and thereby have a delivery fluid rich atmosphere. Separation of the first, second and third regions 80, 82, 84 is preferably as fluid tight as possible such that fluids are not easily transferred from the second or third region to the first region. Optionally, the first region 80 may have an opening to the second 82 and/or third 84 regions to allow for passage of fluids when initially pressurising the system 10, such that all regions can be supplied with similar pressures. The openings may then be closed and only a relatively small volume of fluids may be allowed to pass between the regions when the system 10 is in use. Optionally, intentional leakage points may be disposed between the first region 80 and another region to allow for fluid transfer or fluid movement from the first region 80.

Separation of the regions may also be beneficial as the system 10 can be opened to allow for the removal of modules or opened for maintenance. As the access 215 of the housing 200 is mounted in the side, the access 215 is preferably adapted to allow direct entry into the first region. The access 215 may be the height of the first region, or may be sufficient to access each of the chambers individually. In another embodiment, access 215 may have two or three sections which can be used to access one or more of the regions. The first region is preferably formed with sufficient space between the module 20 and the exhaust plate 350 such that the module can be unmounted from the common rails 70 and removed via the access 215. When access 215 is opened, it is preferred that the second 82 and third 84 regions are sealed or otherwise closed to reduce the potential for venting internal atmosphere. In this way the first region 80 is vented and therefore only the first region 80 need only be pressurised after sealing the access 215. Optionally, the second 82 and third 84 regions can be opened after the access is closed to allow for fluid movement from these regions into the first region which may allow for faster pressurisation times and also increase the volume of carrier gas, or other predetermined fluids, in the first region after closing the access 215.

Second region 82 and third region 84 may also be supplied with pure carrier gases when pressurising the system if desired. These regions may then urge ambient atmosphere to the exhaust plate, which can then remove ambient atmosphere from the system 10.

In yet a further embodiment, the system is formed with only the first region 80 being filled with carrier gases, and the other regions are open to ambient atmosphere and may or may not be pressurised.

In yet a further embodiment, the fluids within the segment 15 may be drawn to the low pressure regions 55 from the high pressure region 50. The high pressure region may be created when the modules 20 are allowing the injection or flow of fluids into the segment via the manifold 107. This can increase the pressure within the local region 90, which is bound by the module 20 and the bias plate 250. The fluids from the local region and the module may then be allowed to move into the segment low pressure regions and the local atmosphere in these regions may be brought into an equilibrium with continuation of processing. The atmosphere within the low pressure regions 55 may be removed from the system via the fluid collection systems and removed from the system, such that the gases within these regions are replaced with the delivery fluids or a mixture of delivery fluids and other known fluids. As the low pressure regions accept fluids from the high pressure region, the low pressure regions may be brought into an equilibrium, or be brought to a pressure which is similar to that of the high pressure region 50.

The fluid collection system may comprise an exhaust plate 350, an exhaust array 355 disposed within the exhaust plate 350, and an exhaust system 360. The exhaust system may be used to direct the flow of fluids to a collection unit (not shown), after receiving fluids via the exhaust plate. The exhaust array may be a plurality of apertures, slits or holes within the exhaust plate which can be used to allow fluids to be drawn to the exhaust system 360. A plurality of conduits allow for the movement of fluids in the exhaust system 360 and a pump may be used to assist with said movement of fluids. As is shown, the exhaust plate is positioned relatively below the modules 20, however it may alternatively be positioned below the bias plate if the modules are disposed in a shower configuration wherein the modules and bias plate are inverted compared to what is illustrated in FIGS. 5 and 6. Exhaust array connections 370 may be used to couple the exhaust system to the exhaust plate 350. The exhaust system 360 may meet in a central location or a combined exhaust location 380 for removal, recycling or separation of fluids. Further, the exhaust system 360 as seen in FIG. 6 illustrates is enclosed within the third region 84, to assist with reducing contamination of the exhaust system 360 with fluids from outside the system. Further, if there are any leaks within the exhaust system 360 the atmosphere from the third region will enter into the exhaust system 360 which is preferably a controlled or known fluid, rather than ambient atmosphere external the system 10.

Referring to FIG. 6A there is shown another embodiment of a system 10. The system 10 comprises an entry and an exit roller device with a segment therebetween. A roll mounting device may optionally be positioned near to the entry and/or exit rollers to allow for a substrate to be unwound and fed into the system 1, and rewound at the exit end if there is a corresponding roll mounting system. The system 1 may instead be an inline system or be a part of another process, and may not require a roll mounting device.

A roller housing 347, case, fume hood, or barrier may be provided around at least a portion of the rollers, either at the entry 11A or exit 11B, to capture gases or prevent appendages of users being injured. An extraction fan, or other fluid circulation device may be used to divert gases which escape the system 10 via the rollers 340.

The segment 15 of the system 10 may be of a height which reduced the overall cross-sectional area of the system. The cross-section as shown is generally rectangular and allows for housing at least the modules 20, bias plate 250 and an inlet for the fluid collection system 40, which may be a recirculation system 40 which recirculates fluids from the modules back to the modules after a predetermined processing. The predetermined processing may include at least one of the following processes; filtering, cooling, altering concentrations of plasma fluid to monomer, or removing contaminants from processing. The system 10 may be at a positive pressure relative to atmosphere, at less than 100 pascals above ambient atmosphere for example, and the cross-sectional shape need not be configured to accommodate for pressures which may deform the housing 200 of the segment 15.

A section or segment 15 may be provided which accommodates a portion of a cleaning system and/or a lacing system. Each segment 15 or sub-segment of the system 10 may comprise a respective cooling system or fluid collection system 40 such that localised regions of the system 10 can be controlled. This may be advantageous if the start of the system 10 is desired to be of a relatively lower temperature compared with the end of the system, for example.

The bias plate 250 may be lifted or moved by a lifting system 500. The lifting system 500 may include one or more lifting devices 505, such as jacks or pistons, which allow for a relative displacement of the bias plate 250 relative to the housing top portion 205 of the segment 15, or relative to the modules 20, or relative to the electrodes 101. A lifting device member 510 may be used to mount the lifting devices 510, or the lifting system 500 may be mounted to the housing of the system 10. The support of the lifting system is shown not connected to housing 200, but will be appreciated that will be mounted to the system 10 at predetermined anchor locations.

Preferably, the lifting system 10 is adapted to lift one or more bias plates 250. A single lifting system may be used to lift at least one of; single bias plate 250, two bias plates 250, or multiple bias plates 250. Relative movement of the bias plates may allow for one edge of the bias plates to be relatively closer to the electrodes 101 than another end of the bias plate 250 if desired.

Packers or spacers (not shown) may be used to physically restrict the movement of the lifting system 500 if desired. An end stopper may be used to prevent the lifting system 500 from extending too far in a predetermined direction.

As shown in FIG. 6B, there is an embodiment of a lifting system which can be used to move a plurality of bias plates 250. The lifting system 250 comprises four lifting devices 505, such as pistons or actuators, which are connected to a frame for the bias plates 250 and lifts the frame, and thereby lifts the bias plates 250. The frame for the bias plates may be bias supports 255. The lifting system 250 may be fitted directly to individual bias plates 250, or may be fitting to a frame or support for the bias plates 250 such that it may lift a plurality of bias plates simultaneously. While it is shown that four lifting devices 505 lift the bias plates 250, the bias plates may be lifted using one or more lifting devices 505. A stopper or abutment means may be provided within the system, or on the modules 20 to prevent the bias plates moving too close to the electrodes 101 such that they can be damages or that the gap between the electrodes and the bias plate is too small as to not allow for passing of a substrate 1 therebetween. Optionally, the bias plate(s) 250 can be lifted by the lifting device 500 to allow for the lacing system 400 to pass the substrate 250 between the electrodes 101 and the bias plate 250 to allow for treatment to occur.

A relative vertical movement may be provided by the lifting system 500, and the lifting system 500 may be adapted to be mounted on the exterior of the system 10, with the lifting devices 505 extending into the system 10 and surrounded by a seal which prevents or reduces fluid loss from the system. Any predetermined gasket or seal may be used to seal the lifting system with the segment housing 200.

In a further embodiment, the system 10 is adapted to remove contaminants from fluids collected recycle recovered fluids, which may be by fractionation methods. A preferred method of fractionation may include cryogenic fractional distillation, which may also extract nitrogen, oxygen, neon, krypton and xenon from exhaust fluids if an argon is not used within the system. If argon is used, cryogenic fractionation may be used to perform a cooling and/or condensation process to filter argon from other fluids collected. Other extraction or recovery methods may be used depending on the fluids used within the system 10.

Fluids may exit from the local region over the sides of the module housing or through the weirs 166 which can be formed in the sides 162 of the module housing 160. The weirs 166 are preferably shaped to direct fluids down and towards a collection bed or exhaust plate 350. Weirs 166 may be angled to direct fluids to a collection system 40 or other desired location within the segment 15, such that fluids directed via weirs have little to no impact on the treatments applied via the modules 20. In an unillustrated embodiment, the module housing 160 may be formed from two generally L-shaped elongate elements which spans between the manifold blocks, and therefore can define a gap under the module if desired, which can be used to easily allow for fluids to exit the module 20 to the segment chamber which can then enter into the fluid collection system 40 (recirculation system). In yet a further embodiment, the module housing 160 may comprise holes or apertures within the underside to allow for fluids to pass into the chamber of the segment 15 more easily. A pump may be used to draw fluids towards the collection bed and may assist with collection and recycling of unused delivery gases, monomer and polymer from the modules 20. Filtration systems may be used to separate monomers from fluids which may then be reused or disposed of appropriately. Alternatively, collected fluids may be stored and collected to be separated or recycled off-site.

Fluid collection systems 40 may be positioned relatively underneath a substrate (See FIG. 6) during processing and have a collection reservoir which may be used to collect fluids passing through the substrate (if the substrate is porous enough) or may be used to capture runoff fluids from the substrate or fluids which exit a module and are not deposited onto the surface of a substrate 1. A vacuum apparatus may be used to draw in unused fluids for collection and recycling. The vacuum may also be used to draw down a substrate and retain the substrate in a desired position.

In one embodiment the collection system comprises a reservoir with a mesh or permeable upper surface (not shown) which can be used to support a substrate 1. The mesh may allow fluids to pass through into the reservoir and be taken away from the processing area to be reused, recycled or disposed of. Gases or fluids not consumed during processing may be captured and recycled by the system. Gas extractors or drains may be used to collect excess fluids which can either be responsibly disposed of or recycled for use by the system 10 or may be collected for use elsewhere. As the system preferably uses a high purity of gases, monomers and chemicals, it may be advantageous to collect and separate impurities within a gas, monomer or chemical such that the gas, monomer or chemical can be reused within the system 10. In this way, waste products from the system 10 may be reduced or otherwise eliminated.

Optionally, filters may be used to assist with capture of fluids or filtration of fluids captured. For example, carbon filters or no-woven material filters may be used to capture fluids and retain potentially harmful fluids therein. Fluids from filters may be extracted at a later time if desired.

Gas extraction methods may include ventilation and fan systems which can be used to extract used plasma fluids and monomer from the system. The monomer and plasma fluids can be collected or redirected after leaving a module 20 if they are not bonded to a substrate 1.

Cooling systems may be used wherein the electrode can be cooled with liquid cooling. Suitable liquids may include plasma gases and inert gases. The utility of using plasma gases is that if there are electrode failures or faults and cooling fluids leak into the plasma region, the electrodes will lose cooling but coating quality will not degrade or contaminants will not be introduced into the system.

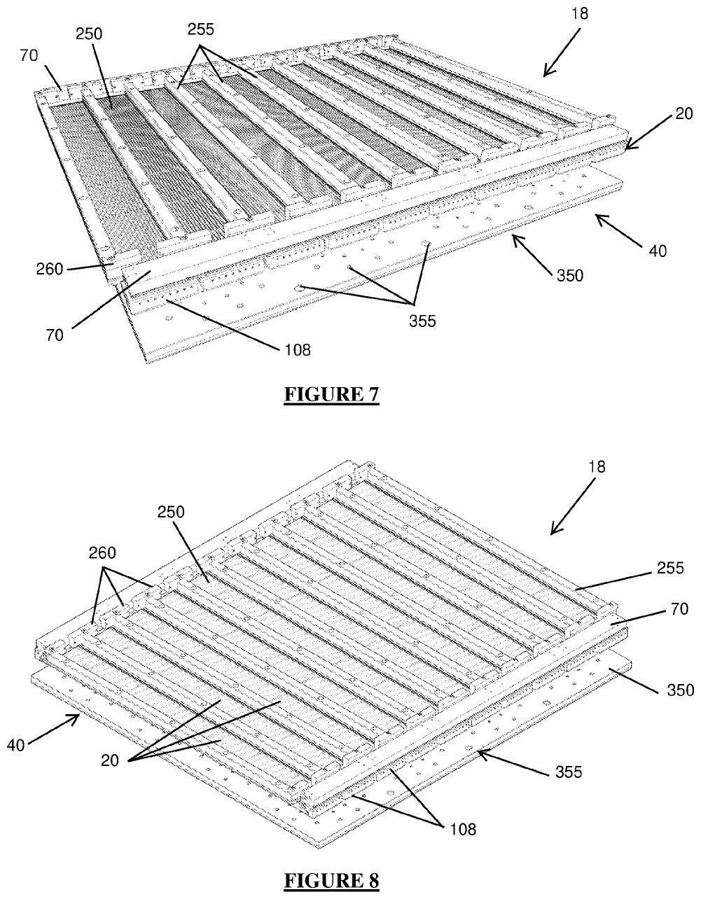

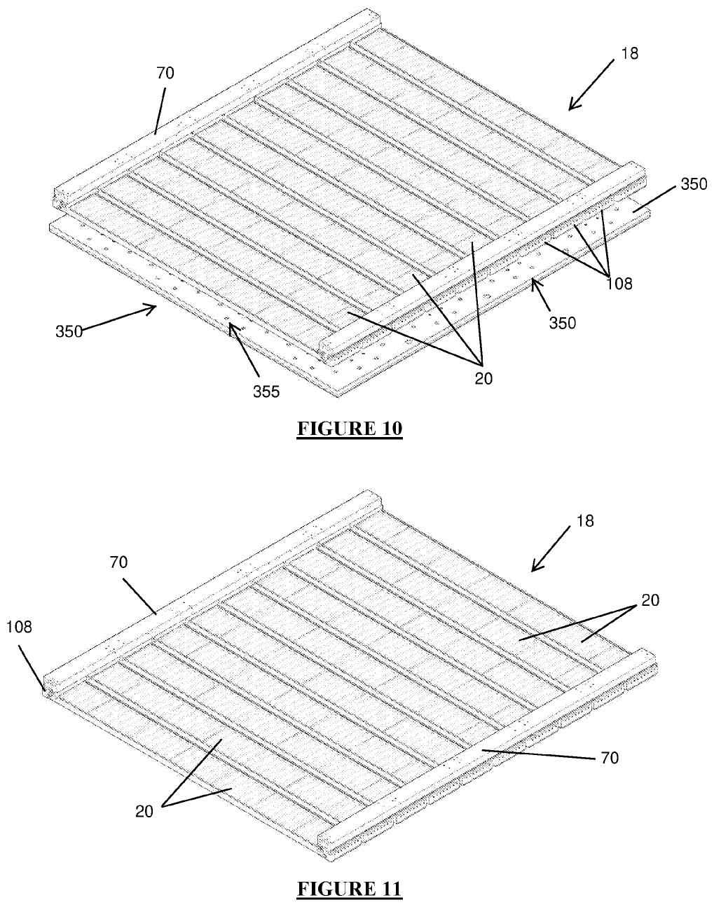

Referring to FIGS. 7 to 11 there are illustrated various views of a module array 18 which can be installed into a segment of a system 10. The module array 18 comprises a plurality of modules 20, which are aligned generally parallel respectively. A common rail 70 is located at each end of the modules which is adapted to deliver fluids and power to the modules 20. The modules 20 may be connected to and suspended by the common rails 70. The Figures also show sections of the support structures, bias plates and exhaust plate being removed to view the modules 20.

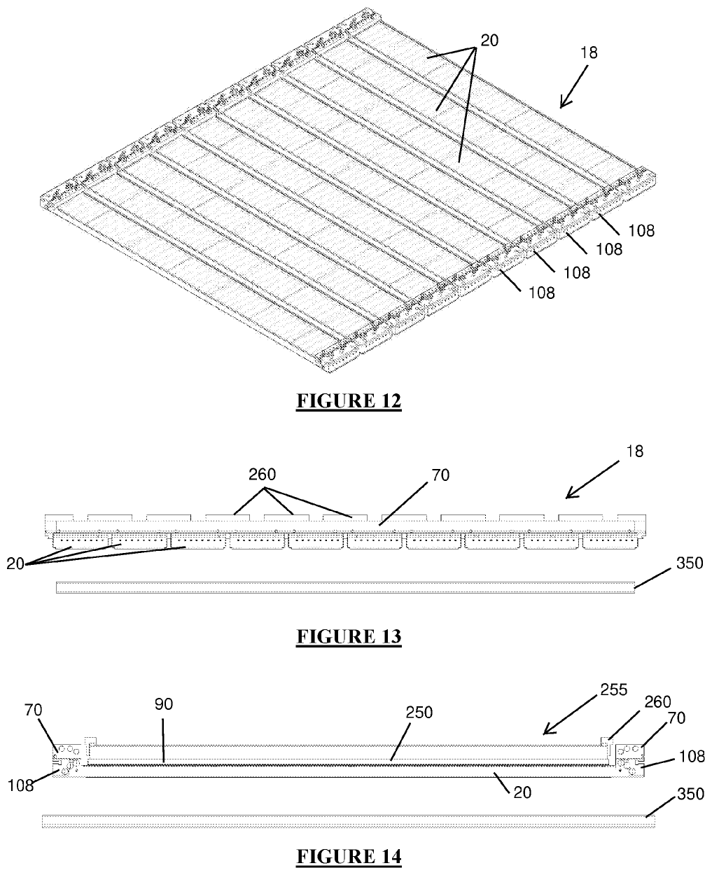

FIG. 12 illustrates a plurality of modules 20 which are evenly spaced and may be connected to respective common rails 70 at each end of the modules 20. The modules can be connected to the common rails 70 at the manifold blocks 108. The gaps between the modules 20 may allow for fluids to flow from the modules and substrate 1 and down to the exhaust plate.

In FIGS. 13 and 14, there is illustrates side and front views of a module array 18 with an exhaust plate relatively below which can collect or disperse the fluids from the local region 90 and the modules 20. The distance between the modules and the exhaust plate may be any predetermined distance. In yet another embodiment, the exhaust plate may also be used to more evenly distribute fluids to the low-pressure regions of the segment, or direct fluids into the exhaust system 360.

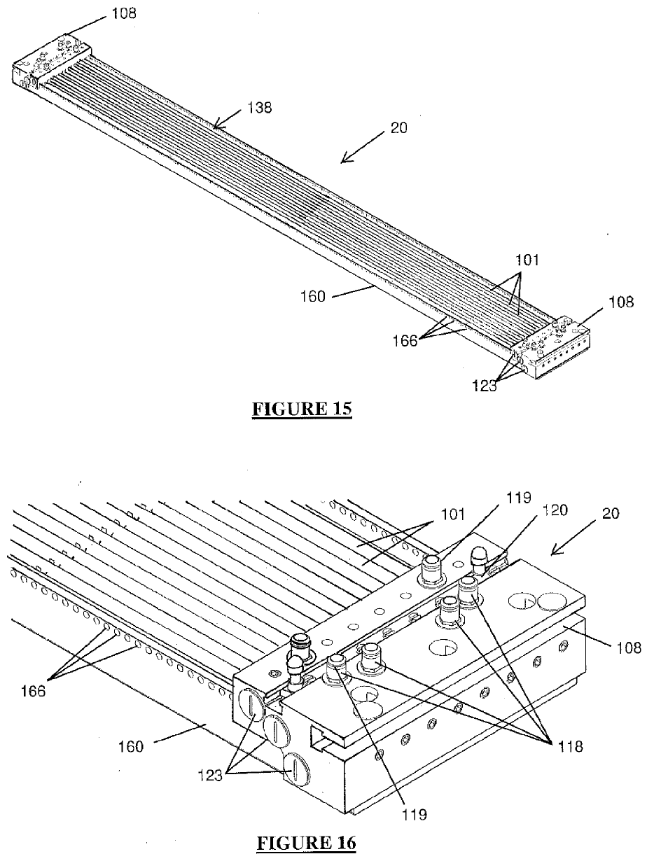

FIG. 15 illustrates a perspective view of an embodiment of a module 20 with a plurality of electrodes 101 which may be used to generate a plasma region 106 (see FIG. 18). The electrodes 101 shown are a series of alternating electrodes 101 comprising positive and negative electrodes, or ground electrodes and radiofrequency (RF) electrodes in other embodiments. A plasma region 106 may be made between two adjacent electrodes when the electrodes are suitably charged and with the presence of a suitable delivery gas. As discussed above, the delivery gas may be an inert gas which can be charged and causes ionisation of the gas to generate the desired plasma region, such as a noble gas. In other embodiments, the gas can be oxygen or another fluid which can be energised to form a plasma. The desired plasma region may have the following levels of ionisation; weak ionisation, partial ionisation or full ionisation of fluids in the plasma region. The extent to which ionisation occurs depends on the frequency and/or voltage applied to the electrodes and may also relate to operational temperatures. Different levels of ionisation may have different functionality for treatment and coating processes and levels may be varied depending on the substrate 1 and desired treatments. However, generally the plasma may be desired to be partial to full ionisation to form a relatively more stable plasma region. As inert gases move from a charged state the molecules will return to their original inert state without reacting with other elements or compounds near to or within the plasma region. Some fluids supplied to the plasma region may generate degradable gases (such as ozone), particularly when ionising atmospheric gases, which may be used to sterilise a substrate, and may degrade within a reasonably short time period to form breathable gases. Non-inert gases may have utility for cleaning and activation of the surface of a substrate, and therefore may have utility with being introduced to a plasma region for ionisation.

Plasma cleaning uses an ionised gas (such as the ionised delivery gas in the above-mentioned embodiments) to remove organic matter or other contaminants from the surface of the substrate 1. It will be appreciated that the delivery gases used for cleaning processes may include, but are not limited to, at least one of oxygen, argon, nitrogen, hydrogen and helium. Based on the composition of the delivery gas, the sterilisation or cleaning processes may be used to modify the surface tension, modify the surface energy, modify contact angle properties, improve inter-surface bonding and/or adhesion, removal of oxides from the surface of a substrate, alter surface wettability to create hydrophobic or hydrophilic properties, or be used for coating processes such as those for imparting a property or improving a property such as; adhesion, wettability, corrosion and wear resistance, electrical conductivity and insulation, magnetic response, reflective/anti-reflective, anti-microbial, anti-scratch, waterproofing, tinting.

In yet another embodiment, a module 20 may use plasma activation processes in which a polymer can be treated to improve its ability to be painted or printed on. This may be achieved by using oxygen plasma to oxidize the outer layer of the polymer. Metals that oxidize easily may be treated with an argon delivery gas. This produces not only a clean product, but also an increase in the polar groups, directly improving the printability and coatability of the polymer product. Oxygen argon plasma can also used for plasma activation in some processes.

Ionised fluids in the plasma region may be urged to the substrate 1 under gravity as the system is adapted to operate in atmospheric conditions (±3%). As plasma may be influenced by magnetic fields and electromagnetic fields or radiation, the plasma region 106 may be subject to at least one of a magnetic field or magnetic radiation which may assist the movement of the ionised fluids in a desired direction. Movement of ionised fluids may be urged towards a substrate 1 which may also improve interaction and/or treatment rates, thereby improving the processing speeds of the system 10.

However, it is preferred that a bias plate 250 is used which can assist with drawing ionised matter from the plasma region 106. As such, the bias plate 250 may be disposed on the other side of the substrate, such that the active plasma region 106 is generated between the electrodes and the bias plate assists with urging ionised matter towards the substrate 1. The bias plate 250 may be charged or grounded as desired. This may allow for movement of positively and/or negatively charged ions (cations and anions) from the plasma region 106. Optionally, the bias plate 250 may be pulsed or charged periodically to assist with drawing ions form the plasma region.

A plurality of bias plates 250 may be disposed above the modules 20 of a segment 15, which may be supported in a predetermined position by a bias support 255, as seen in FIGS. 7 to 9. The supports extend between the common rails 70 of the segment 15, or may extend perpendicularly to the direction of movement of the substrate. The supports 255 comprise a flange 257 or other securing means to secure the bias plate 250 in a predetermined position. The flange 257 which supports the bias plate 250 may project from the support 255 and extend along the axial direction of the support 255. The support 255 may be formed from a box beam, or another elongate element which can support loads of up to around 100 kg. The bias support 255 may be mounted onto the common rail 70 at the ends by a bias support end 260. The bias support ends 260 may be mated with the common rails 70.

The bias plates 250 can be passive bias plates wherein these plates are earthed or provide a further negative location to improve the flow of excited materials from the plasma region towards the local region. Optionally, the bias plate 250 can be selectively charged and grounded to encourage positive ions and electrons to flow from the plasma region to the local region. The bias plate 250 may also more evenly disperse matter from the plasma region 106 between the electrodes 101.

One or more bias plates 250 may be installed within a segment 15 and may be positioned above the modules 20, when the modules are inverted or in an “upside down” configuration 20, as is illustrated in FIG. 2 or 11, for example. The bias support 255 may extend over the modules 20 and may span between the common rails 70. A bias support end may be connected to the common rail 70 and the bias support 250 and maintain the bias support in a desired position relative to the modules 20.

In another embodiment, the bias supports 255 may be mounted to the housing of a segment 15. The supports may be fitted with actuation means to allow for raising or lowering of the bias plates 250. Electrical connections for the bias plate 250 may be mounted with the supports 255. Connection of the electrical connections to a power source 30 may be provided via the common rails 70.

In another embodiment, a high-pressure region proximal the electrodes and low pressure region proximal the substrate may be created which can cause fluids to flow from the plasma region 106 towards the lower pressure region. Preferably the high-pressure region 50 is above the electrodes 101 and the low pressure region 55 is near to the treatment surface of the substrate 1 causing ionised fluids to move towards the low pressure region 55 which may more effectively cause a desired flow of plasma or fluid flow. The low-pressure region 55 may alternatively be generated below the substrate 1 which may cause a similar improved flow of fluids. Changing the pressure of the high pressure and/or the low-pressure regions may be used to increase or decrease flow of plasma or other fluids to the substrate 1.

Referring to FIG. 8, there is shown an embodiment of a module array 18 which may be form a portion of a segment 15. Delivery gas and fluids can be provided to the modules 20 via the common rail 70. The common rail 70 comprises at least one fluid channel which can be used to deliver a delivery gas to a module 20, or may be used to transport a monomer or a coolant fluid to and/or from the modules 20. Common rail 70 comprises at least one channel, but more preferably comprises at least two channels. The channels may be fluid channels, connection channels and/or sensor channels. A fluid channel may be used to deliver at least a portion of the fluid to the manifold 108 to subsequently be ejected from the inlet manifold 109. Optionally, a valve may be provided on each of the manifolds 107 which can be used to selectively allow or prohibit the flow of fluids.

Fluid channels 72, 74 may be used to deliver monomer and/or plasma fluids to the manifold 108 and/or deliver and remove coolant to the electrodes 101. A connection channel 76 may also be provided which allows for connection of electrodes to a power supply.

The fluid channels may also be used to provide a coolant to the electrodes 101. The coolant may be a liquid or a gas, for example water or an inert gas(es). The coolant is passed through the electrode fluid channel 104 of the electrode. The core 102 of the electrode 101 is preferably formed with the fluid channel 104 extending therethrough and is sized to fit within the sheath 104. Collectively an electrode may be formed from a sheath 103 and a core 102. While it is preferred that the core comprise a fluid channel 104, the core may be formed with a solid core if the temperature is within a desired range during use. Fluids provided to the electrode fluid channel 104 may be recycled or recirculated to maintain a desired electrode temperature, or reduce the temperature of the electrodes when desired. Coolants may be pumped into the system by a cooling system.

Electrodes 101 may be formed with any desired shape. In the embodiments illustrated, the electrodes 101 are generally circular in cross-section, however the electrodes may be any predetermined shape to impart a desired fluid flow or generate a desired plasma in the plasma region. Other suitable shapes may include, but are not limited to; rectangles, triangles, droplet, squirkle, semi-circular, ovoid, or any other regular polygonal shape. The shapes in which the electrodes are formed may impart a desired fluid flow to the substrate, or prevent an undesired backflow.

The manifold 107 of the modules 20 is connected to a common rail 70 which can be used to provide fluids to a segment 15. Referring to FIGS. 16 to 21, there is shown a number of embodiments of modules and components therefor. FIG. 16 shows the manifold 107 and the electrodes 101 of the module 20 within the housing 160. FIG. 17 illustrates the module 20 without the manifold block installed on the manifold mount 122.

The embodiment of FIG. 17 illustrates electrodes 101 extending through the sheaths such that alternating cores 102 extend into the region of the manifold block 108 at a first end of the module 20, and the opposing alternating cores 102 extend into the region of the other manifold block 108 at a second end of the module 20. In this configuration the electrodes 101 can inhibit the formation of plasma near to the manifold block, which can reduce local temperatures, or arcing if desired. The sheaths 103 of the electrodes 101, may optionally be of equal length and terminate in the same plane or be mounted evenly such that their ends align. However, as pictured the sheaths 103 may be staggered in an alternating fashion. This may allow for plumbing of the electrodes 101 to predetermined fluid channels 72, 74.

The channels 74 and 76 may be adapted for delivery of coolant to the electrodes, and removal of heated coolant from the electrodes. Channel 72 may be adapted for delivery of monomer, and/or precursor, and/or plasma fluid to the manifold 107. Heated fluids from the electrodes 101 can be delivered to a chiller or other cooling system to allow for the regulation of coolant temperature.

In yet another embodiment, channels 74 and 76 form part of a liquid cooling system 35 for the electrodes. The liquid of the liquid cooling system may be cooled with a chiller or cooling system, which may be internal or external the segment 15. The liquid in the liquid cooling system may be any predetermined liquid which allows for a desired thermal transfer. A predetermined liquid may include but is not limited to; water, ethylene glycol, Dynalene, propylene glycol, deionised water, Galden, Fluorinert, liquid nitrogen, monomer, or a combination thereof. Other liquids may also be used to maintain a desired temperature within the system 10.

It will be appreciated that the liquid cooling system can be used to impart a desired temperature to the liquid, and the flow rate of the liquid cooling within the system is dynamic to allow for the desired temperature to be imparted to the electrodes for predetermined processes.

The liquid cooling system may transport fluids with the use of a negative pressure such that the liquids are pulled or sucked through the system, rather than pushed. This is advantageous particularly is there are any seals which become compromised, and also reduced pressure on seals within the recirculation path of the liquid. This may also be advantageous if there is damage to an electrode, such as cracking or fracturing, and provides a further failsafe for ingress of water or liquids entering the system. This is also particularly of note as power required to maintain a stable plasma may be impacted by the presence of water or moisture within the system 10. This is to say that control over the stability and quality of the plasma can be negatively impacted with the unintentional addition of water within the system. In other embodiments it may be advantageous to include water or water vapour to improve the functionality of a coating.

In a further embodiment, liquid cooling system may be a gas cooling system wherein the liquid is replaced with a gas and/or an aerosol. The gas cooling system may function in a similar manner as that of the liquid cooling system. The gases which may be used within the gas cooling system may be oxygen, argon, air, xenon, fluorine, helium, neon, or any other desired gas. It may be preferred that the gas within the cooling system is an inert gas such that any leaks into the chamber do not adversely impact the coatings applied. It will be appreciated that reactive gases may also be used in some embodiments, such as air, oxygen or nitrogen, for example.

In yet a further embodiment, at least one of channels 74 and 76 are a cavity 77 wherein a busbar, which may be electrical electrode connector 121, may be mounted to provide electrical connection to the cores 102. In this way the busbar may also can be cooled by the coolant and thereby be operated within a desired temperature range.

In an unillustrated embodiment, the cores 102 extend to the manifold block at both ends of the module 20. The sheaths 101 extend to both ends of the module 20 with each sheath extending a respective first fluid channel to a second fluid channel, wherein the first channel delivers coolant, and the second fluid channel allows for removal of the coolant. Coolant may be provided to the core of the electrode, and also between the sheath 101 and the electrode 102.

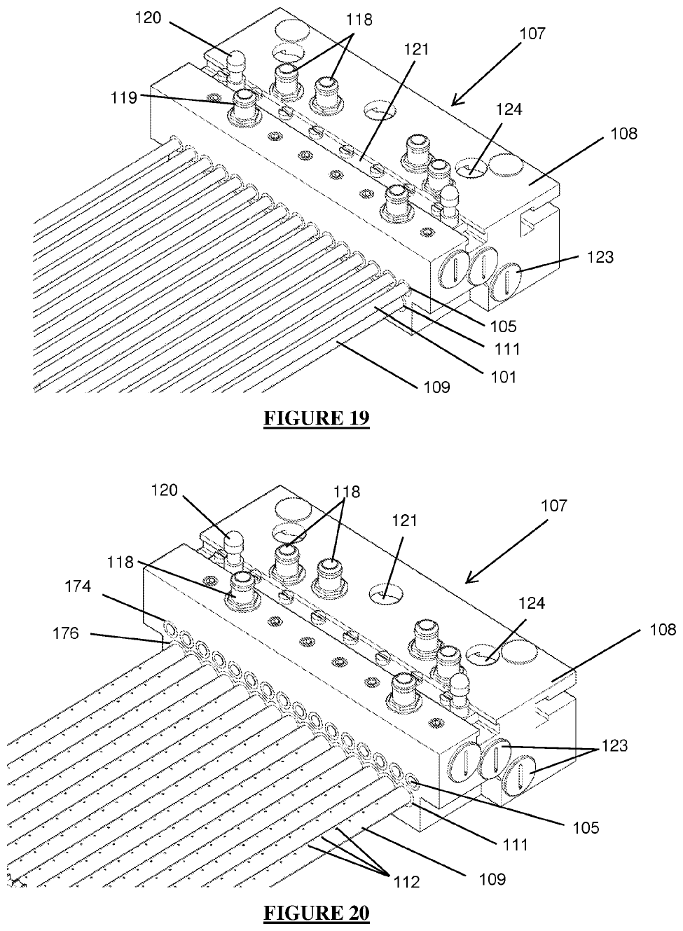

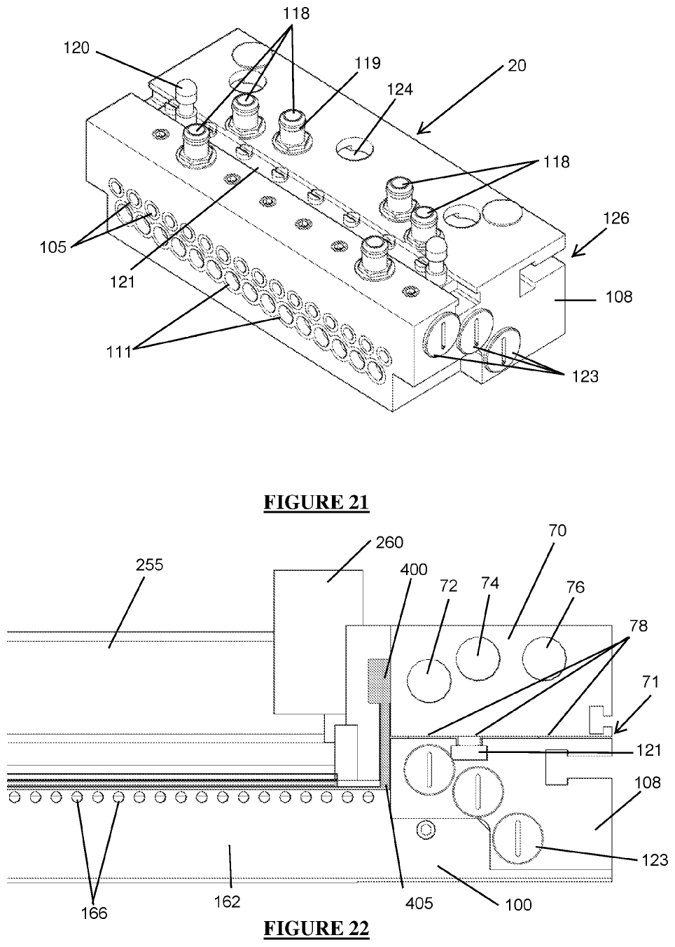

FIG. 19 shows the housing 160 of the module removed, and FIG. 20 shows the manifold 107 of the module 20. The block 108 can be fixed with the manifold mount 122 by any desired means, such as a nut or thread. The manifolds comprise a manifold block 108, an inlet manifold connected to the manifold block, and optionally an inner manifold which can be received within the inlet manifold. The inlet manifold may be tubular to allow for fluids to pass from the inner channel and out into the segment via the manifold outlets 112. The manifold outlets 112 can be of any predetermined size or shape to allow for a desired dispersion of fluids into the segment. Preferably, the inlet manifolds 109 are positioned adjacent to the electrodes 101 and the outlets 112 are directed to disperse fluids into the plasma regions 106 between the electrodes 101. The inner manifold may be mounted within the inlet manifold channel and may be connected to a fluid supply of the manifold block 108. The inner manifold may have a plurality of apertures or slits through which fluids can be supplied to the inlet manifold 109. In this way the inner manifold 110 can supply the inlet manifold with fluids with a more even pressure across the length of the inlet manifold 109, which may improve fluid dispersion and distribution into the segment 15. The manifold blocks 108 may be integrally formed with the module housing 160, or are removably mounted thereto. In another embodiment, the manifold blocks are formed with the common rail and the module electrodes are removably mounted thereto. Similarly, the inlet manifold 109 may be removably mounted to the manifold blocks 108. Referring to FIGS. 20 and 21, illustrate seals mounted in the manifold block 108, which can securely seat electrodes 101 and the manifold inlets 109. These seals may be formed from a suitable sealing material, such as epoxy, silicone, polymers or rubbers. The seals 105, 111 may be shaped to conform to the geometry of the electrodes 101 or the inlet manifold 109. The electrode manifold seal 105 may be mounted in electrode aperture 174, and the inlet manifold seal 111 may be mounted within the manifold aperture 176. In another embodiment, the electrode seals 105 and the inlet manifold seals 111 may be cast after the electrodes or inlet manifolds are seated to ensure a fluid tight fit with the manifold block 108.

Optionally, the manifold 107 or common rail may comprise a fluid flow control means which be used to restrict flow of fluids supplied to the inlet manifold 109. Conventional valves may be installed within the common rail 70 or the manifold 107 to alter the flow of fluids through the module 20, which can also be used to increase or decrease the pressure of the fluid exiting the manifold outlets 112 into the plasma region 106. The fluid flow control means can therefore be used to more effectively control ejection (or exit) of fluids from the manifold outlets 112 and optionally impart a desired effect to a fluid exiting the outlets. In yet another embodiment, the manifold is provided with at least one of a vaporiser, mister, aerosoliser, spraying device or other means to convert the state of a fluid. It is preferred that fluids exiting the outlet 112 are dispersed such that more complete or faster ignition and/or ionisation of fluids can occur. This may also provide for a more even plasma density across a plasma region 106 which can be more effective to treat a substrate 1.

In another embodiment, the manifold 107 may be fitted with separate monomer and plasma gas inlet manifolds 109 which can individually allow for the distribution of the respective treatment fluid. In this way the monomer and the delivery gas may optionally be mixed at the time of injection or release between the electrodes 101. This may provide a more effective delivery method for delivering a monomer and may allow for more precise concentrations to be introduced to the plasma region 106. The common rail may have more than one fluid channel which can be used for delivering fluids to the module 20. The outlets 112 of the inlet manifold 109 may also be shaped to impart a desired fluid flow to the fluids exiting the outlets. For example, flow restrictors, baffles, projections, tapered apertures, plugs, spigots, and predetermined aperture geometries. Imparting a desired fluid flow to the fluids may improve the delivery rate of fluids to the substrate surface 1 or the plasma region 106. Further, having individual inlet manifolds may also allow for fluids to be delivered with different temperatures, different flow rates, and/or different volumes, and may also allow for fluids to be selectively turned off or flow rates altered to achieve a desired flow and/or mixture. Preferably, the temperatures of the fluids are in the range of around 0° C. to 40° C.

The number of electrodes 101 used for a module 20 may depend on the desired processing and/or the substrate 1 to be processed. More preferably, the number of electrodes 101 corresponds to the number of inlet manifolds 109 of the module 20 (the number of electrodes 101 is equal to the number of inlet manifolds 109 plus one electrode 101). It will be appreciated that fewer electrodes 101 may be used to generate the plasma, however this may also reduce the strength of the plasma region 106 and raise operational temperatures required to maintain a desired/consistent plasma region 106.

In some embodiments, reducing the distance between the plasma region 106 and the substrate 1 may also reduce the overall energy requirements of the system 10. In one specific embodiment, the distance between the electrodes and the substrate 1 may be in the range of 3 mm to 5 mm, and more preferably is around 4 mm. Reducing the distance between the electrodes and the substrate may also reduce the profile of the system 10.

In another embodiment, reducing the cross-sectional area of the electrodes 101 may also reduce the energy requirements of the system 10. Further, the wall thickness of the geometry may also dictate the power required to energise the electrodes 101 to form a plasma. As such, circular wall thicknesses may provide for a more even generation of plasma density.

Electrodes 101 may be fabricated with a hollow structure, round, ovoid, square or rectangular stainless steel, aluminium, copper, or brass tubing, or other metallic conductors. The hollow structure may be concentric or otherwise generally conform to the shape of the electrode outer wall. The inner wall of the hollow structure may be coated with a corrosion resistant material such that coolants can be in contact with the inner region of the hollow tubular electrodes 101. A dielectric coating may also be provided to outside of the electrode 101.

In one embodiment, the electrodes 101 may be formed with a width of between 0.5 cm to 3 cm and a height between 1 cm to 3 cm. The cross-section of the electrodes 101 is preferably uniform along the length of the electrode 101 such that a relatively more uniform plasma field can be generated. It will be appreciated that in other embodiments, portions of the electrodes 101 may have a different diameter, cross-sectional area or cross-section such that differing effects or strengths may be imparted to a plasma region 106.

Delivery gases provided to the manifolds 107 may have an aerosol comprising droplets of monomer, and optionally nanoparticles, with a delivery gas, such that when the delivery gas is ionised, the monomers are polymerised. A monomer may be dispersed within the delivery gas prior to reaching the module 20 To reduce energy required by the system 10, a monomer may be in a liquid state prior to interaction with a delivery gas which may then vaporise or aerosolise a monomer.

A plane of the electrodes 101 may be defined as being generally parallel to the plane of the inlet manifolds 109 as can be observed in FIG. 18. Each electrode 101 may be positioned offset from the manifold outlets 112 to allow for delivery gases to more effectively be provided to between electrodes 101 to generate a plasma region 106. It is preferred that the electrodes 101 have a uniform spacing such that corona discharges are less likely to occur during use which can damage electrodes. A module rack 138 may be provided within the housing 160 which can support at least one of the electrodes and the inlet manifolds. An embodiment of such a rack 138 is illustrated in FIG. 18. The module rack comprises an electrode rack 140 may be used to mount the electrodes 101 with a desired spacing such a minimum or maximum distance can be achieved consistently which may improve the plasma region 106 generated, and also a manifold rack 146. The manifold rack 146 and electrode rack 140 may be integrally formed, or may be formed separately and optionally joined together. The electrode rack shown comprises a plurality of electrode recesses 142 at the end of projections 144 extending from a body portion. The manifold rack 146 is formed with recesses 148 to accommodate the inlet manifolds 109. The electrode rack may also be formed with a recess or other feature which can conform to the geometry of the inlet manifold. The embodiment shown comprises a separate electrode rack 140 and manifold rack 146 which are joined or mated together. Optionally, the electrode recesses may be fitted with a securing means, to secure or retain the electrodes 101 in the recess during use. This may be of particular advantage when the modules are configured to suspend the electrodes 101 over a substrate or article.

Electrodes 101 may be coated with a dielectric, and similarly other components of the module may also be coated with a dielectric. Said other components may include, but are not limited to; inlet manifolds 109, racks 138, 140, 146 and the housing 160. The dielectric may comprise a material such as PET, PEN, PTFE or a ceramic such as silica or alumina, however other materials may also be used for the dielectric material. Dielectric materials may be used to form the sheath 103 of the electrode 101. Preferably, if ceramics are used, the ceramics are non-porous such that the potential for damage to electrodes is reduced from fractures or other physical failures. This may assist with the lifespan or durability of the electrodes during use. Other materials may be used to fill gaps within porous ceramics which can assist with heat reduction or cooling of the electrodes during prolonged use.

An electrode rack 140 may also allow for displacement of electrodes 101 relative to the outlets 112 of an inlet manifold 109. While electrodes 101 can be displaced, the electrodes 101 are preferably uniformly disposed in an electrode rack 140. The electrode rack 140 may be used to support sections of the electrodes 101 along the length. The relative height of the electrode recesses 142 may correspond to the heights or relative heights of the electrode manifold seals 105.

In another embodiment, a plurality electrode racks 140 can be connected together via a rack connector (not shown). The rack connector may be a similar means as that used to connect together the electrode rack 140 and the manifold rack 146, if these are formed separately.

Referring to FIG. 21 there is illustrated electrode manifold seals and inlet manifold seals which allow for mounting of the electrodes 101 and the inlet manifolds 109, respectively. The seals are preferably fluid tight and may be formed with the use of a rubber, epoxy or polymer for example, and can preferably withstand operating temperatures in the range of 0° C. to around 300° C. Higher temperature ranges are also anticipated and will depend on temperature of the electrodes and/or the plasma, and whether active cooling systems are used. A seal recess is formed within the module block 108 and is adapted to receive the seals. Optionally, the electrodes and the inlet manifolds may be mounted in place and the seals may be formed around the electrodes 101 and/or the inlet manifolds 109. In another embodiment, a polymer cover can be mounted within the recesses of the manifold block 108 to receive the electrodes 101 and/or the inlet manifolds 109.

Preferably, the manifold blocks 108 and/or the module housing 160 of the modules 20 are formed such that correct placement of the electrodes 101 can be ensured. It will be appreciated that while cores 102 may be staggered the sheaths 103 may have a uniform configuration without evidence of staggered cores 102 when mounted.

Modules 20 or an array of modules 18 may each have a respective power supply coupled thereto, or each segment 15 may have a respective power supply coupled thereto.

Coatings may be applied to electrodes 101 with conventional dipping and heat treatment processes. Tempered glass, annealed glass, and toughened glass may also be used to form a sheath 103, a shell or coating on the electrodes 101 which may reduce the porosity at the surface of the electrode 101. Tempered glass may include borosilicate glass, gorilla glass, safety glass, laminated glass, fire glass, superglass, lead glass and low iron glasses.

Dielectric material thickness may be in the range of 0.5 mm to 3 mm from the core of the electrode 101. The dielectric properties of the material should be sufficient to withstand temperatures of at least 40° C., but more preferably may withstand temperatures of at least 100° C. In other embodiments, the dielectric material can be heated to temperatures of around 100° C. to 650° C. without failure of the dielectric. The dielectric material may be selected from the group of; ceramics, alumina, paper, mica, glass, polymer, composites of the aforementioned, air, nitrogen, and sulfur hexafluoride.

Alumina (aluminium oxide) may be used to form the electrodes. Preferably, alumina 90% to 99.5% may be used to form the electrodes. Preferably, 92%, 95% and 97% alumina are preferred in some specific embodiments. While it is preferred that at least 90% alumina materials are used, other embodiments may allow for the used of a minimum of 80% alumina or higher. Alumina selected preferably have a flexural strength in the range of 280 Nm to 365 Nm, and with a hardness R45N between 72 to 83.

Barium strontium titanate (BST) and ferroelectric thin films may also be used for dielectric purposes in some embodiments. These materials may be formed in laminations or applied to the surface of the core 101A of the electrode or to a surface of a sheath 101B or dielectric material.

Poly(p-xylylene), also commonly referred to as the trade name “Parylene”, coatings can also be used to assist with dielectric properties of the electrodes 101, and may also be coated onto electrodes 101 to assist with hydrophobic properties of the electrodes 101, which may reduce build-up of monomer and/or polymer. Further, hydrophobic coatings may assist with reducing the frequency of cleaning electrodes 101 if monomers or chemistry are changed for different treatment processes. Preferably, Parylene coatings are selected which can withstand short and long term temperature exposure.

The system may be fitted with anti-arcing means which may activate when the potential for arcing exceeds a predetermined limit. Such anti-arcing means may be adapted to perform at least one of the following functions; reduce the volume of fluids from the outlets 112, reduce power, reduce current, reduce voltage, alter the frequency and shut-off the system 10. Anti-arcing means may be in communication with individual modules 20 or an array of modules 18.

Introduction of a monomer may form a Penning mixture with the plasma gases, which can assist with Penning ionisation, particularly at pressures near to atmospheric pressures, to thereby form a desirable plasma cloud or plasma glow within the plasma region 106. The monomers may be injected as a liquid spray, a vapor or atomized particles and may assist with forming desirable plasma conditions as monomers may be adapted to stabilise a plasma streamer or plasma corona condition.

Penning traps may be used to reduce movement of ionised particles in one or more predetermined directions, and/or urge ionised particles or polymerised monomer in a predetermined or desired direction.

Recirculation of monomer, polymer and plasma fluids may be achieved by recirculation equipment. Optionally, a photo ionisation detector or other monitoring/sampling device may be installed within the recirculation equipment, such that the collected fluids from the system 10 can be assessed to determine the volume of monomer or precursor to be added to the fluids supplied to the modules 20 to allow for a predetermined treatment. Sampling by the monitoring/sampling device may be periodic or constant.

Production monitoring equipment may include infra-red (IR) systems, such as Fourier-transform infrared spectroscopy (FTIR) devices, which can detect the presence of monomer compounds on a surface of a substrate. In another embodiment, profilometer measurements may also be taken at predetermined intervals on a substrate. Other monitoring systems may also be used to detect the thickness of coatings applied to a substrate.

Methods for treating a substrate 1 may include providing a polymer to a substrate, having a generally sheet or planar form, in which the polymer has been formed by plasma polymerisation. The substrate 1 may have at least one fibre or yarn exposed at a surface which can be treated by the system 10. Polymers may be formed by plasma at atmospheric pressure wherein the energy of the plasma is sufficient to cause fractionation and subsequent polymerisation of monomers and subsequent bonding of the polymer to a substrate 1. The thickness of the polymer coating applied to the substrate 1 may be dependent on the density of the plasma, the coating time, and the volume of monomer introduced into a plasma region 106.

In yet a further embodiment, the plasma may be used to treat only a first side of a substrate 1, while the second side of the substrate may be protected from treatments, or may be separately treated by a different coating or treatment process. This may allow for selective modification of one side of a substrate which cannot be achieved by conventional coating methods.

Processing speeds may be used to press or bias the substrate in a desired position during treatment, such as elevating or pressing the substrate to the bias plate 250. Biasing the substrate to the bias plate may provide for a generally consistent distance between the substrate and the electrodes 101 during processing. In some embodiments, the processing speed of the substrate is in the range of 0.01 m/s to 20 m/s depending on the length of the system 10 and the desired treatment process. Exposure time of the substrate is preferably sufficient to allow for application of a coating in the range of 5 micron to 100 nm thick. Exposure time of the substrate will be dependent on the speed of the substrate, the desired thickness of the coating and polymerisation rate of monomer species.

A bias plate 250 may be used to attract ionised matter which can assist with increasing deposition rates or imparting a fluid movement to the ions. Preferably, the bias plate is a DC bias plate which is negatively charged. It will be appreciated that the bias plate may be positively charged if desired. Penning traps may be used above and/or below the plasma region, such that ionised matter in the plasma region can be repelled or attracted in specific directions. Preferably, if a Penning trap is used, the polarity of the Penning trap is opposite that of the bias plate 250, if the bias plate is present. A magnetic field may also be used to induce movement of ions within a plasma region and can urge positive and/or negative ions in a desired vector or direction.

In another embodiment the substrate 1 is not exposed to plasma, but only plasma polymerised species or coatings formed by plasma. Other embodiments may allow for pre-treatment of a substrate with plasma to clean or activate a surface of the substrate and subsequent coating without exposure to plasma, but being exposed to polymerised species which may for a coating.

In yet another embodiment, portions of a substrate 1 surface may be coated with a first coating thickness, while other portions of the surface may be coated with a second thickness, which may be thicker or thinner than the first thickness. A gradient may be observed between the first coating thickness and the second coating thickness. The gradient may be linear, slope, radial, angle, reflected, or diamond gradient. Any gradient may be a transition from the first coating thickness to the second coating thickness. In another embodiment, the first thickness transitions to the second thickness without a gradient.

The gradient may also be a transition region from a first functionalised coating to a second functionalised coating. This may allow for more controlled fluid direction. For example, the first thickness may have a hydrophobic functional coating while the second thickness may have a hydrophilic coating which can generate wicking channels or wicking regions. Other functional coatings and treatments can be applied to a substrate for desired properties. More than one functional coating may be applied to the substrate. Patterns may also be formed on the surface of the substrate using plasma coating techniques. Etching may also be used to expose a functional treatment below one or more surface treatments. If one or more functional treatments are disposed on a substrate etching may be used to expose selected functional treatments. Etching coatings may not be readily visible without microscopy equipment and preferably does not alter the feel of a coated surface.

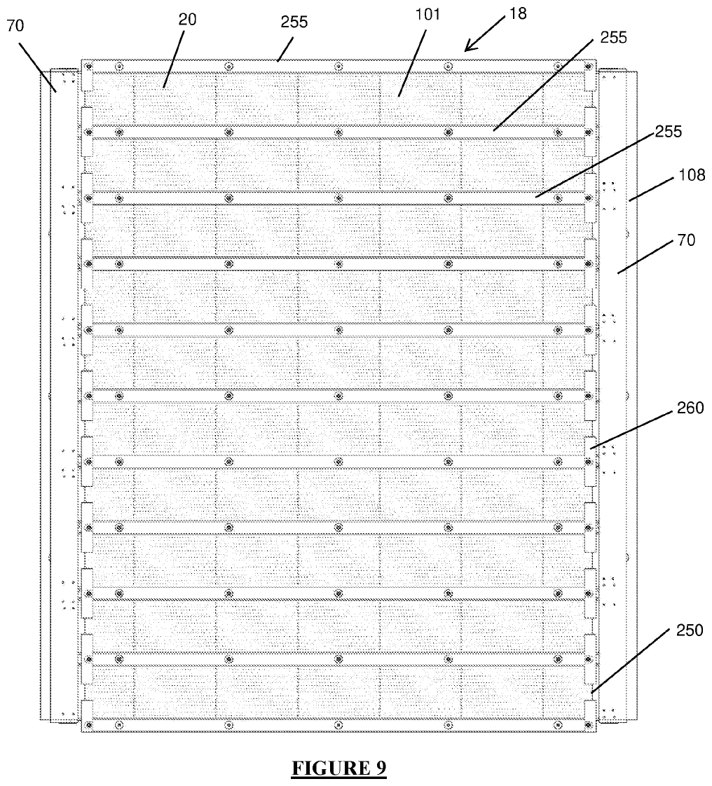

Electrodes 101 are connected to a power supply which can be used to charge the electrodes 101. Power conduits from the power supply to the electrodes 101 may be installed within the support structures 132, and optionally electrodes may also be grounded via a grounding means in the support structures 132 as shown. The electrodes 101 of FIG. 9 are square/rectangular electrodes 101 with each electrode 101 having a hollow core to allow for a coolant to be provided therein. The hollow cores may be connected to the cooling system. Having linear sided electrodes 101 may be used to form a longitudinal region or column of plasma with a uniform density there between. Forming a column of plasma may be more difficult or impossible to achieve with respect to electrodes with circular or ovoid cross-sections. The linear sides of adjacent electrodes 101 may be parallel such that sections the plasma region are not more dense than other regions and arcing is less likely to occur. Typical electrode 101 spacings formed between alternating RF and grounded electrode surfaces may be between about 0.2 mm and approximately 10 mm, and more particularly between about 1 mm and about 5 mm. As such, the plasma regions 106 illustrated may not be to scale and have been enlarged for illustrative purposes.

Electrode lengths, widths, gap spacings, and the number of electrodes 101 can be chosen depending on the material or substrate 1 to be treated. An example of a module apparatus for industrial-scale textile fabric treatment may comprise electrodes with a spacing of between 1 mm to 10 mm, and may comprise one or more plasma region.

The rack 138 for the modules 20 and/or electrodes 101 can be formed from a plastic material or another non-conductive material. The rack 138 may be housed and supported in a plastic module housing 160 block 120 fabricated from thermoplastics such as polyetherimide or polyetherketone. Optionally, a non-conductive coating may be applied to a metal rack 130, 140 to form a non-conductive barrier. In another embodiment the racks are made at least in part from ceramic to more effectively transfer heat away from the substrate 1 and also transfer heat away from the electrodes which can allow electrode coolant to be more effective or reduce the amount of coolant required for the system 10.

With more gas injected or pumped into the chamber the fluids within the chamber will be forced out of the chamber via the manifold outlets 112 and towards the plasma region 106. This may cause a relatively high pressure within the chamber which may be varied by the flow rate of the delivery gas provided to the chamber. Optionally, multiple delivery gas channels can be provided such that each chamber 116 can have a different delivery gas, or a different gas flow provided to the manifold outlets 112. Each chamber may also have at least one further gas input which may provide a monomer or other fluid to the gas chamber 116.

The outlet 112 diameters in the inlet manifold 109 may also be varied by opening or closing an iris. The iris may be actuated by an actuator in communication with a controller. In another embodiment, the inlet manifolds are similar to fluid injectors which may be spaced at predetermined intervals and in any predetermined array or configuration. The controller may be remotely activated by a user of the system 10. Optionally, the iris can be dynamically operated during use if fluid flows are outside of a desired flow rate or an adverse processing effect is observed.

Vaporisation or aerosolization of fluids may be desirable depending on the method of transport of a monomer, and optionally a nanoparticle by the carrier gas. Injector assemblies may be used to convert fluids into a desired state before injection or being direction into a plasma region 106. Fluid vaporisation assemblies may be similar in concept to those used for vaping or vaporising ingestible fluids may also be suitable for use with a module 20.

The inlet manifold 109 may be formed from any desired material which is generally non-reactive, easy to flush or clean, or may provide for a desired finished surface which allows for a desired flow of gas. Such materials may include, Teflon, PTFE, PFA, thermoplastic polymers, ceramic, metals, fibreglass, glass, tempered glass, metal alloys or any other desired material. It is preferred that the inlet manifolds 109 are removable such that they can be readily replaced for a desired treatment process or to be cleaned at a desired time. Optionally, steam or high pressure or high temperature fluids may be provided to the manifold 107 to clean the manifold. This may be similar to an autoclave process. In a further embodiment, the system 10 can be flushed with water or a similar cleaning fluid which can be converted to steam or vaporised by electrodes 101 which can assist with cleaning a module.

Optionally, after treatment processes have been completed, the inlet manifolds 109 may be flushed with a sterilant gas, a cleaning gas, steam, or a cleaning or flushing fluid. Cleaning fluids may be provided to the inlet manifolds 109 at a relatively high-pressure. This may assist with reducing the build-up of deposited fluids, vaporised materials solidifying or otherwise blockages in the manifold 107.

As stated hereinabove, typical delivery gases may include helium, oxygen, non-noble gases, noble gases or mixtures thereof, and small amounts of additives such as nitrogen or oxygen, as examples. The substrate 1 may be treated with a chosen composition, which may react in the presence of the species exiting the plasma and, as will be discussed hereinbelow, a monomeric species may be polymerized and caused to adhere to the substrate 1 by such species.

The monomer or precursor supplied to the manifold 107 for treatment of a substrate 1 may have various functional groups suitable for imparting desired properties to the fabric including repellency, wicking, antimicrobial activity, flame retardancy, as examples. After application to the fabric, the treated portion is moved into the vicinity of plasma regions such that excited species therefrom impinge thereon. The monomer is cured as the treated fabric is exposed to the plasma from the plasma region 106, forming thereby a polymeric material which adheres to the fabrics.

The module rack 138 may be formed from any desired material, such as a metal, metal alloy, polymer, ceramic of any other desired material. However, it will be appreciated that the most desired materials for forming a rack are non-conductive materials, such as polymers. Similarly, module housings 22 may also be formed from similar materials as that of the racks. Polymers may be selected from the group of; Acrylonitrile Butadiene Styrene (ABS), Polypropylene, Polyethylene, High impact polystyrene (HIPS), Vinyl, Flexible PVC, Nylon, Polycarbonate, Lexan, TPE, Synthetic Rubber and Acrylic. It will be appreciated that if a conductive material is to be used, the conductive material may be coated with a dielectric or a non-conductive film or layer. For example, Teflon may be used to coat portions of a conductive surface.

The electrode rack 140 can house electrodes 101 in a predetermined array or in a predetermined configuration. While all electrodes 101 of the system 10 are shown as being a linear configuration, any predetermined configuration may be used. For example, electrodes 101 can be offset from each other, or pairs of electrodes can be staggered or otherwise displaced in a different plane that that of adjacent electrode pairs. Optionally, more than one array of electrodes 101 may be used in a module 20, and may allow for fluids to pass through more than one plasma region 106 with each plasma region 106 having a different plasma density. This may be advantageous as initial excitation or ionisation of a fluid can be established at a high voltage or high temperature and move through a second plasma region which is of a relatively lower voltage and/or lower density to maintain excitation or ionisation.

Electrodes 101 of the modules 20 can be mounted in a direction which is parallel to the direction of movement of the substrate 1, or may be mounted perpendicular, or angled, relative to the direction of movement of the substrate 1, or a combination thereof. Other orientations of the electrodes 101 may be facilitated by an electrode rack 140. As a substrate 1 may be between 1000 mm to 3500 mm in width, it is desirable to form an electrode rack 140 which can span at least the width of the substrate 1. A plurality of module racks 138 can be used within a module to support the length of the electrodes 101 and/or the inlet manifolds 109. This may reduce or generally eliminate the potential for sagging of electrodes 101 and inlet manifolds 109 which could result in uneven coatings or other issues such as; potential damage to electrodes, electrode movement out of a parallel arrangement, arcing, variable or undesired plasma densities, and/or require more energy to generate a plasma. The module racks mounted in the housing 160 may be staggered or offset relatively to an adjacent module 20 such that the electrode supports do not adversely impact treatment of a substrate 1 by creating weak plasma densities in rows or lines which may cause visual or functional defects. Multiple module racks 138 may be used to allow for support of electrodes 101 and inlet manifolds 109. Preferably, the electrode rack 140 allows electrodes 101 to be connected to a power supply and/or cooling system.

As the modules 20 may use manifold outlets 112 to provide fluids into the segment 15, the direction of the electrodes 101 may not impact the orientation or the structure manifold block 108.

An array of modules series may comprise a plurality of the same module type, such as a plasma module 20, a coating module, heating module, or any other treatment module desired. Preferably, when mounting modules 20 in series perpendicular to the movement direction of the substrate 1 the modules 20 are the same type of module to allow for the same treatment across the width of the substrate 1. However, if modules 20 are mounted in series parallel to the direction of movement of the substrate, the modules 20 may be different module types.

In one example, a monomer is pre-applied to a substrate 1 to be treated and/or polymerised. The monomer may be applied to the fabric by spraying, as an example. The monomer may have various functional groups suitable for imparting desired properties to the fabric including fluid repellency, wicking, antimicrobial activity, flame retardancy, as examples. After application to the fabric, the treated portion is moved into the vicinity of plasma regions such that excited species therefrom impinge thereon. The monomer is cured as the treated fabric is exposed to the plasma products, forming thereby a polymeric material which adheres to the fabrics.

Segments

A plurality of segments 15 may be fitted together and sealed to form the system 10. Each segment may be modular and removable, such that the overall length of the system 10 can be modified for specific treatment processes. Further, as the system 10 is formed from multiple segments 15, the system 10 may be adapted to turn on or off selected segments 15, and the modules therein, to reduce the processing area of the system. This can be advantageous if one system requires maintenance. Optionally, empty segments may be fitted to the system which can allow for a substrate or article to be passed through the empty segment without being treated within the empty segment. An empty segment may be transparent, or otherwise devoid of obstruction to allow for an inspection of the substrate or articles within the system. An empty segment may also be installed temporarily within the system if a segment 15 has been removed. Empty segments may still be fitted with a common rail to bridge or join common rails of adjacent segments to ensure fluid commination is maintained. In the event that at least one segment is turned off or the segment is an “empty segment” the system may decrease or modify the treatment or exposure of the substrate to provide an appropriate exposure time to provide a desired treatment or coating thickness.

Segments 15 of the system 10 may be adapted to function with a respective pressure compared to other segments of the system 10. Each segment of the system 10 may be fitted with a sealing means, barrier, or interlock to reduce the volume of fluids moving between segments. Each segment with a pressure above or below atmospheric pressure by ±3% may be considered to be a partial pressure chamber. For example, if the system comprises five segments 15, each segment may be adapted to have a higher or lower pressure relative to an adjacent segment. Optionally, the system may be adapted to have a higher pressure within the central segment, than the segments near to the entry and/or exit of the system.

The segments 15 of the chamber may be sealed with an interlock 310 (or roller 310) which can be provided at any desired location internal the system 10 to form a seal 305. The interlock may be an abutment between two elements, such as two rollers, a roller and a flap or flexible projection, a flap and a corresponding surface 320 or any other two elements which can form an abutting or mating relationship. The two elements forming such an abutting relationship are adapted to allow for a substrate or article to be passed therebetween to allow for a seal to be formed along a portion of the two elements where they are still in an abutting relationship. In the example of an article 1 being a textile, the substrate may generally be in the range of 0.1 to 3 mm, although it will be appreciated that other thicknesses may also be received by the system.

For substrates 10 which prohibit a sufficient sealing adjacent the article 1 at the interlock 310 if the interlock has a continuously linear edge to form the seal 305, the interlock 310 may be formed with a slot or conforming edge which may be adapted to form a seal around the article more sufficiently. For example, the interlock may have a stepped sealing edge to accommodate the article and form a seal with the article and the corresponding surface 320.

In some embodiments it may be preferred that the system 10 is fitted with one or more pressure loss chambers which can reduce the volume of fluids which are lost when using the system, and therefore the pressure within the system as a whole can be maintained more consistently. The fluid losses are caused from a higher pressure internal the segments relative to the atmospheric pressure. As such, the system uses a minor positive pressure relative to atmospheric pressure. This higher pressure may be optional, however, as it may assist with the reduction of external gases entering into the system it may be preferred.

Each flap may extend from the upper portion of the sealing chamber and abut the sides of the chamber and bottom portion to form a seal 305. The seal 305 may be sufficient to prevent or reduce leakage of fluids from the system 10. It is preferred that the sealing flap is a flexible flap or a deformable flap such that upon closing the seal 305 the flap can be biased towards the bottom portion of the seal.

Fluid loss chambers 15 may be provided at the entry and/or exit of the system to ensure that the internal fluids of the system are prevented, or substantially prevented from escaping during use. As the substrate 1 is moved into the system the openings of the system can be a location for fluid losses. Similarly, this may also be true for the exit of the system. Therefore, it may be desirable to have a sealing chamber 300 at the start and the end of the system 10. Each sealing chamber may be fitted with the same sealing means, or may be fitted with different sealing means 310.

In yet another embodiment, the system may be adapted to have an integrated entry and exit formed with the treatment chamber rather than having a separate chamber for the exit and entry. In this way the system 10 does not require separate entry and/or exit chamber to be coupled with the system 10.

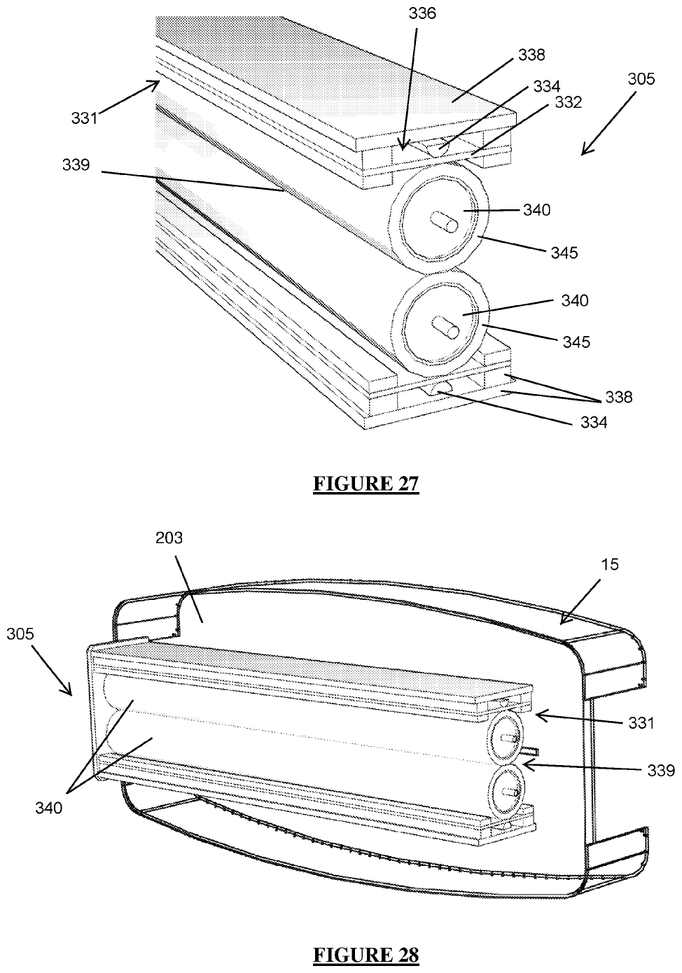

Turning to FIGS. 27 and 28, there is illustrated a further embodiment of a seal 305, which may optionally be mounted within a sealing chamber 300 or at the start and/or end of the system 10, similar to that shown in FIG. 1. The seal 305 may comprise a pair of rollers 340 which can be independently controlled to rotate. The movement of the rollers 340 is such that the substrate 1 can be fed into the system 10. The rollers 340 may have a rigid core which is in communication with a motor or drive, which can affect their rotation. A cover 345 is disposed on the outer surface of the rollers 340 and is preferably used to provide sufficient grip for the transport of the substrate 1. The cover may also be adapted to deform or compress when a substrate is inserted between the rollers such that the cover 345 can form a seal around the perimeter of the substrate when being fed into the system, or being removed from the system at the end. A suitable material for forming the cover 345 may include, but is not limited to; a closed cell foam, foam, a polymer, a rubber, a composite material, and a membrane. The contact between the rollers may form a contact surface which is between 1 mm to 40 mm in length, and may assist with the reduction of fluids leaking from the rollers 340. The outer surface of the cover may optionally be formed with a wool, hair, a knitted material, loops, or any other textured surface which may reduce potential damage of substrates entered between the rollers 340 and may also be used to reduce wear on the rollers when moving.

A seal 305 can be formed between the rollers when the rollers are moved into an abutting relationship. It will be appreciated that the cover may form a part of the roller 340 in this context. The rollers may optionally be relatively displaced such that substrates can be entered or removed from between the rollers. Pressure applied to a substrate between the rollers may be int eh range of 1 Newton to 50 Newtons, and may also assist with removal of local atmosphere before entering into the system 10. Other pressures may also be applied depending on the relative displacement between the rollers 340. Each roller 340 may be independently moved, rotated and/or displaced relative to the other roller 340.

While the rollers 340 are sealed with each other at an inner portion 339, the outer portions 331 of the rollers may be sealed with a diaphragm, membrane, leaf or flap. An example of a flap is similar to that seen in FIG. 26, for example. In this way the system segments 15 can be sealed, while also being in a configuration which can receive the substrate or articles to be passed into the system 10.

The rollers 340 may be sealed at the outer portions 331 by a diaphragm 332. The diaphragm 332 may be biased by a pressure element 334. The pressure element 334 can be controlled at a terminal or adapted to automatically apply further pressure if a leak is detected. The ends of the rollers 340 may be sealed by conventional means, such as ring seals, the cover 345 or any other predetermined means for sealing known in the art.

A bias chamber 336 may be used to house the pressure element 334 and a fluid may be pumped into the bias chamber 336 to push the diaphragm downwardly to form a sealing arrangement with the outer portion 331 of the rollers 340. The walls of the bias chamber may be rigid relative to the diaphragm such that the diaphragm deforms to form a seal before the walls 338 are urged to move.

The use of a positive pressure within the system may allow for external atmospheric fluids to be restricted or prevented from entering into the system 10 when undesired.

As the pressures of the system 10 may be preferred to be positive pressures, the housing 200 of the segments 15 may be shaped to allow for deformation when internal pressures are increased. The housing top and bottom portions 205, 210 may be rounded, concave, convex or otherwise in the shape of an eye such that pressures can be distributed without damage or undesired deformation which could potentially cause leaks. In other embodiments, the housing may be of any geometric shape which can house the segment components and is preferably adapted to reduce potential leaks. The housing 200 may have a staggered housing system which may assist with mating segments together and reducing potential leak regions of the system 10. A sectioned portion 209 may be provided to form a portion of the housing at the start and/or rear of the segment 15. The sectioned portion 209 may be used to complete the top 205 or bottom 210 portions of the housing 200 if the system utilises segment housing which extends between two or more segments 15. At least one side portion 207 may have an access 215 formed therein which can be used to access the modules 20. The access 215 may be screwed, bolted, latched, fixed, secured, releasably secured or attached to the side 207.

An access 215 is provided in the side 207 of the housing 200, which can be used to open the system and interact with modules and components of the segments 15. The access 215 may be fitted against a seal, such as a rubber seal or the like, and may be bolted, screwed, latched, or fastened onto the segment 15. The access 215 is preferably removable, and multiple access panels may form the access 215 of the system 10. Each segment may be formed with an access on either side of the housing, or just one side of the housing 200. Optionally, the top portion 205 is hinged and the top portion 205 can be opened and rotated about the hinge to access the internals of the segment 15. Housing supports 220 may be used to elevate the segments to a desired level and may be adjustable in height. Brace supports 225 may be used to provide stability to the supports 220 and may also be used to rest or seat the segment housing 200 on. In one embodiment, the segment housing is seated in a cradle which may be formed by the supports 220 and the braces 225.

Modules may be serviced via an access 215, such as an access port as seen in FIG. 1. Each of the system modules 20 may have a respective access location and be used to remove or service a respective module 20. Optionally, each chamber segment or each predetermined chamber segment may have an access location such that more than one module 20 can be accessed for service and/or removal at the same time. the access locations may be fitted with sealing means to prevent or substantially prevent leakage of internal atmosphere of the chamber.

In yet a further embodiment, the system further comprises a holding segment or holding chamber (not shown). This may allow for a substrate 1 to be entered into the system and retained within the holding segment before being treated. This can allow for a predetermined length of textile to be entered into the system 10 without being treated. A holding segment can be used to load a length of substrate into the system and allow for a buffer period if there are modifications required to the substrate not entered into the system. This can be of particular benefit in relation to sections of substrate which may be fixed to another substrate, such as the tail of a first substrate being fixed with the lead of a second substrate. For example, a textile desired to be treated by the system may comprise multiple sections of substrate which are the same material, or a plurality of materials and these sections of substrate may be fixed together while a portion of the substrate is being treated.

Further, having a holding chamber may allow for errors or defects in the substrate to be marked, or remedied in advance of the treatment process of a section of a substrate 1. The holding chamber may also be fitted with an active pump system and/or a sensor to determine the volume of argon or other fluids within the chamber. The use of a holding chamber may also allow for tensioning equipment inside the system 10 to impart a desired tension more reliably.

Holding chambers may be used to more clearly view the substrate 1 as it enters into the system and ensure that the substrate has been mounted for processing correctly. The lacing system may be adapted to allow for repeat attempts to correctly align the substrate or collect the substrate 1. The lacing system may be adapted to carry the substrate 1 from outside the system 10 and bring the substrate 1 to any predetermined segment within the system 10.

In yet a further embodiment, the segments may be provided with different pressures from the modules 20 to form partial pressure segments. The segments may have pressures which are higher or lower than atmospheric pressure, but are preferably higher than 100 kPa. In an example, a system comprising five segments 15 may be adapted to have selected segments supplied with a higher pressure relative to the other segments. As each chamber may have a different pressure than an adjacent chamber, the chambers may be fitted with a seal, airlock or other barrier which can restrict the movement of fluids from one chamber to the next. The series of segments 15 may be used to ramp up and/or ramp down pressures slowly such that portions of the processing line can be treated in a modified atmosphere. In such a configuration the middle most segment 15, may have the highest pressure of all the segments 15. Optionally, pressures of the first and last segments 15 may also be comparable or generally equal to each other. Similarly, the second and fourth segments may also have substantially the same pressures therein, relative to each other. The segments 15 may also be at atmospheric pressure, and hazardous treatments may be applied therein and be drawn to the middle of the system 10 and removed from near to the entry and the exit.

In a further embodiment, the modules 20 of the segments 15 may be integrally fixed with each segment. In this configuration, the segment may be approximately the same width or larger than the module 20, such that a plurality of segments 15 can be mounted or secured together. However, more than one module 20 may be mounted or integrally fixed with the segment 15. Fixing modules with segments 15 may allow for segments to be removed to allow for easy cleaning and access for maintenance. Segments 15 with an electrode array may be in the range of around 500 mm to 3000 mm in length, however other lengths may also be desirably fabricated for use with the system. The lengths of the segments 15 may be dependent on the width of the modules 20 used for treatment of a substrate 1.

Each segment 15 may be the same as an adjacent segment 15 or may have a similar housing an adjacent segment 15. Each segment may have any predetermined number of modules 20, array of modules 18 and/or types of modules 20.

It will be appreciated that modules 20 which are integral with the segment 15 may mean that a module housing 160 or module housing which is integrally formed with a portion of the housing, while the electrodes 101 and inlet manifold 109 may be replaceable or otherwise removable.

The system 10 may further comprise an entry segment, or a series of segments leading into the treatment segments. The entry segment may be used to separate the atmosphere of the treatment segments from the entry and exit locations of the system 10.

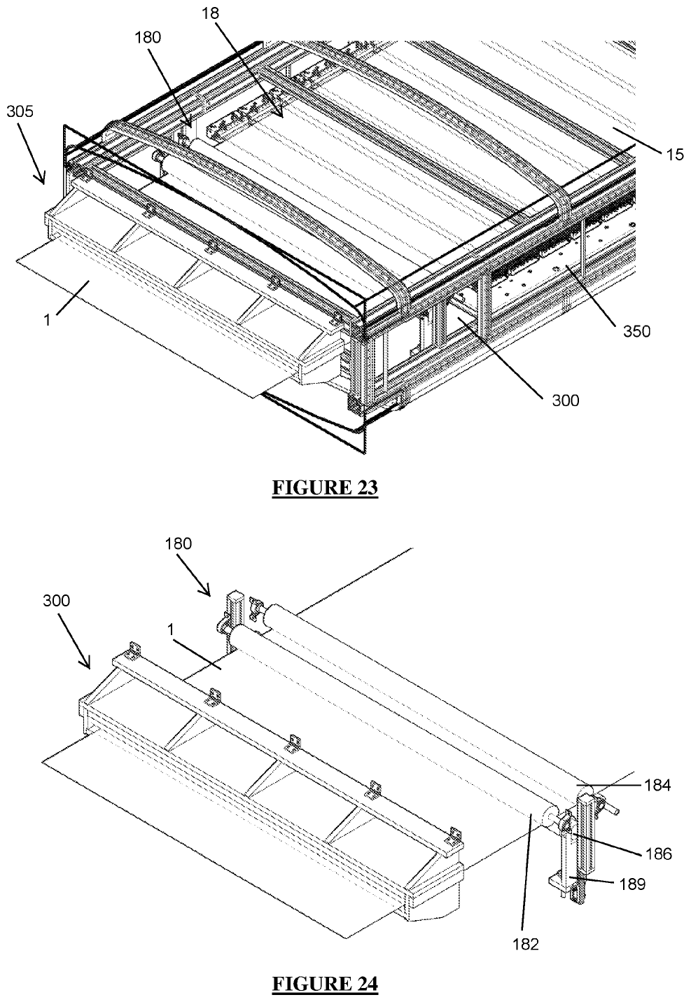

The entry and the exit segments may be sealed by an internal sealing system 10 when the entry and/or exit is opened. The internal sealing system 10 is adapted to seal the segments from external atmosphere ingress, or movement of fluids between segments 15 undesirably. The entry and exit segments 15 may be similar to that of any other segment 15 within the system 10, however the entry and the exit segments 15 may further comprise a wall 203 with an entry or exit slot. The wall 203 may be a front wall 203 or a rear wall 203 at the exit of the system, to which a seal 305 can be mounted, see for example FIGS. 23 and 24. The seal 305 may be fixed to the wall 203 at a hinge 325 as seen in FIGS. 23 to 26. The hinge 325 may be provided to allow to a portion of the seal to be rotated relative to the wall 203 to allow for mounting a substrate 1 within the seal 305. Referring to FIGS. 25 and 26, an internal entry seal 330 may be provided to close or seal off the slot in the wall 203 when the seal 305 is opened, or at any desired time. Closing the internal entry seal 330 may allow for a reduction of fluid loss from the segments. It will be appreciated that the internal entry seal 330 may be mounted at the end of the system 10 and be an internal exit seal instead.

Cleaning

Cleaning of the electrodes 101 and the modules 20 may be achieved with the use of an automated cleaning tools. The system 10 may include at least one means for scraping, lifting or removing build-up materials on the electrodes 101. The build-up materials may be ceramic materials which include silicone in the case of HMDSO, for example. The build-up materials may interfere with the effectiveness of the electrodes, or may reduce the reaction gap, or plasma region 106 between the electrodes as the build-up of materials increases. As such, it may be advantageous to remove these materials after a predetermined period. Optionally, these by-products may be collected and used for other applications.

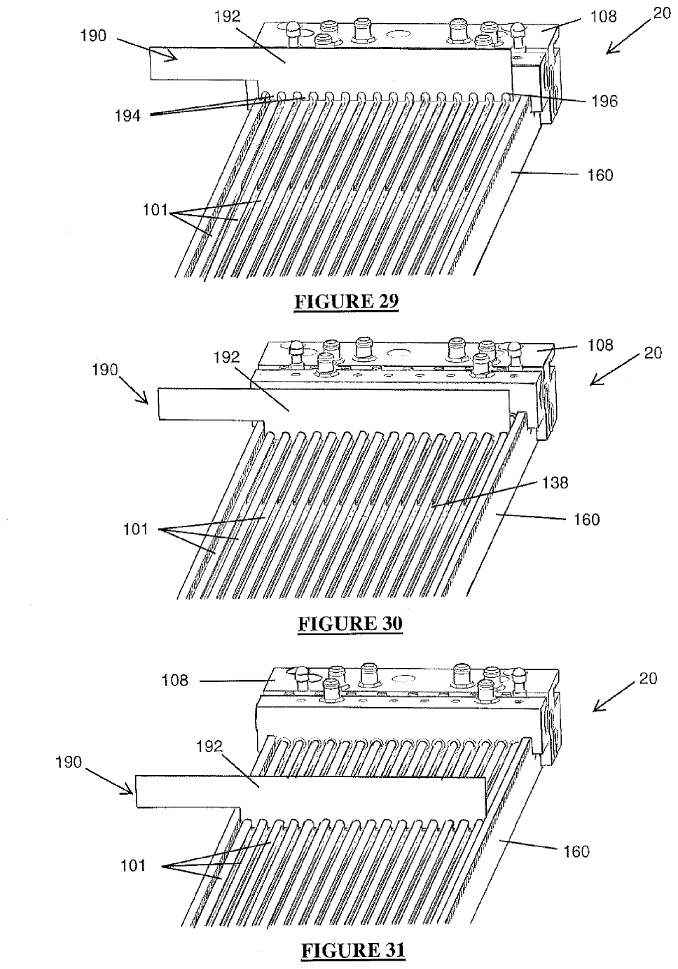

The electrodes 101 and the manifold 107 may be cleaned by the cleaning tool 190. An embodiment of a cleaning tool 190 is illustrated in FIGS. 29 to 31. A respective cleaning tool 190 may be mounted onto each module 20 to allow for periodic or desired cleaning of the electrodes 101 and/or the inlet manifolds of the system 10. The cleaning tool as shown in FIG. 29 is in a pre-engagement position. FIG. 30 illustrates the cleaning tool positioned in a first engaged position with the electrodes and FIG. 31 illustrates the cleaning tool being moved from the first engaged position to a second engaged position, wherein the distance between the first and second engaged positions has been cleaned, scraped, or partially cleaned by the cleaning tool 190.

A vacuum (not shown) may be associated with the cleaning tool 190 which can collect by-products which are within the module 20. A sweeper (not shown) may be used to assist with collecting or directing by-products or debris within the module 20, such that the vacuum can be used to collect said by-products or debris. In another embodiment, the module 20 module housing 160 may be formed with one or more slots which can allow by-product or debris to fall through the one or more slots. In this way the by-product or debris can fall onto the exhaust plate 350 and then be urged into the exhaust system 360. Any debris or by-product remaining on the surface of the exhaust plate 350 may be collected or cleaned off at a later time as this would not impact the treatment processes. The exhaust array connections may be in communication with at least one of the apertures of the exhaust array 355. If some of the apertures of the array 355 are not connected with the exhaust array connections 360, these apertures may allow debris or by-products to fall onto the housing or another collection plate (not shown) below.

Cleaning tool 190 may comprise a body 192 portion which is connected to an actuator (not shown). The actuator may be bound to a track, rail or a predetermined movement path. The body 192 of the cleaning tool may span the width of the m module housing 160. A plurality of protrusions 194 may project from the body 192 which may be contoured to conform to the general shape of the electrodes 101 and/or the inlet manifolds 109. The actuator may affect movement of the scraper cleaning tool 190 and may move the scraper in a direction which is in the axial direction of the electrodes 101. Referring to FIGS. 30 to 31, the cleaning tool 190 is shown as being in an engaged position with the electrodes 101 in which the electrodes can be scraped by the scraping edge 196. Other predetermined movements of the scraper may also be used, such as a circular movement or perpendicular movement, which may be of particular use with regards to brush type cleaning tools 190.

The vacuum may be used to collect by-product, debris, or materials which fall into the module housing 160. The by-product may be formed during treatment processing, or may be formed when electrodes 101 or the inlet manifold 109.

Debris that falls into the housing 160 may be swept by a sweeping tool (not shown) to an end of the module housing 160, or out of an aperture in the housing 160 (not shown). The sweeping tool may be used to direct debris to a central location, to an aperture or towards the vacuum.

Cleaning tools 190 via abrasion methods may be any desired physical interactions between the tool and the components of the module 20. Each of the modules may be fitted with at least one brush or other abrasion tool to allow for the scraping, rubbing, scratching, or polishing of the electrodes. The electrodes are preferably formed with a generally smooth outer surface which can be cleaned by these methods. In another embodiment, the electrodes may be formed with a textured surface which requires the use of bristles or a plurality of discrete elements with respective contact points to clean the textured surface. Bristles may be formed from polymer, metals, composites materials which may cut into, abrade or scratch away at build-up material which has formed on the electrodes 101, and/or the inlet manifolds 109.

Preferably, the surface of the electrodes 101 is non-porous and generally smooth such that cleaning by scraping. A scraper, one example of a cleaning tool 190, may be used to clean at least a portion of the electrode surface which can remove by-product build-up or remove films or coatings deposited on the electrodes 101. Cleaning off build-up of materials may be essential as power requirements to maintain a stable plasma may increase with build-up of by-product or coating on the electrodes, and also may assist with reducing the potential for debris to be dislodged and adhered with the coating.

The scraper may be shaped to generally conform to the surface proximal surface of the electrodes 101. A scraping edge 196 or scraping surface of the cleaning tool 190 can be used to cut into or lift by-product and/or debris from the electrodes 101. It is preferred that at least 30% of the surface of the electrodes 101 can be cleaned with the scraper. More preferably, at least 50% of the surface of the electrodes can be cleaned by the scraper, or even more preferably, at least 70% of the surface of the electrodes can be cleaned by the scraper.

The electrodes 101 are preferably mounted on supports that allow for scraping or cleaning of the electrodes 101. An embodiment of a support for the electrodes 101 is illustrated in FIG. 18, for example. The support is a module rack 138 which comprises a manifold rack 146 and an electrode rack 140. Each of the racks 146, 140 may be adapted to receive an inlet manifold and an electrode, respectively. The racks 146, 140 may be formed as an integral piece or may be formed separately and fixed or secured together (as can be seen in FIG. 18, for example). If the racks are secured together, any desired mating method may be used, such as a tongue-in-groove connection, male and female connector, clasp, clamp, press-fit, seated arrangement, gluing, bonding, or any other predetermined mating method. As shown, the electrode rack comprises an electrode recess which is formed at the end of a projection 144. A plurality of projections 144 are shown which can be used to support a portion of the electrodes in the electrode recesses 142. The recesses 142 may correspond to the general shape of the electrodes 101.

Optionally, the electrodes are adapted to be rotated to allow for by-product or debris build-up to be controlled. Rotation of the electrodes 101 may also allow for the scraper or cleaning tool to more effectively clean electrodes 101 with one or more passes to remove, or substantially remove, build-up from said electrodes 101.

Preferably, the modules 20 are designed to be in an “upside down” configuration as shown in the images to allow for debris to fall from the electrodes and down into the shell of the module. In this way the fluids from the modules are propelled relatively upward. However, while this configuration is shown, the system 10 may be adapted to have the modules projecting fluids relatively downward, such that a substrate 1 or conveyor system can be used with the system, and 3D articles may be treated. If the system is preferably used to treat 3D articles which with the modules in an inverted position, the system may have a conveyor or article holder which can retain the article to be treated in place over the modules to allow for treatment.

The system 10 may be fitted with a transport means which comprises at least one of clamps, seats, mounts, hooks, magnets or another means adapted to suspend an article above the modules 20 to allow for treatment. For example, if a phone case is to be treated, the system 10 may have a mount which is the size of the phone to be cased by said phone case, on which the phone case can be mounted. The phone case can then be treated and removed from the mount after treatment.

The system 10 may be adapted to provide for batch processing of multiple items, and therefore may be suitable for use in line processing. The line processing can be part of existing line processing system.

In yet a further embodiment, electrodes 101 may be formed from an extrusion of material, such as extruded ceramics or extruded polymer. If the electrodes 101 are formed from alumina, for example, the alumina may be extruded and hardened to form the electrodes. However, the electrode sheaths 103 may be formed from one or more elements bonded, glue, welded or fused together. If electrode sheaths 103 are formed from a plurality of pieces, the electrodes may have two outer sides, which may sandwich or bound an electrode core 102. The other sides of the electrode core 102 may be bound by further portions of a sheath to fill in any gaps if an adhesive, epoxy, binder, cement, or glue. The geometry of these electrodes may be generally rectangular in nature.

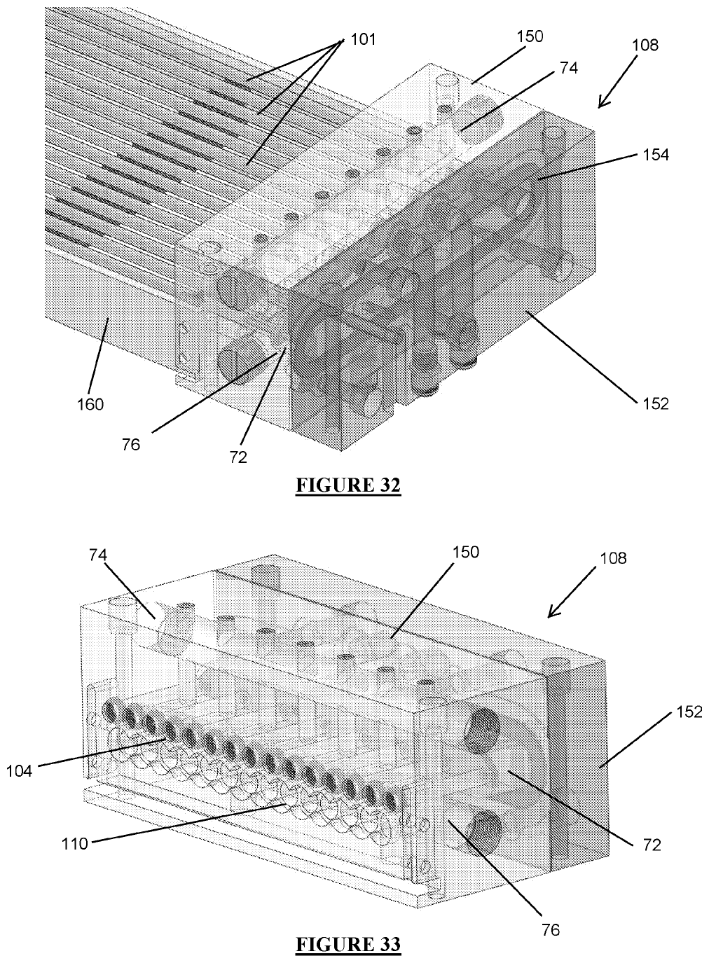

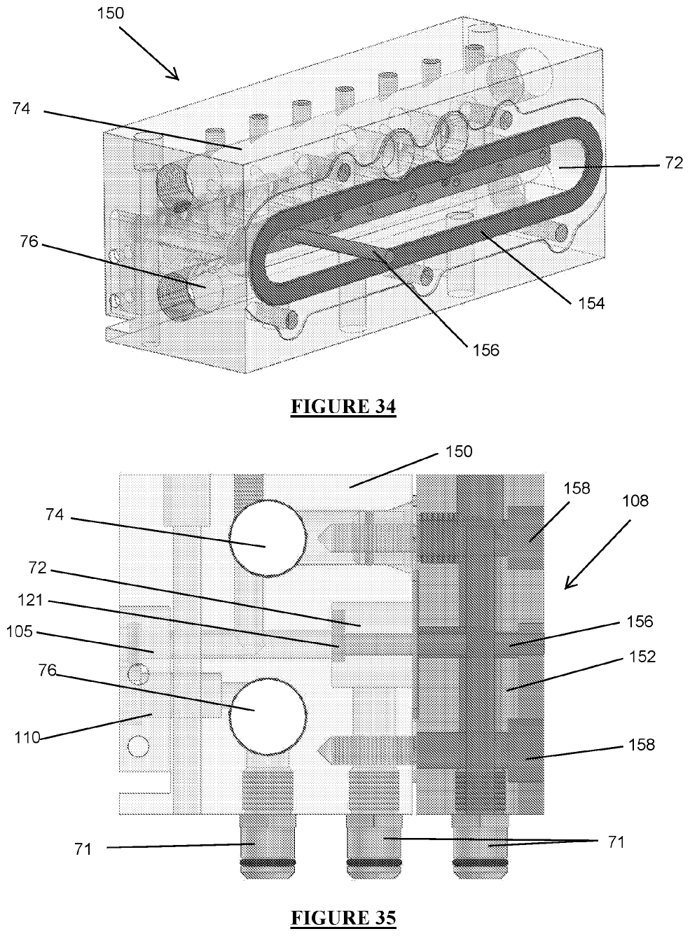

Turning to FIGS. 32 to 35 there is illustrated embodiments of a manifold block 108 which is formed from two portions 150, 152. This manifold block 108 may be used in any of the embodiments as discussed herein. A gasket or seal can be provided between the two portions 150, 152 of the manifold block 108 which can allow for a liquid or fluid tight seal. As shown the connection of the two portions of the manifold block may be generally perpendicular to the longitudinal axis of the electrodes. The two portions 150, 152 of the manifold block 108 may be achieved with securing means 158, such as screws, bolts, tongue-in-groove or any other predetermined means which allows for a fluid tight seal to be formed between the portions 150, 152 local the seal 154.

The two portions of the manifold block 108 may be the electrode portion 150, which seats the electrodes, and an end portion 152 which may be adapted to deliver fluids or remove fluids from the manifold block. As can be seen, two fluid paths are mounted within the end portion which can be used to either supply or remove fluids from the electrode cooling system channels 72, 74, however the end portion may be configured with any number of fluid paths in fluid communication with a fluid channel. The channel 74 may be a cavity which mounted the busbar 121 which connects a plurality of electrode cores 102.

The cavity 74 with the electrical bar or busbar 121 may receive fluids which are to enter into the electrodes 101, or receive the warmed coolant from the electrodes 101. It may be preferred that the cavity receives the fresh or cooled coolant to be supplied to the electrodes 101 such that the busbar can be maintained at a generally cooler temperature or desired temperature.

In this way the upper channel 72 and the cavity 74 define an entry and an exit for coolant of fluids supplied to a module 20. More particularly if coolant is supplied to a cavity at a first manifold at a first end of a module, the upper channel of the second manifold block at the second end of the module may be adapted to receive the coolant which has passed through a set of electrodes, or vice versa. Each module 20 may have at least two sets of electrodes, in which the first set is an active set of electrodes, and the second set is a grounded set of electrodes. The active set of electrodes may be RF electrodes, or may be otherwise energised or supplied a voltage to allow for excitation of a plasma fluid to form a plasma.

A plasma fluid and/or precursor can be supplied to the manifold 108 via the lower channel 76 and be provided to the electrodes 101 to form a plasma and a reactive species which may be used to coat an article or substrate 1. It will be appreciated that the lower channel 76 may be used to provide exclusively a plasma fluid which can be supplied to the plasma region between the electrodes 101. The lower channel 76 may also be used to provide one or more different monomers or precursors to the manifold 107.

An electrical bar 121 or busbar 121 may be disposed within the manifold block 108 to provide electrical connection with the electrodes 101 to allow for energisation of the electrodes 101 when in use. The contact may be a strip of metal which is welded, soldered or in contact with the cores 102 of the electrodes 101. The electrical connection to the busbar or electrode electrical connector 121 may be achieved by a conductive element 156 which extends from the busbar 121 through the end portion of the manifold block 152. The busbar 121 may be within the cavity 72 and be exposed to coolant from the cooling system.

Bias plate 250 may comprise a metallic substrate, in which the metallic substrate is at least one of; a metallic mesh, a continuous metallic sheet, a metallic sheet with an array of predetermined shapes cut therefrom, or a metallic sheet with thicker predetermined regions which may or may not be in a predetermined pattern. Optionally, the metallic sheet may be imparted with a random texture. The metallic substrate may optionally be charged via an electrical connection. Any predetermined charge can be imparted to the metallic substrate which may be positive or negative, and allow for a desired movement of species from the plasma region towards the bias plate, and impinge or deposit onto the substrate or article being treated by the system 10.

In an embodiment, a bias plate 250 may be formed from a first ceramic material and a second ceramic material with the metallic substrate positioned therebetween. The first and or second ceramic may be any predetermined ceramic or glass. If glass is used it will preferably be a tempered glass, laminated glass or any other glass which is adapted to withstand higher temperatures or exposure to a large temperature difference. In another embodiment, the bias plate 250 may be formed with a first ceramic and a metallic substrate mounted thereto. A cooling channel may be formed in the bias plate to cool the ceramic of the bias plate. The cooling channel may be adapted to supply coolant fluids which may be the same as the local atmosphere or a similar composition as that of the plasma fluid.

In yet a further embodiment, the bias plate is formed from a metallic substrate or metal sheet. In this embodiment, the metallic sheet or substrate may have a number of textures imparted thereto or may have an array of apertures cut from it, which may reduce arcing or improve visibility to the plasma region of the modules 20.

The bias plate array, as seen in FIG. 6B to FIG. 12 may be formed from a plurality of bias plates 250 mounted in an array which corresponds to the module array 18. The number of modules 20 in a segment 15 may be equal to or more than the number of bias plates within the segment 15.

The gases in the recirculation system may be cooled by a heat exchanger and/or a chiller which can reduce the temperature of the fluids which are recirculated from the modules. The temperature of the gases from the modules may be in the range of 20° C. to 180° C., but are preferred to be generally in the range of 0° C. to 40° C., or more preferably in the range of 10° C. to 30° C. The chiller for the recirculating gases and the electrode cooling system may be the same system, or may be separate systems adapted to regulate the temperature of each separately.

For example, it may be advantageous to have a first temperature for the electrode cooling system and a second temperature for the recirculating gases of the chamber. In this way two separate systems can achieve the desired relative temperatures.

Substrates 1 or articles treated with the system 10 may optionally undergo a post-plasma treatment step. The post-plasma treatment step may be a curing step, an exposure to a laser, exposure to UV or heat treatment. These steps may finish the substrate or article coating and impart a desired functionality, or enhance the applied functionality that was applied with the plasma treatment or plasma coating. For example, a hydrophilic coating applied to a substrate may have a higher contact angle (greater than 90°) after a heat treatment. Similar functionality may be achieved by the use of UV treatments, or exposing the coating to a laser. Post treatments may be used to cure the coating applied via the plasma treatment. Post-treatments, such as heat treatments, may be achieved with the use of a heating room or heating chamber, or may be immediately after the plasma-treatment or plasma coating.

In another embodiment an aging process may be used to improve the functionality of the coating, and may include leaving the article or substrate for a period of time to allow for the coating to age, such as for a period of weeks to months, or may be accelerated with the use of a post-treatment such as a heat treatment.

The system 10 may also be adapted to supply a volume of plasma fluid directly to the chamber to maintain a positive pressure within the chamber. This positive pressure may be less than 1 atmosphere of pressure, and is preferably less than 5% of 1 atmosphere of pressure, or even more preferably is around 20 pascals to 5 kilopascals. In another embodiment, the system internal pressure is around 20 to 200 pascals above local atmospheric pressure, and may be referred to as atmospheric pressure throughout this specification. However, it will also be appreciated that any reference to atmospheric pressure may also be a “true atmospheric pressure”, which is the same as the local atmospheric pressure at around 101 kPa.

The system may receive a volume of gas to top up the system, or otherwise supply the segment 15 with plasma fluids. For example, if the plasma fluid were an argon gas the volume of argon gas supplied may be in the range of 1 L/min to JOOOL/min, depending on the overall internal volume of the chambers. The top up gases supplied to the system may be via the modules, or the recirculation system, or from a dedicated top up line (not shown). The recirculation system may be the exhaust system which allows for gases to be transported from the chamber and through a cooling system and/or filtration system which may be adapted to remove contaminants or particles from the gases within the segment 15. Particles within the segment may be monomer, polymers, partially polymerised monomer, or by-products from a treated substrate.

Picker System

In another embodiment, the modules 20 may be removed by a picker system (not shown) which can detach a module from the common rail and transport the module to a cleaning station or a module access location. The cleaning station may have automated cleaning systems

In another embodiment, a picker system (not shown) is used mate with a module and released the module from the common rail. The picker may be adapted to interact with the ends of the module 20 and remove the manifold from the common rail. The manifolds may be released by the picker by unmating the manifold fluid connectors and the manifold electrical connectors from the common rail ports. The interface 71 between the common rail 70 and the manifold block 108 may include a spigot or connection member and may have a seal which can provide a further fluid seal to reduce the potential for leaks occurring. Each module 20 may have a respective common rail, such that the fluids supplied to a discrete common rail supplies fluids to only one module. It will be appreciated that the system may be adapted to allow for a common rail which supplies more than one module 20. When modules are removed from the common rail, or the discrete common rail the fluid connections may be adapted to dynamically seal to prevent fluids from continually entering into the system 10.

The picker system may be adapted to release the module fluid connectors and electrical connectors from the common rail and transport the module from a fixed position with the common rail to a second position. The second position may be a position where the module can be removed from the segment 15, or may be a moved to a location which the system can clean the module, or replace the module removed. Optionally, a replacement module may be fitted into the removed module location such that treatments can continue. This may be of particular advantage in relation to hot swapping modules 20.

The picker system may have a pair of release tools which can release the module from both common rails, or from both supports at the end of the module; if the module is not connected to a common rail 70. The release tools may disengage the module 20, and the connectors of the manifold 107 and lower or raise the module relative to the common rails 70. When the module 20 is released, any ports to which the module was connected to may be sealed or closed to prevent fluids leaking into the system when not desired. Optionally, the ports can be sealed before the module is moved relative to the common rail 70.

Picker systems may be of particular advantage as the system is preferred to remain closed to maintain desirable internal atmosphere conditions, which may include an argon rich atmosphere or an atmosphere which is advantageous to the formation of a desirable plasma.

In yet a further embodiment, the system 10 may comprise a segment 15 which comprises the bias plate 250, modules 20 and recirculation system 40 within the same chamber or environment, such that they are all generally exposed to the same local atmosphere and pressure. In this way the bias plate, module 20, and recirculation system 40 are not sealed off from each other and the temperatures within the segment can be maintained more simply. A fan or series of fans can be used to assist with fluid movement within the segment 15 if desired.

It may be preferred that the recirculation system 360 is adapted to function without an exhaust plate and may have one or more entry locations which draws in fluids from the segment. Optionally, the system is purged such that an internal atmosphere is at least 95% pure argon. In other embodiments, the system is purged such that the internal atmosphere is between 98%-99.999% argon. It is preferred that the system maintains a minimum purity such that undesired coatings are formed.

Although the invention has been described with reference to specific examples, it will be appreciated by those skilled in the art that the invention may be embodied in many other forms, in keeping with the broad principles and the spirit of the invention described herein.

The present invention and the described preferred embodiments specifically include at least one feature that is industrial applicable.

1. A system for treating an article, wherein the system comprises;
a segment adapted to contain a local atmosphere and an internal pressure which is within the range of 90 kPa to 110 kPa;
the segment comprising a module;
the module comprising a pair of electrodes;
a manifold for delivering a fluid to the pair of electrodes; and
wherein the electrodes are adapted to energise the fluid delivered from the manifold before being deposited onto the article.

2. The system as claimed in claim 1, wherein the segment further comprises a bias means which may attract the fluids energised by the electrodes.

3. The system as claimed in claim 1, wherein the module is connected to a common rail which is in fluid communication with a fluid reservoir.

4. The system as claimed in claim 3, wherein the common rail further comprises an electrical connection to power the module.

5. The system as claimed in claim 3, wherein the common rail is adapted to mate with and releasably fix the module in a desired position.

6. The system as claimed in claim 1, wherein an exhaust system is disposed relatively below the modules such that at least a portion of the energised fluids which are not deposited onto the substrate can be collected.

7. The system as claimed in claim 1, wherein the system further comprises a lacing system for guiding a substrate adjacent to the modules.

8. The system as claimed in claim 1, wherein the manifold comprises a plurality of inlet manifold tubes which comprise a plurality of apertures for delivery of the fluid.

9. The system as claimed in claim 8, wherein a conduit extends into the inlet manifold tube.

10. The system as claimed in claim 1, wherein the system further comprises at least one of an atomiser, a vaporiser and an aerosoliser.

11. The system as claimed in claim 1, wherein the pair of electrodes are coated with a dielectric material.

12. The system as claimed in claim 1, comprises at least two segments, wherein each segment is joined at a seal to an adjacent segment.

13. The system as claimed in claim 1, wherein an entry seal is mounted onto a segment and adapted to seal the segment from external atmosphere.

14. The system as claimed in claim 1, wherein the internal pressure of the system is increased relative to ambient atmosphere by the introduction of fluids from the modules.

15. The system as claimed in claim 1, wherein plasma can be formed between the electrodes when the fluid is energised.
